(19) United States
(12) Patent Application Publication
(10) Pub. No.: US 2024/0094260 A1
(43) Pub. Date: Mar. 21, 2024

(54) Methods for Making Probe Arrays Utilizing Lateral Plastic Deformation of Probe Preforms

(71) Applicant: Microfabrica Inc., Van Nuys, CA (US)

(72) Inventor: Onnik Yaglioglu, Chatsworth, CA (US)

(73) Assignee: Microfabrica Inc., Van Nuys, CA (US)

(21) Appl. No.: 17/384,680

(22) Filed: Jul. 23, 2021

Related U.S. Application Data
(60) Provisional application No. 63/055,892, filed on Jul. 23, 2020.

(51) Int. Cl. B21D 22/02

(52) U.S. Cl. CPC B21D 22/02; C25D 1/003

(57) ABSTRACT

Improved probe arrays (e.g. buckling beam arrays) are formed using probe preforms that have desired array spacings but not intended individual probe configurations. Groups of preforms are engaged with one or more deformation plates that cause permanent (i.e. plastic) deformation of the probe preforms to provide probe from deformed probe preforms with desired probe configurations where at least part of the deformation of multiple probe preforms occur simultaneously and where multiple deformations of individual probe preforms may occur in parallel or in series and where deformation is provided by substantially lateral displacement of the one or more deformation plates relative to a permanent or temporary array substrate or one or more different deformation plates. In some variations, the substantial lateral displacement may be accompanied by longitudinal shifting as necessary to accommodate for change in relative longitudinal positioning as lateral displacement occurs.

### RELATED APPLICATIONS

The below table sets forth the priority claims for the instant application along with filing dates, patent numbers, and issue dates as appropriate. Each of the listed applications is incorporated herein by reference as if set forth in full herein including any appendices attached thereto.

| | Continuity | | Which was | Which | Which | Dkt No. |
|---|---|---|---|---|---|---|
| App. No. | Type | App. No. | Filed | is now | issued on | Fragment |
| This | claims | 63/055,892 | 2020 Jul. 23 | pending | — | 392-A |
| application | benefit of | | | | | |

### FIELD OF THE INVENTION

The present invention relates generally to the field of probe arrays or subarrays for testing (e.g. wafer level testing or socket testing) of electronic components (e.g. integrated circuits) and more particularly to the formation of such arrays or subarrays from a plurality of probe preforms that are simultaneously shaped by lateral plastic deformation while spaced according to an array configuration.

### BACKGROUND OF THE INVENTION

Probes:

Numerous electrical contact probe and pin configurations as well as array formation methods have been commercially used or proposed, some of which may be prior art while others are not. Examples of such pins, probes, arrays, and methods of making are set forth in the following patent applications, publications of applications, and patents. Each of these applications, publications, and patents is incorporated herein by reference as if set forth in full herein as are any teachings set forth in each of their prior priority applications.

| U.S. Pat App No., Filing Date | |
|---|---|
| U.S. App Pub No., Pub Date | |
| U.S. Patent No., Pub Date | First Named Inventor, “Title” |
| 10/772,943 - Feb. 4, 2004 | Arat, et al., “Electrochemically Fabricated Microprobes” |
| 2005-0104609 - May 19, 2005 | |
| — | |
| 10/949,738 - Sep. 24, 2004 | Kruglick, et al., “Electrochemically Fabricated Microprobes” |
| 2006-0006888 - Jan. 12, 2006 | |
| — | |
| 11/028,945 - Jan. 3, 2005 | Cohen, et al., “A Fabrication Process for Co-Fabricating a |
| 2005-0223543 - Oct. 13, 2005 | Multilayer Probe Array and a Space Transformer |
| 7,640,651 - Jan. 5, 2010 | |
| 11/028,960 - Jan 3, 2005 | Chen, et al. “Cantilever Microprobes for Contacting |
| 2005-0179458 - Aug. 18, 2005 | Electronic Components and Methods for Making Such |
| USP 7,265,565 - Sep. 4, 2007 | Probes |
| 11/029,180 - Jan. 3, 2005 | Chen, et al. “Pin-Type Probes for Contacting Electronic |
| 2005-0184748 - Aug. 25, 2005 | Circuits and Methods for Making Such Probes” |
| — | |
| 11/029,217 - Jan. 3, 2005 | Kim, et al., “Microprobe Tips and Methods for Making” |
| 2005-0221644 - Oct. 6, 2005 | |
| 7,412,767 - Aug. 19, 2008 | |
| 11/173,241 - Jun. 30, 2005 | Kumar, et al., Probe Arrays and Method for Making |
| 2006-0108678 - May 25, 2006 | |
| — | |
| 11/178,145 - Jul. 7, 2005 | Kim, et al., “Microprobe Tips and Methods for Making” |
| 2006-0112550 - Jun. 1, 2006 | |
| 7,273,812 - Sep. 25, 2007 | |
| 11/325,404 - Jan. 3, 2006 | Chen, et al., “Electrochemically Fabricated Microprobes” |
| 2006-0238209 - Oct. 26, 2006 | |
| — | |
| 14/986,500 - Dec. 31, 2015 | Wu, et al. “Multi-Layer, Multi-Material Micro-Scale and |
| 2016-0231356 - Aug. 11, 2016 | Millimeter-Scale Devices with Enhanced Electrical and/or |
| — | Mechanical Properties” |
| 16/172,354 - Oct. 18, 2018 | Chen, et al. “Pin-Type Probes for Contacting Electronic |
| 2019-0204354 - Jul. 4, 2019 | Circuits and Methods for Making Such Probes” |
| — | |
| 16/584,818 - Sep. 26, 2019 | Smalley, “Probes Having Improved Mechanical and/or |
| — | Electrical Properties for Making Contact between Electronic |
| — | Circuit Elements and Methods for Making” |
| 16/584,863 - Sep. 26, 2019 | Frodis, “Probes Having Improved Mechanical and/or |
| — | Electrical Properties for Making Contact between Electronic |
| — | Circuit Elements and Methods for Making” |
| 62/961,672 - Jan. 15, 2020 | Wu, “Compliant Pin Probes with Multiple Spring Segments |
| (P-US381-B-MF) | and Compression Spring Deflection Stabilization Structures, |
| | Methods for Making, and Methods for Using” |
| 62/961,675 - Jan. 15, 2020 | Wu, “Probes with Multiple Springs, Methods for Making, and |
| (P-US382-B-MF) | Methods for Using” |
| 62/961,678 - Jan. 15, 2020 | Wu, “Compliant Pin Probes with Flat Extension Springs, |
| (P-US383-B-MF) | Methods for Making, and Methods for Using” |
| 16/791,288 - Feb. 14, 2020 | Frodis, “Multi-Beam Vertical Probes with Independent Arms |
| (P-US385-A-MF) | Formed of a High Conductivity Metal for Enhancing Current |
| | Carrying Capacity and Methods for Making Such Probes” |
| 62/985,859 - Mar. 5, 2020 | Veeramani, “Probes with Planar Unbiased Spring Elements |
| (P-US379-B-MF) | for Electronic Component Contact and Methods for Making |
| | Such Probes” |
| 63/015,450 - Apr. 24, 2020 | Lockard, “Buckling Beam Probe Arrays and Methods for |
| (P-US390-A-MF) | Making Such Arrays Including Forming Probes with Lateral |
| | Positions Matching Guide Plate Hole Positions and |
| | Integrating Guides” |
| 17/139,925 - Dec. 31, 2020 | NP OF 379-B |
| (P-US398-A-MF) | Veeramani, “Probes with Planar Unbiased Spring Elements |
| | for Electronic Component Contact and Methods for Making |
| | Such Probes” |
| 17/139,933 - Dec. 31, 2020 | NP OF 381-B |
| (P-US399-A-MF) | Wu, “Compliant Pin Probes with Multiple Spring Segments |
| | and Compression Spring Deflection Stabilization Structures, |
| | Methods for Making, and Methods for Using” |
| 17/139,936 - Dec. 31, 2020 | NP OF 382-B |
| (P-US400-A-MF) | Wu, “Probes with Multiple Springs, Methods for Making, and |
| | Methods for Using” |
| 17/139,940 - Dec. 31, 2020 | NP OF 383-B |
| (P-US401-A-MF) | Wu, “Compliant Pin Probes with Flat Extension Springs, |
| | Methods for Making, and Methods for Using” |
| 17/240,962 - Apr. 26, 2021 | NP OF 390-A |
| (P-US405-A-MF) | Lockard, “Buckling Beam Probe Arrays and Methods for |
| | Making Such Arrays Including Forming Probes with Lateral |
| | Positions Matching Guide Plate Hole Positions” |
| 63/217,721 - Jul. 1, 2021 | Wu, “Compliant Pin Probes with Extension Springs, Methods |
| P-US402-B-MF | for Making, and Methods for Using” |
| 63/214,625 - Jun. 24, 2021 | Veeramani, “Probes with Planar Unbiased Spring Elements |
| P-US403-A-MF | for Electronic Component Contact and Methods for Making |
| | Such Probes” |
| 63/217,216 - Jun. 20, 2021 | Veeramani, “Multi-Beam Probes with Decoupled Structural |
| P-US404-A-MF | and Current Carrying Beams and Methods of Making” |
| 17/320,173 - May 13, 2021 | Lockard, “Vertical Probe Arrays and Improved Methods for |
| P-US406-A-MF | Making Using Temporary or Permanent Alignment Structures |
| | for Setting or Maintaining Probe-to-Probe Relationships” |

Electrochemical Fabrication:

Electrochemical fabrication techniques for forming three-dimensional structures from a plurality of adhered layers have been, and are being, commercially pursued by Microfabrica® Inc. (formerly MEMGen Corporation) of Van Nuys, California under the process names EFAB and MICA FREEFORM®.

Various electrochemical fabrication techniques were described in U.S. Pat. No. 6,027,630, issued on Feb. 22, 2000 to Adam Cohen.

A related method for forming microstructures using electrochemical fabrication techniques is taught in U.S. Pat. No. 5,190,637 to Henry Guckel, entitled “Formation of Microstructures by Multiple Level Deep X-ray Lithography with Sacrificial Metal Layers”.

FIGS. 1A-1I illustrate side views of various states in an example multi-layer, multi-material electrochemical fabrication process. FIGS. 1A-1G illustrate various stages in the formation of a single layer of a multi-layer fabrication process where a second metal is deposited on a first metal as well as in openings in the first metal so that the first and second metals form part of the layer. In FIG. 1A, a side view of a substrate 182 having a surface 188 is shown, onto which patternable photoresist 184 is deposited, spread, or cast as shown in FIG. 1B. In FIG. 1C, a pattern of resist is shown that results from the curing, exposing, and developing of the resist. The patterning of the photoresist 184 results in openings or apertures 192(a)-192(c) extending from a surface 186 of the photoresist through the thickness of the photoresist to surface 188 of the substrate 182. In FIG. 1D, a metal 194 (e.g. nickel) is shown as having been electroplated into the openings 192(a)-192(c). In FIG. 1E, the photoresist has been removed (i.e. chemically stripped) from the substrate to expose regions of the substrate 182 which are not covered with the first metal 194. In FIG. 1F, a second metal 196 (e.g. silver) is shown as having been blanket electroplated over the entire exposed portions of the substrate 182 (which is conductive) and over the first metal 194 (which is also conductive). FIG. 1G depicts the completed first layer of the structure which has resulted from the planarization of the first and second metals down to a height that exposes the first metal and sets a thickness for the first layer. In FIG. 1H, the result of repeating the process steps shown in FIGS. 1B-1G several times to form a multi-layer structure is shown where each layer consists of two materials. For most applications, one of these materials is removed as shown in FIG. 1I to yield a desired 3-D structure 198 (e.g. component or device).

Electrochemical Extrusion

Another method for forming three-dimensional structures was described in U.S. patent application Ser. Nos. 10/272,255, 10/272,254, and 10/271,574, now respectively U.S. Pat. Nos. 7,163,614, 7,172,684, and 7,288,178. These patents describe electrochemical extrusion (or ELEX) methods that may be used to form elongated structures with vertical, curved, or even stair-stepped configurations.

A first example of such an ELEX method is illustrated in FIGS. 2A-2F (i.e. FIGS. 5A-5F of the '178 patent) wherein a relatively thin mask (i.e. much thinner than the masks used in LIGA) is provided that can be moved independently of the substrate during deposition of material so as to form a structure by what may be considered electrochemical extrusion. FIG. 2A illustrates a mask 202 that includes a support portion 204 (e.g. a rigid or dimensionally stable structure) and a conformable portion 206, an electrode 208 that may function as an anode, a substrate 210, and a bellows 220 and bellows chamber 212 that are located within a deposition tank 214 that can hold an electrolyte 216 (shown in FIG. 2B). The open side of the bellows 220 connects to and seals with a perimeter region of the mask 202. This sealing makes the openings through the mask the only paths between the inside and outside of the bellows. Next, as shown in FIG. 2B, the substrate 210 and the mask 202 are pressed against each other, and the tank 214 is filled with electrolyte 216 in such a manner that the electrolyte does not become located in the region 212 between the substrate and the bellows. As shown in FIG. 2C, a potential is applied between the anode 208 and the substrate 210 (which acts as a cathode) via power source 222 and wires 224 and 226. The potential is supplied with a polarity and current that allows a deposition 238 to begin forming on the substrate at an appropriate rate. The primary source of the deposition material is preferably the anode 208 with potentially some deposition material being supplied directly by the electrolyte.

After the deposition thickens to a desired height, the substrate and the mask begin to separate at a desired rate. The average rate of separation is preferably approximately equal to the average rate of deposition such that a deposition zone and a location on the mask surface stay in the same approximate position throughout the deposition operation with the exception of the initial portion of the deposition that occurs before movement begins. During separation, the sidewalls 232 of the mask seal with the sidewalls 234 of the growing deposit 238 such that the electrolyte does not enter the bellows chamber 212. In one embodiment, the deposition rate and the movement occur in such a manner that the position of the deposition stays at a position 240 relative to the face surface 236 of the mask resulting in a separation of “L”. In other embodiments though, the average deposition rate and the separation rate are approximately equal, and actual separation may occur in discrete and discontinuous steps while the deposition may occur in a continuous manner or in a discontinuous manner. Deposition and movement may occur in an alternating manner at different times. In some embodiments, the working surface may extend into the support region of the mask.

FIG. 2D depicts the state of deposition after the deposit thickness has grown to several times the thickness of the original mask and even more times the thickness of the conformable material portion 206 of the mask. FIG. 2E depicts the state of the process after the deposit 238 has grown to become the completed structure 242. FIG. 2F depicts the combined substrate 210 and structure 242 after being removed from the apparatus of FIGS. 2A-2E.

A second example of an ELEX method is set forth in FIG. 3 (i.e. FIG. 6 of the USP '178 patent) which illustrates a side view of a structure 342 formed by electrochemical extrusion of material onto substrate 310 via mask 302. During the formation of the structure 342, not only was there a perpendicular separation of the planes of the mask 302 and substrate 310 surfaces but there was also motion that had a component parallel to the planes of the mask and substrate surfaces. The parallel component of motion may include translational motion or may include rotational motion around an axis that has a component that is perpendicular to a plane of the mask surface (i.e. the face of the conformable material) or of a contact face of the substrate surface.

Electrochemical fabrication provides the ability to form prototypes and commercial quantities of miniature objects, parts, structures, devices, and the like at reasonable costs and in reasonable times. In fact, electrochemical fabrication is an enabler for the formation of many structures that were hitherto impossible to produce. Electrochemical fabrication opens the spectrum for new designs and products in many industrial fields. Even though electrochemical fabrication offers this new capability and it is understood that electrochemical fabrication techniques can be combined with designs and structures known within various fields to produce new structures, certain uses for electrochemical fabrication provide designs, structures, capabilities and/or features not known or obvious in view of the state of the art.

A need exists in various fields for miniature devices having improved characteristics, improved operational capabilities, reduced fabrication times, reduced fabrication costs, simplified fabrication processes, greater versatility in device design, improved selection of materials, improved material properties, more cost effective and less risky production of such devices, and/or more independence between geometric configuration and the selected fabrication process.

### SUMMARY OF THE INVENTION

It is an object of some embodiments of the invention to provide an improved method of forming probe arrays or subarrays from probe preforms (i.e. vertical column like structures with or without features, curvature, or bends along their lengths, e.g. columnar structures) that are built up with lateral positions corresponding to a desired array pattern, at one or more longitudinal heights, and corresponding to through holes associated with one or more deformation plates that may be engaged with the probe preforms prior to completing their formation or after completion of probe preforms and thereafter using the deformation plates to plastically shape the probe preforms into probes of desired configuration, whereafter the deformation plate(s) may be removed or retained as guide plates or other array structures (e.g., retention structures).

It is an object of some embodiments of the invention to provide one or more deformation plates directly or indirectly on a build substrate and thereafter to form an array or subarray of probe preforms in lateral alignment with the one or more deformation plates wherein: (1) one longitudinal end of each of the probe preforms extends into, or possibly completely through, the holes in the one or more deformation plates when those ends are formed, or (2) the probe preforms do not extend into the holes in the one or more deformation plates upon formation but extend into the holes after at least partial or complete formation of the probe preforms (e.g. upon removal of a portion of a material that holds the probe preforms in their relative lateral positions which could be followed by relative movement of the deformation plate with respect to a local longitudinal axis of the probe preforms or a longitudinal axis of the probe preform array as a whole), and thereafter using the one or more deformation plates to plastically shape the probe preforms into probes of desired configuration while in an array or subarray formation, whereafter the deformation plates may be removed or retained as one or more guide plates or one or more other array structures (e.g. retention structures).

It is an object of some embodiments of the invention to laterally align one or more deformation plates and MEMS probe preforms (e.g. probe preforms formed by a mems fabrication process such as a single layer or multi-layer, multi-material electrochemical formation process) after only partial longitudinal formation of the probe preforms in an array or subarray configuration; and then after such lateral alignment, finishing the longitudinal formation of the probe preforms wherein: (1) a portion of a masking or sacrificial material is removed after the lateral alignment of the one or more deformation plates to the probe preforms which in turn allows the one or more deformation plates to be moved longitudinally so that probe preforms extend at least partially into the through holes, if not completely through the holes, of the one or more deformation plates, and thereafter continuing longitudinal formation of the probes, or (2) prior to laterally aligning the partially formed probe preforms and the one or more deformation plates, exposing the ends of the probe preforms (e.g. by removal of sacrificial or masking material) so that they may be engaged with one or more deformation plates, and then laterally and longitudinally aligning the probe preforms and the deformation plates such that the ends of the partially formed probe preforms extend at least part way into the holes, if not completely through holes; and thereafter continuing longitudinal formation of the probe performs, and thereafter using the one or more deformation plates in plastically shaping the probe preforms into probes of desired configuration, whereafter the one or more deformation plates may be removed or retained as array structures (e.g., guide plates or other probe retention structures).

It is an object of some embodiments of the invention to laterally and longitudinally align one or more deformation plates with a plurality of probe preforms that were formed together with positions corresponding to holes existing in deformation plates or that will be made to exist in the deformation plates wherein: (1) a portion of a masking or sacrificial material is removed after the lateral alignment of the one or more deformation plates to the probe performs which in turn allows the one or more deformation plates to be relatively moved longitudinally so that probe preforms extend at least partially into the through holes, after which, if necessary, further removal of masking or sacrificial material may occur to allow further longitudinal engagement of probe performs with the one or more deformation plates, or (2) prior to laterally aligning the formed probe preforms and the one or more deformation plates, exposing the ends of the probe preforms (e.g. by removal of sacrificial or masking material) so that they may be engaged with one or more deformation plates, and then laterally and longitudinally aligning the probe preforms and the deformation plates such that the ends of the probe preforms extend at least part way into the holes, if not completely through holes; and thereafter if necessary continuing the removal of masking or sacrificial material to allow further longitudinal engagement of the probe preforms with the one or more deformation plates.

It is an object of some embodiments of the invention to form one or more deformation plates while in lateral alignment with probe preform arrays where: (1) one or more deformation plates are formed directly or indirectly on a probe substrate prior to the formation of the probe preforms, (2) one or more deformation plates are formed in lateral alignment with partially formed probe preforms and are then moved longitudinally such that ends of the partially formed probe preforms at least partially extend into the through holes of the one or more deformation plates, (3) one or more deformation plates are formed in lateral alignment and longitudinal alignment with the partially formed probe preforms such that the ends of the partially formed probe preforms at least partially extend into the through holes of the one or more deformation plates, (4) one or more deformation plates are formed in lateral alignment with completed probe preforms and are then moved longitudinally such that ends of the formed probe preforms extend through the through holes of the one or more deformation plates, or (5) one or more deformation plates are formed in lateral alignment and longitudinal alignment with the completed probe preforms such that the ends of the partially formed probe preforms extend through the through holes of the one or more deformation plates as the deformation plates are formed.

It is an object of some embodiments of the invention to form one or more deformation plates while in lateral alignment with probe preform arrays where the formation of the one or more deformation plates includes: (1) locating a plate of material relative to the probe preforms and then forming through holes in the plate in lateral alignment with the locations of the probe preforms in the probe preform array, (2) providing coating over the end of completed or partially formed probe preforms to provide a temporary expansion of probe preform cross-section in the longitudinal position of the probe preforms where deformation plate formation is to occur, locating at least one deformation plate material in depositable, flowable, spreadable, or sprayable form around at least part of the expanded cross-sectional portions of the probe preforms; solidifying the deformation plate material if not solidified upon deposition; and possibly planarizing the deformation plate material before or after solidification, or (3) at a longitudinal level not occupied by probe preforms or partially formed probe preforms, locating a masking material in locations where through holes of a deformation plate are to exist; locating at least one deformation plate material in depositable, flowable, spreadable, or sprayable form around the sides of the masking material; solidifying the deformation plate material if not solidified upon deposition; and possibly planarizing the deformation plate material before or after solidification and thereafter removing the masking material and positioning the deformation plate longitudinally to engage the partially, or completely, formed probe preforms.

It is an object of some embodiments of the invention to provide improved methods of simultaneously engaging a plurality of partially formed or fully formed probe preforms with one or more deformation plates having through holes set in an intended array configuration that will engage the probe preforms and allow manipulation of the preforms to reconfigure the preforms into probe configurations.

It is an object of some embodiments of the invention to ensure that completely formed probe preforms or partially formed probe preforms are in an intended configuration at the time of engaging one or more deformation plates having that configuration.

It is an object of some embodiments of the invention to provide lateral alignment and then longitudinal engagement of at least one deformation plate with a plurality of probe preforms or partially formed probe preforms, where the preforms are formed in a lateral array configuration, and thereafter, causing one or more lateral and possibly longitudinal movements of at least one deformation plate with respect to another deformation plate or with respect to a substrate so as to provide one or more permanent deformations of the probe preforms (e.g. lateral shifting of opposite ends of the probe preforms or intermediate portions of the preforms relative to the ends) compared to their initial positions, and then either retaining the at least one deformation plate as a guide plate, or removing the at least one deformation plate from the array.

It is an object of some embodiments of the invention to reduce errors in probe preform placement prior to engaging probe preforms and deformation plates.

It is an object of some embodiments of the invention to reduce the time and/or effort of producing probe arrays (e.g. buckling beam probe arrays).

It is an object of some embodiments of the invention to reduce the cost of production of forming probe arrays or probe heads (e.g. buckling beam probe arrays or probe heads).

It is an object of some embodiments of the invention to provide improved methods of fabricating probe arrays. Some such methods may include use of only (i.e., will be limited to) multi-layer, multi-material electrochemical fabrication methods that fabricate the entire probe arrays in fully configured states. Other methods may combine separately formed arrays (or subarrays) laterally with other arrays (or subarrays) to formed larger tiled arrays where lateral subarray combining may occur after sacrificial material release, prior to sacrificial material release, before or after lateral shifting of deformation plates relative to other deformation plates or substrates to cause probe preform deformation or even complete probe formation. Other methods may include in situ steps or operations or post layer steps or operations that provide for conformable coating of specialized materials over probe preforms or probe elements, selected portions of probe preforms or entire probe preforms, selected portions of probes or entire probes (e.g. dielectrics for isolation of probe preforms or probes from one another, dielectrics for electrical isolation of a portion of one probe preform or probe from another portion of the same probe preform or probe, e.g. for coaxial configurations, contact materials, bonding materials, adhesion enhancement materials, barrier materials, and the like). Other methods may include formation of intentionally extended single layer contact surfaces that allow uninhibited movement of slidable probe or probe preform components through deformation plates even in the presence of unintended layer features (e.g. layer-to-layer offsets or non-perpendicular intra-layer wall configurations). Still other methods may include setting probe or probe preform orientation relative to layer planes and layer stacking directions to allow optimal creation of probe preforms, probes, and array features. Other steps or operations may be provided or features formed in probe preforms, probes, probe arrays, or guide plates that provide features of opposed slidable, or otherwise movable, probe preform or probe elements in build locations that allow minimum feature size gaps to exist which are larger than gaps desired when the probes are in operational configurations along with formation of spring loaded stops, snap-together features, or other structures that allow enforcement of working locations or working regions that are distinct from build locations.

It is an object of some embodiments of the invention to provide an improved method of forming probe arrays that decouple a cost for forming an array from the number of probes in the array.

It is an object of some embodiments of the invention to provide an improved method of forming probe arrays that at least partially decouple a cost for forming the array from the number of probes in the array by eliminating or reducing labor cost associated with assembling of individual probes into the array configuration, by allowing for assembly of probe arrays or probe preform arrays from groups of probes where individual groups each include a plurality of probes that are formed together in an array configuration.

It is an object of some embodiments of the invention to provide an improved method of forming probe arrays that at least partially decouple a lead time for forming the array from the number of probes in the array.

It is an object of some embodiments of the invention to provide an improved method of forming probe arrays that decouple a lead time for forming probes and probe arrays from such probes from the number of probes in the array by eliminating or reducing time associated with assembling of individual probes into the array configuration, by allowing for assembly of probe arrays or probe preform arrays from groups of probes where individual groups each include a plurality of probes or probe preforms that are formed together in an array configuration.

It is an object of the invention to provide probes with configurations that are angled, or have multiple angles relative to a longitudinal axis of a probe array with reduced numbers of stair-steps, eliminated stairsteps associated with probes formed from a plurality of stacked layers, or with stair stepping decoupled from a longitudinal and a lateral axis of a probe array.

Other objects and advantages of various embodiments of the invention will be apparent to those of skill in the art upon review of the teachings herein. The various embodiments of the invention, set forth explicitly herein or otherwise ascertained from the teachings herein, may address one or more of the above objects alone or in combination, or alternatively may address some other object ascertained from the teachings herein. It is not intended that all objects, or even multiple objects, be addressed by any single aspect or embodiment of the invention even though that may be the case regarding some aspects.

In a first aspect of the invention, a method of forming a probe array, includes: (a) providing a build substrate; (b) forming a plurality of probe preforms with one end of each probe preform formed directly or indirectly on the build substrate and with the other end of each probe preform extending away from the build substrate and with the plurality of probe preforms formed in a lateral pattern with a desired array spacing; (c) providing at least one deformation plate having a plurality of holes having a lateral pattern matching at least a portion of the lateral pattern of the plurality of probe preforms; (d) engaging matching holes of the at least one deformation plate with matching probe preforms; (e) locating the at least one deformation plate at a longitudinal height (or heights) relative to the probe preforms that corresponds to at least one deformation level for the plurality of probe preforms; (f) changing the lateral position of the at least one deformation plate with respect to an element selected from the group consisting of: (1) the build substrate, (2) a transfer substrate, and (3) a different deformation plate that also engages the matching probe preforms but at a different longitudinal height, such that the change in lateral positioning induces a plastic deformation into each of the matching probe preforms at the least one deformation level to introduce at least one permanent bend or deformation in each of the plurality of matching probe preforms, whereby the at least one deformation provides probes from the probe preforms where in each probe has a desired probe configuration, and whereby a combination of the probes and at least one element selected from the group consisting of: (1) the substrate; (2) at least one deformation plate that is retained as a guide plate; (3) a transfer substrate, different from the build substrate, to which the probes are attached; and (4) at least one guide plate that was not previously used as a deformation plate that is made to engage the probes, form at least part of the probe array.

Numerous variations of the first aspect of the invention exist and include for example: (A) the at least one deformation plate including a plurality of deformation plates that each engage multiple probe preforms and simultaneously introduce permanent deformation in a plurality of probe preforms at multiple heights; (B) the at least one deformation plate including a plurality of deformation plates that each engage multiple probe preforms and that are used to introduce permanent deformation in a plurality of probe preforms simultaneous at at least one height after which at least one of the plurality of deformation plates is moved to introduce additional permanent deformation at at least one different height; (C) a stabilization material or plate that is positioned to hold the probe preforms to the substrate during deformation; (D) the probe preforms being formed from a plurality of layers of deposited material; (E) the probe preforms being formed from a single deposition of material that extends from a lower portion of the probe preforms to an upper portion of the probe preforms; (F) the probes in the probe array including similar bends at similar longitudinal levels; (G) some probes in the probe array including bends and/or longitudinal heights of bends or deformations that are different from the bends and/or longitudinal heights of the bends or deformations of other probes which form part of the array; (H) the probe array when complete having a configuration selected from the group consisting of (1) the probe array not including the build substrate; (2) the probe array not including any substrate; (3) the probe array not including a guide plate; (4) the probe array including at least one guide plate; (5) the probe array when complete includes at least two guide plates; and (6) the probe array not including a substrate; (I) the providing of the at least one deformation plate includes forming a deformation plate in lateral alignment with probe preforms; (J) the providing of the at least one deformation plate and the engaging of the deformation plate includes forming a deformation plate in lateral and longitudinal alignment with probe preforms; (K) the at least one deformation plate being engaged with at least a portion of the probe preforms prior to complete release of the probe preforms from a sacrificial material such that sacrificial material provides some lateral support for holding the probe preforms in their respective lateral positions during engagement; (L) the probe preforms being formed using an electrochemical fabrication process; (M) variation L wherein the electrochemical fabrication process is a multi-layer electrochemical fabrication process; (N) variation M, wherein the multi-layer electrochemical fabrication process includes deposition of at least one structural material and at least one sacrificial material during the formation of each of a plurality of successive layers wherein each successive layer has its boundaries set by one or more planarization operations; and (O) variation N, wherein at least one layer includes a permanent stabilization material selected from the group consisting of (1) a sacrificial material that is removed after deformation is completed; (2) a material that is a structural material that remains as part of the probe array; (3) a material that functions as a patterning material for deposition of probe preform material; and (4) a material is deposited after removal of a patterning material that was used in depositing of probe preform material. Other variations are also possible and include for example variations of the variations noted above mutatis mutandis, elements or features found in the various embodiments or objects of the invention as set forth herein or variations of the elements or features of such embodiments or objects.

In a second aspect of the invention, a method for forming a probe array, includes: (a) providing a substrate; (b) forming a plurality of probe preforms with one end of each probe preform formed directly or indirectly on the build substrate and with the other end of each probe preform extending away from the build substrate and with the plurality of probe preforms formed in a lateral pattern with a desired array spacing; (c) creating at least one deformation plate having a plurality of holes having a lateral pattern matching at least a portion of the lateral pattern of the plurality of probe preforms, wherein the at least one deformation plate upon creation has holes therein that are aligned laterally with the probe preforms, and wherein either during or after creation of the at least one deformation plate, longitudinally engaging the holes in the deformation plate with matching probe preforms or partially formed matching probe preforms; (d) as necessary locating the at least one deformation plate at at least one longitudinal height relative to the probe preforms that corresponds to at least one deformation level for the matching plurality of probe preforms; (f) changing the lateral position of the at least one deformation plate with respect to an element selected from the group consisting of: (1) the substrate, and (2) a different deformation plate that also engages the matching plurality of probe preforms at a different longitudinal height, such that the change in lateral positioning induces a plastic deformation into each of the matching probe preforms at the least one deformation level to introduce at least one permanent bend or deformation in each of the plurality of matching probe preforms; whereby the at least one deformation provides probes from deformed probe preforms with a desired probe configuration, and whereby a combination of the probes and at least one element selected from the group consisting of: (1) the substrate; (2) at least one deformation plate that is retained as a guide plate; (3) a separate substrate to which the probes are attached; and (4) at least one guide plate that was not previously used as a deformation plate that is made to engage the probes, form at least part of the probe array.

Numerous variations of the second aspect of the invention are possible and include for example the variations noted for the first aspect of the invention, elements or features found in the various embodiments or objects of the invention as set forth herein or variations of the elements or features of such embodiments or objects.

In other aspects of the invention, methods of forming probe arrays using at least one deformation plate include functional combinations or subcombinations of steps, functionalities, or features along with functional orders for using those steps, functionalities, or features found or ascertainable from the generalized embodiments, alternative implementations of those generalized embodiments, the specific embodiments, or alternative implementations of those specific embodiments.

In other aspects of the invention, methods of forming a probe array using at least one deformation plate include the steps, functionality, and/or features noted in the above objects of the invention as (1) individually set forth, (2) set forth in separate alternatives noted with regard to some objectives, or (3) set forth in a combination of such objectives or separate alternatives for those objectives, so long as the combination does not completely remove all the benefits offered by each of the separate objectives or alternatives.

In other aspects of the invention, a probe array is provided that has at least one guide plate and includes the functionality or features noted in the above objects of the invention as (1) individually set forth, (2) set forth in separate alternatives noted with regard to some objectives, or (3) set forth in a combination of such objectives or separate alternatives for those objectives, so long as the combination does not completely remove all the benefits offered by each of the separate objectives or alternatives.

In other aspects of the invention, subcombinations of steps, functionalities, or features as set forth in the generalized embodiments, alternative implementations of those generalized embodiments, the specific embodiments, or alternative implementations of those specific embodiments are included in a combination or subcombination in any functional manner to achieve one of the objectives noted herein, or as ascertained from the teachings herein (i.e. as directly set forth or set forth by incorporation).

Other aspects of the invention will be understood by those of skill in the art upon review of the teachings herein and for example may include alternatives in the configurations or processes set forth herein, decision branches noted in those processes or configurations, or partial or complete exclusion of such alternatives and/or decision branches in favor of explicitly setting forth process steps or features along with orders to be used in performing such steps or connections between such features. Some aspects may provide device counterparts to method of formation aspects, some aspects may provide method of formation counterparts to device aspects, and other aspects may provide for methods of use for the probe arrays provided herein.

### BRIEF DESCRIPTION OF THE DRAWINGS

FIGS. 1A-1F schematically depict the formation of a first layer of a structure using adhered mask plating where the blanket deposition of a second material overlays both the openings between deposition locations of a first material and the first material itself.

FIG. 1G depicts the completion of formation of the first layer resulting from planarizing the deposited materials to a desired level.

FIGS. 1H and 1I respectively depict the state of the process after formation of the multiple layers of the structure and after release of the structure from the sacrificial material.

FIGS. 2A-2F provide illustrations of an example set up and operation of an ELEX process for forming a plurality of longitudinally extended structures.

FIG. 3 provides an illustration of an ELEX formation process that provides a structure with varying cross-sectional formation offsets (or lateral offsets) that may be generated during the formation of a longitudinally elongated structure.

FIG. 4 provides a generalized flowchart for fabricating probe arrays that include a plurality of probe preforms formed with lateral positions corresponding to an array pattern, one or more deformation plates formed or positioned to engage the probe preforms, and possibly a substrate on which the probes are formed or attached after formation wherein the formation of the probes includes at least one step of laterally moving one or more deformation plates to cause plastic deformation of probe preforms to provide non-biased probe configurations.

FIG. 5 provides a block diagram setting forth a number of example alternative processes that may be used in forming probe preforms.

FIG. 6A provides a block diagram listing a number of examples of different build substrates on which probe preforms may be formed.

FIG. 6B provides a block diagram listing a number of examples relating to substrate transfer and release.

FIG. 6C provides a block diagram that sets forth a number of examples related to tiling of subarrays with respect to one another to form larger probe arrays.

FIG. 7A provides a block diagram setting forth a number of examples of how deformation plates may be positioned relative to probe preforms that have been formed or are being formed and alternatively how deformation plates may be formed relative to probe preforms that have been formed or are being formed.

FIG. 7B provides a block diagram setting forth two examples of how deformation plates and probe preforms may be laterally aligned.

FIG. 8 provides a simplified flowchart of a first specific embodiment of the invention for forming a probe array with a deformation plate inserted from above after probe preform formation and after partial removal of a sacrificial material wherein the deformation plate may be removed from the final probe array or may be retained as a guide plate or other array structure.

FIGS. 9A-9I provide cut side views of example results of the steps set forth in operational Blocks A-I of FIG. 8.

FIG. 10 provides a simplified flowchart of a second specific embodiment of the invention for forming a probe array with a base support material added before or during probe preform formation and a deformation plate inserted from above after probe preform formation and after partial removal of a sacrificial material wherein the deformation plate may be removed from the final probe array or may be retained as a guide plate or other array structure.

FIGS. 11A-11I provide cut side views of example results of the steps set forth in operational Blocks A-I of FIG. 10.

FIG. 12 provides a simplified flowchart of a third specific embodiment of the invention for forming a probe array with a base deformation plate (i.e., a preform stabilization plate) added before or during probe preform formation and a second deformation plate inserted from above after probe preform formation and after partial removal of a sacrificial material wherein the second deformation plate may be removed from the final probe array or may be retained as a guide plate or other array structure.

FIGS. 13A-13I provide cut side views of example results of the steps set forth in operational Blocks A-I of FIG. 12.

FIG. 14 provides a simplified flowchart of a fourth specific embodiment of the invention for forming a probe array with a deformation plate inserted from above after probe preform formation and after partial removal of a sacrificial material along with a base support material (i.e. preform stabilization material) added after probe preform formation and after completing removal of the sacrificial material wherein the deformation plate may be removed from the final probe array or may be retained as a guide plate or other array structure.

FIGS. 15A-15K provide cut side views of example results of the steps set forth in operational Blocks A-K of FIG. 14.

FIG. 16 provides a simplified flowchart of a fifth specific embodiment of the invention for forming a probe array with a base support deformation plate and a second deformation plate inserted from above after probe preform formation and after partial removal of a sacrificial material wherein the second deformation plate may be removed from the final probe array or may be retained as a guide plate or other array structure.

FIGS. 17A-17I provide cut side views of example results of the steps set forth in operational Blocks A-I of FIG. 16.

FIG. 18 provides a simplified flowchart of a sixth specific embodiment of the invention for forming a probe array using a plurality of deformation plates inserted from above after probe preform formation and partial removal of sacrificial material that can be used in creating multiple plastic deformation regions in a parallel manner wherein all the deformation plates may be removed from the final probe array or one or more may be retained as guide plates or other array structures.

FIGS. 19A-19I2 provide cut side views of example results of the steps set forth in operational Blocks A-I of FIG. 18 wherein some of the steps illustrate deformation plate placement and movement that result in probes having different structural configurations.

FIG. 20 provides a simplified flowchart of a seventh specific embodiment of the invention for forming a probe array using a plurality of deformation plates inserted from above after probe preform formation and partial removal of sacrificial material that can be used in creating multiple plastic deformation regions in a serial manner (i.e. deformations of each probe at different longitudinal heights occur one after another as opposed to at the same time where different plates may be used for the different deformations or plates may be reused after repositioning to cause one or more subsequent deformations) wherein all the deformation plates may be removed from the final probe array or one or more may be retained as guide plates or other array structures.

FIGS. 21A-21J2 provide cut side views of example results of the steps set forth in operational Blocks A-J of FIG. 20 wherein some of the steps illustrate deformation plate placement and movement that result in probes having different structural configurations.

FIGS. 22A1 and 22C2 provide cut side views of example results of an embodiment similar to the sixth or seventh specific embodiments wherein the substrate on which the probe preforms are created is a temporary substrate that is spaced from the probe preforms by a release layer that is removed after probe formation and movement of at least some of the deformation plates to guide plate positions wherein the removal results in a probe array with guide plates retaining the probes in their array configuration.

### DETAILED DESCRIPTION OF PREFERRED EMBODIMENTS

Electrochemical Fabrication in General

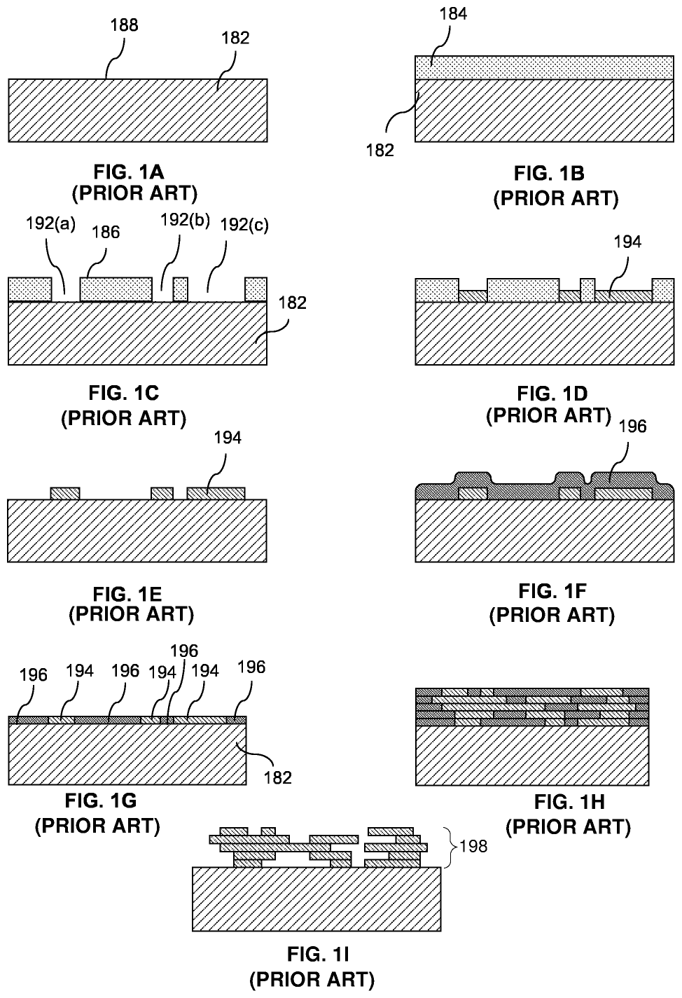

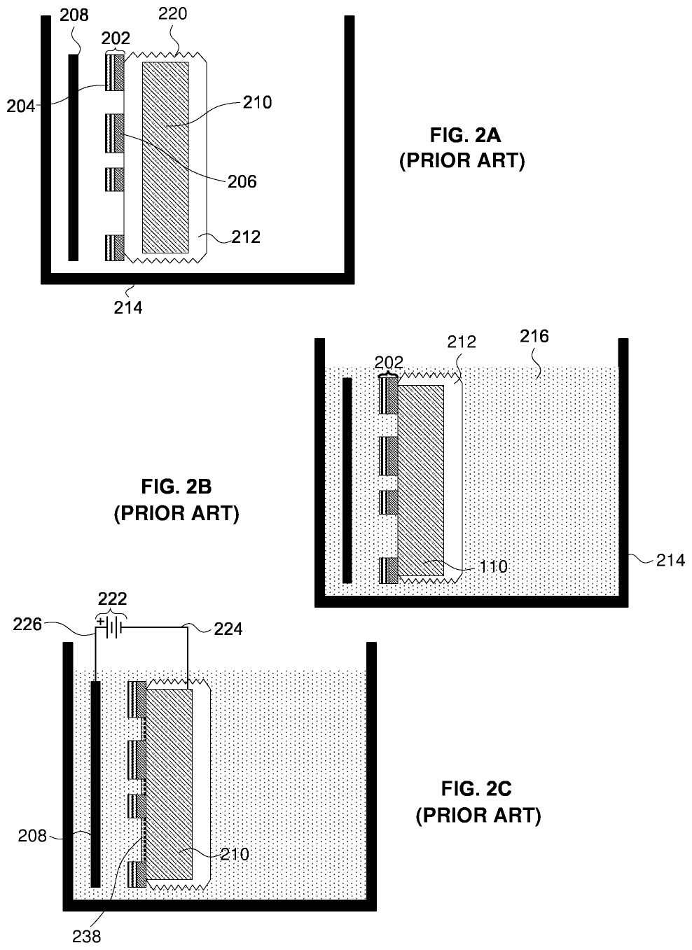

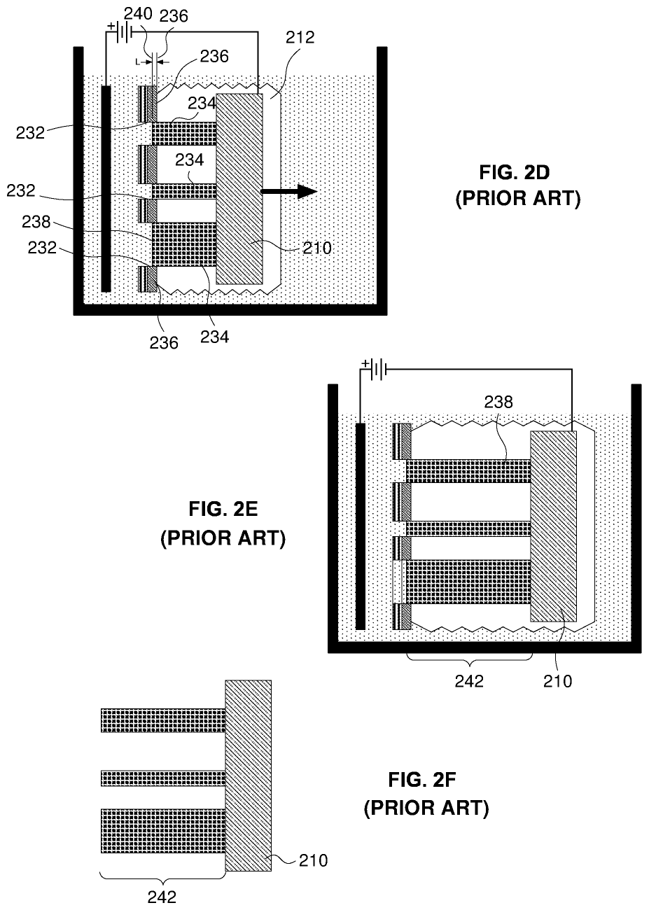

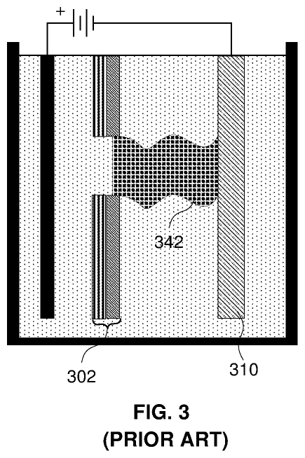

An example of a multi-layer, multi-material electrochemical fabrication process was provided above in conjunction with the illustrations of FIGS. 1A-1I. In some variations, the structure may be separated from the substrate. For example, release of the structure (or multiple structures if formed in a batch process) from the substrate may occur when releasing the structure from the sacrificial material particularly when a layer of sacrificial material is positioned between the first layer of the structure and the substrate. Alternative methods may involve, for example, the use of a dissolvable substrate that may be separated before, during, or after removal of the sacrificial material, machining off the substrate before or after removal of the sacrificial material, or use of a different intermediate material that can be dissolved, melted, or otherwise used to separate the structure(s) from the substrate before, during, or after removal of the sacrificial material that surround the structure(s).

Various embodiments of various aspects of the invention are directed to formation of three-dimensional structures from materials, some, or all, of which may be electrodeposited or electroless deposited (as illustrated in FIGS. 1A-1I and as discussed in various patents and patent applications incorporated herein by reference). Some of these structures may be formed from a single build level (e.g. a planarized layer) that is formed from one or more deposited materials while others are formed from a plurality of build levels, each generally including at least two materials (e.g. two or more layers, five or more layers, and even ten or more layers). In some embodiments, layer thicknesses may be as small as one micron or as large as one hundred to two hundred microns. In still other embodiments, layers may be up to five hundred microns, one millimeter, even multiple millimeters, or more. In other embodiments, thinner layers may be used. In still other embodiments, layer thickness may be varied during formation of different levels of the same structure. In some embodiments, microscale structures have lateral features positioned with 0.1-10 micron level precision and minimum feature sizes on the order of microns to tens of microns. In other embodiments, structures with less precise feature placement and/or larger minimum features may be formed. In still other embodiments, higher precision and smaller minimum feature sizes may be desirable. In the present application, meso-scale and millimeter-scale have the same meaning and refer to devices that may have one or more dimensions that may extend into the 0.1-50 millimeter range, or somewhat larger, and features positioned with a precision in the 0.1 micron to 100 micron range and with minimum feature sizes on the order of several microns to hundreds of microns.

The various embodiments, alternatives, and techniques disclosed herein may form multi-layer structures using a single patterning technique on all layers or using different patterning techniques on different layers. For example, various embodiments of the invention may perform selective patterning operations using conformable contact masks and masking operations (i.e. operations that use masks which are contacted to but not adhered to a substrate), proximity masks and masking operations (i.e. operations that use masks that at least partially selectively shield a substrate by their proximity to the substrate even if contact is not made), non-conformable masks and masking operations (i.e. masks and operations based on masks whose contact surfaces are not significantly conformable), adhered masks and masking operations (masks and operations that use masks that are adhered to a substrate onto which selective deposition or etching is to occur as opposed to only being contacted to it), and/or selective patterned deposition of materials (e.g. via extrusion, jetting, or controlled electrodeposition) as opposed to masked patterned deposition. Conformable contact masks, proximity masks, and non-conformable contact masks share the property that they are preformed and brought to, or in proximity to, a surface which is to be treated (i.e. the exposed portions of the surface are to be treated). These masks can generally be removed without damaging the mask or the surface that received treatment to which they were contacted or located in proximity to. Adhered masks are generally formed on the surface to be treated (i.e. the portion of that surface that is to be masked) and bonded to that surface such that they cannot be separated from that surface without being completely destroyed or damaged beyond any point of reuse. Adhered masks may be formed in a number of ways including: (1) by application of a photoresist, selective exposure of the photoresist, and then development of the photoresist, (2) selective transfer of pre-patterned masking material, (3) direct formation of masks from computer-controlled depositions of material, and/or (4) laser ablation of a deposited material.

Patterning operations may be used in selectively depositing material and/or may be used in the selective etching of material. Selectively etched regions may be selectively filled in or filled in via blanket deposition, or the like, with a different desired material. In some embodiments, the layer-by-layer build up may involve the simultaneous formation of portions of multiple layers. In some embodiments, depositions made in association with some layer levels may result in depositions to regions associated with other layer levels (i.e. regions that lie within the top and bottom boundary levels that define a different layer's geometric configuration). Such use of selective etching and/or interlaced material deposition in association with multiple layers is described in U.S. patent application Ser. No. 10/434,519, by Smalley, filed May 7, 2003, which is now U.S. Pat. No. 7,252,861, and which is entitled “Methods of and Apparatus for Electrochemically Fabricating Structures Via Interlaced Layers or Via Selective Etching and Filling of Voids”. This referenced application is incorporated herein by reference.

Temporary substrates on which structures may be formed may be of the sacrificial-type (i.e. destroyed or damaged during separation of deposited materials to the extent they cannot be reused), non-sacrificial-type (i.e. not destroyed or excessively damaged, i.e. not damaged to the extent they may not be reused, e.g. with a sacrificial or release layer located between the substrate and the initial layers of a structure that is formed). Non-sacrificial substrates may be considered reusable, with little or no rework (e.g. replanarizing one or more selected surfaces or applying a release layer, and the like) though they may or may not be reused for a variety of reasons.

Definitions of various terms and concepts that may be used in understanding the embodiments of the invention (either for the devices themselves, certain methods for making the devices, or certain methods for using the devices) will be understood by those of skill in the art. Some such terms and concepts are discussed herein while other such terms are addressed in the various patent applications to which the present application claims priority and/or which are incorporated herein by reference.

The term “longitudinal” as used herein refers to a long dimension of a probe, an end-to-end dimension of the probe, or a tip-to-tip dimension. Longitudinal may refer to a generally straight line that extends from one end of the probe to another end of the probe or it may refer to a curved or stair-stepped path that has a sloped or even changing direction along a height of the probe. When referring to probe arrays, the longitudinal dimension may refer to a particular direction the probes in the array point or extend, but it may also simply refer to the overall height of the array that starts at a plane containing a first end, tip, or base of a plurality of probes and extends perpendicular thereto to a plane containing a second end, tip, or top of the probes. The context of use typically makes clear what is meant especially to those of skill in the art. It is intended that the interpretation to be applied to the term herein be as narrow as warranted by the details of the description provided or the context in which the term is used. If however, no such narrow interpretation is warranted, it is intended that the broadest reasonable scope of interpretation apply.

The term “lateral” as used herein is related to the term longitudinal. In terms of the stacking of layers, lateral refers to a direction within each layer, or two perpendicular directions within each layer (i.e. one or more directions that lie within a plane of a layer that is substantially perpendicular to the longitudinal direction). When referring to probe arrays, laterally generally has a similar meaning in that a lateral dimension is generally a dimension that lies in a plane that is parallel to a plane of the top or bottom of the array (i.e. substantially perpendicular to the longitudinal dimension). When referring to probes themselves, the lateral dimensions may be those that are perpendicular to an overall longitudinal axis of the probe, a local longitudinal axis of the probe (that is, local lateral dimensions), or simply the dimensions similar to those noted for arrays or layers. The context of use typically makes clear what is meant especially to those of skill in the art. It is intended that the interpretation to be applied to the term herein be as narrow as warranted by the details of the description provided or the context in which the term is used. If no such narrow interpretation is warranted, it is intended that the broadest reasonable scope of interpretation apply.

Generalized Probe Array and Probe Array Formation Embodiments:

Probe arrays, methods of making probe arrays, and methods of using probe arrays can take on different forms in different embodiments of the invention.

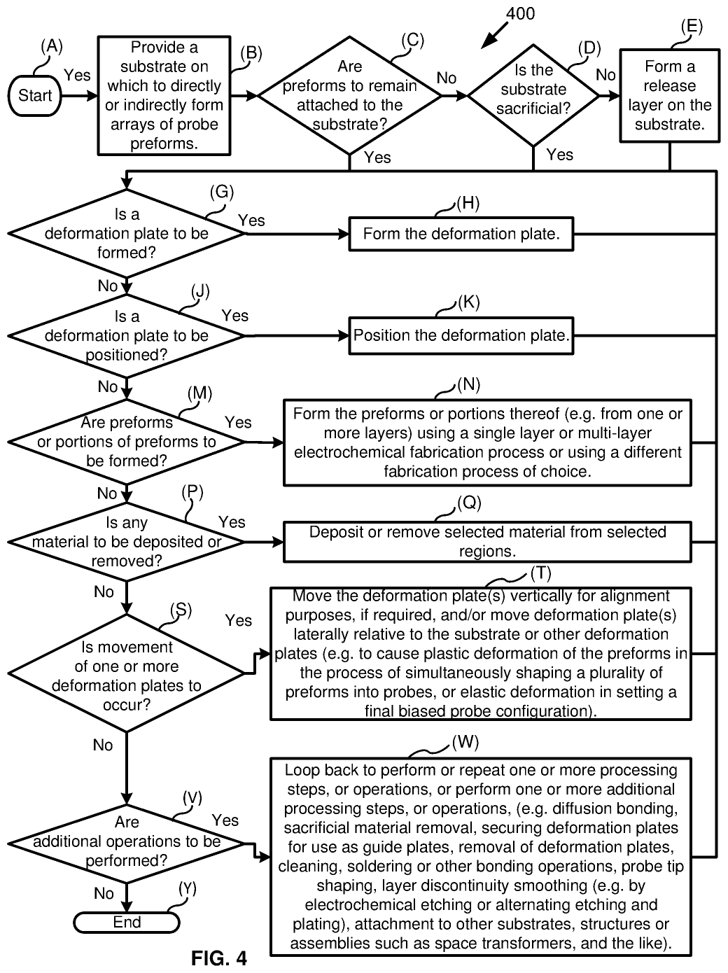

FIG. 4 provides a generalized flowchart for fabricating probe arrays that include a plurality of probe preforms formed with lateral positions corresponding to an array pattern, one or more deformation plates formed or positioned to engage the probe preforms and which may be removed from a final array structure or retained as guide plates or other array structures, and possibly a substrate on which the probe preforms are formed or preforms or probes attached after formation. The flowchart 400 of FIG. 4 includes Blocks A-Y with Blocks C, D, G, J, M, P, S, and V representing inquiries or decision Blocks, Blocks B, E, H, K, N, Q, T, and W representing process steps or groups of steps that may be performed, while Blocks A and Y represent process initiation and termination blocks respectively. It is not intended that the process of FIG. 4 represent a single process with all the indicated steps or the inquires being made one after another in the order indicated or even being performed but instead it is intended to provide a framework which may be used in defining numerous alternative processes. Some such alternatives may include most of the process steps and/or decision operations while others may include a much smaller subset of the process steps along with only some or even none of the decision operations. In actual implementations, process operations, decisions, and/or processing order may be manually implemented, implemented under machine control, programmed computer or microprocessor control, or be implemented by a combination of one or more of these. Depending on the order in which process steps are to be executed, a first loop through Blocks A-V may result in one or more steps being performed while one or more subsequent loops may repeat those steps, perform one or more other steps, or result in the performance of a combination of the two. During implementation, numerous process steps and decisions not explicitly noted in the flowchart may be performed including, for example, cleaning steps, activation steps, material annealing or tempering steps, inspection or testing steps, decisions based on the outcome of one or prior steps, removal and rework steps, and the like. In some embodiments, some steps may be split into sub-steps, other steps may be implemented between the sub-steps that have been split from one another, and/or only a portion of those sub-steps actually performed. At some point during operation of the process of FIG. 4, whether during a first pass through the process or one or subsequent processes, Block T, or its equivalent will be performed at least once and either one or both of the operations of Blocks K or N will be performed in preparation for performing the operation or operations of Block T.

More particularly, the process exemplified in FIG. 4 starts with Block A and then moves to Block B which calls for providing a substrate on which to form, directly or indirectly, an array or arrays of probe preforms. Next, in Block C, an inquiry is made as to whether the preforms are to remain attached to the substrate. If the answer to the inquiry of Block C is “yes”, the process moves to Block G. If the answer is “no”, the process moves to Block D. In Block D, an inquiry is made as to whether the substrate is sacrificial. If the answer to the inquiry of Block D is “yes”, the process moves to Block G. If the answer is “no”, the process moves to Block E. Block E calls for forming a release layer on the substrate, and then the process moves to Block G.

From the inquiry of Block C if “yes”, the inquiry of Block D if “yes”, or after the operation of Block E, as noted above, the process moves to Block G in which an inquiry is made as to whether a deformation plate is to be formed. If the answer to is “no”, the process moves to Block J. If the answer is “yes”, the process moves to Block H which calls for forming the deformation plate. After the operation or operations of Block H, the process loops back to Block G.

In Block J, an inquiry is made as to whether a deformation plate is to be positioned. If the answer is “no”, the process moves to Block M. If the answer is “yes”, the process moves to Block K which calls for positioning the deformation plate. After the operation or operations of Block K, the process loops back to Block G.

In Block M, an inquiry is made as to whether preforms or portions of preforms are to be formed. If the answer is “no”, the process moves to Block P. If the answer is “yes”, the process moves to Block N which calls for forming the preforms or portions thereof (e.g., from one or more layers) using a single layer or multi-layer electrochemical fabrication process or using a different fabrication process of choice. After the operation or operations of Block N, the process loops back to Block G.

In Block P, an inquiry is made as to whether any material is to be deposited or removed. If the answer is “no”, the process moves to Block S. If the answer is “yes”, the process moves to Block Q which calls for depositing or removing selected material from selected regions. After the operation or operations of Block Q, the process loops back to Block G.

In Block S, an inquiry is made as to whether movement of one or more deformation plates is to occur. If the answer is “no”, the process moves to Block V. If the answer to is “yes”, the process moves to Block T which calls for moving the deformation plate(s) vertically for alignment purposes, if required, and/or moving deformation plate(s) laterally relative to the substrate or other deformation plates (e.g., to cause plastic deformation of the preforms in the process of simultaneously shaping a plurality of preforms into probes, or elastic deformation in setting a final biased probe configuration). After the operation or operations of Block T, the process loops back to Block G.

In Block V, an inquiry is made as to whether additional steps are to be performed. If the answer is “no”, then the process moves to Block Y where the process ends. If the answer is “yes”, the process moves to Block W which calls for looping back to perform or repeat one or more processing steps or performing one or more additional processing steps (e.g. diffusion bonding, sacrificial material removal, securing deformation plates for use as guide plates, removal of deformation plates, cleaning, soldering or other bonding operations, probe tip shaping, layer discontinuity smoothing (e.g. by electrochemical etching or alternating etching and plating), attachment to other substrates, structures or assemblies such as space transformers, and the like). After completion of the operation or operations of Block W, the process loops back to Block G.

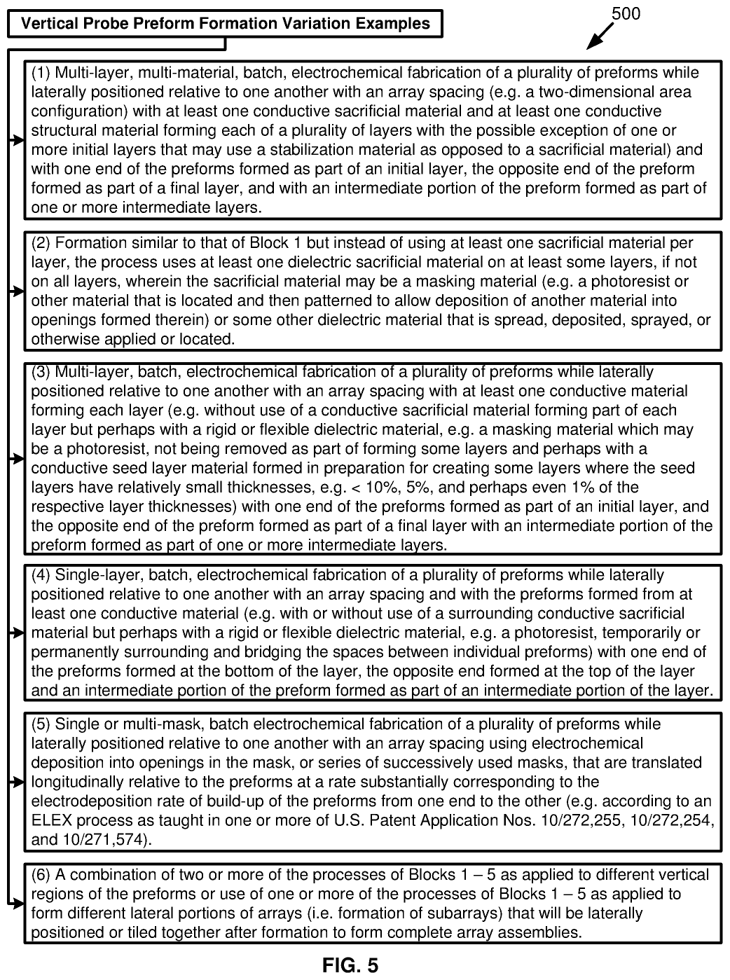

FIG. 5 provides a block diagram setting forth a number of example alternative processes that may be used in forming probe preforms. In particular, the block diagram 500 of FIG. 5 provides six example process variations 1-6 for forming probe preforms according to Block N of FIG. 4 including a multi-layer, multi-material process using conductive structural and sacrificial materials (Block 1); a multi-layer, multi-material process using a conductive structural material and dielectric sacrificial material (Block 2); a multi-layer, process using a conductive structural material, possibly an unremoved masking material, and possibly some seed layers during the formation of layers (Block 3); a single layer process (Block 4); a single or multi-mask process involving longitudinal translation of the mask during probe preform formation (Block 5); and a combination of two or more of the processes of 1-5 in forming different longitudinal portions of the probe preforms according (Block 6). Other embodiments for forming probe arrays may use other processes for forming probe preforms.

Example 1 of block diagram 500 (Block 1) more particularly provides for the multi-layer, multi-material, batch, electrochemical fabrication of a plurality of preforms while laterally positioned relative to one another with an array spacing (e.g. a two-dimensional area configuration) with at least one conductive sacrificial material and at least one conductive structural material forming each of a plurality of layers with the possible exception of one or more initial layers that may use a stabilization material as opposed to a sacrificial material) and with one end of the preforms formed as part of an initial layer, the opposite end of the preform formed as part of a final layer, and with an intermediate portion of the preform formed as part of one or more intermediate layers.

Example 2 of block diagram 500 (Block 2) more particularly provides for formation via electrochemical fabrication similar to that of example 1 but instead of using at least one sacrificial material per layer, the process uses at least one dielectric sacrificial material on at least some layers, if not on all layers, wherein the sacrificial material may be a masking material (e.g. a photoresist or other material that is located and then patterned to allow deposition of another material into openings formed therein) or some other dielectric material that is spread, deposited, sprayed, or otherwise applied or located.

Example 3 of block diagram 500 (Block 3) more particularly provides for multi-layer, batch, electrochemical fabrication of a plurality of preforms while laterally positioned relative to one another with an array spacing with at least one conductive material forming each layer (e.g. without use of a conductive sacrificial material forming part of each layer but perhaps with a rigid or flexible dielectric material, e.g. a masking material which may be a photoresist, not being removed as part of forming some layers and perhaps with a conductive seed layer material formed in preparation for creating some layers where the seed layers have relatively small thicknesses, e.g. <10%, 5%, and perhaps even 1% of the respective layer thicknesses) with one end of the preforms formed as part of an initial layer, and the opposite end of the preform formed as part of a final layer with an intermediate portion of the preform formed as part of one or more intermediate layers.

Example 4 of block diagram 500 (Block 4) more particularly provides for single-layer, batch, electrochemical fabrication of a plurality of preforms while laterally positioned relative to one another with an array spacing and with the preforms formed from at least one conductive material (e.g. with or without use of a surrounding conductive sacrificial material but perhaps with a rigid or flexible dielectric material, e.g. a photoresist, temporarily or permanently surrounding and bridging the spaces between individual preforms) with one end of the preforms formed at the bottom of the layer, the opposite end formed at the top of the layer and an intermediate portion of the preform formed as part of an intermediate portion of the layer.

Example 5 of block diagram 500 (Block 5) more particularly provides for single or multi-mask, batch electrochemical fabrication of a plurality of preforms while laterally positioned relative to one another with an array spacing using electrochemical deposition into openings in the mask, or series of successively used masks, that are translated longitudinally relative to the preforms at a rate substantially corresponding to the electrodeposition rate of build-up of the preforms from one end to the other (e.g. according to an ELEX process as taught in one or more of U.S. patent application Ser. Nos. 10/272,255, 10/272,254, and 10/271,574).

Example 6 of block diagram 500 (Block 6) more particularly provides for a combination of two or more of the processes of Blocks 1-5 of FIG. 5 as applied to different vertical regions of the preforms or use of one or more of the processes of Blocks 1-5 as applied to form different lateral portions of arrays (i.e., formation of subarrays) that will be laterally positioned or tiled together after formation to form complete array assemblies.

Other processes may be used in forming probe preforms and will be understood by those of skill in the art upon review of the teachings set forth herein or incorporated herein by reference.

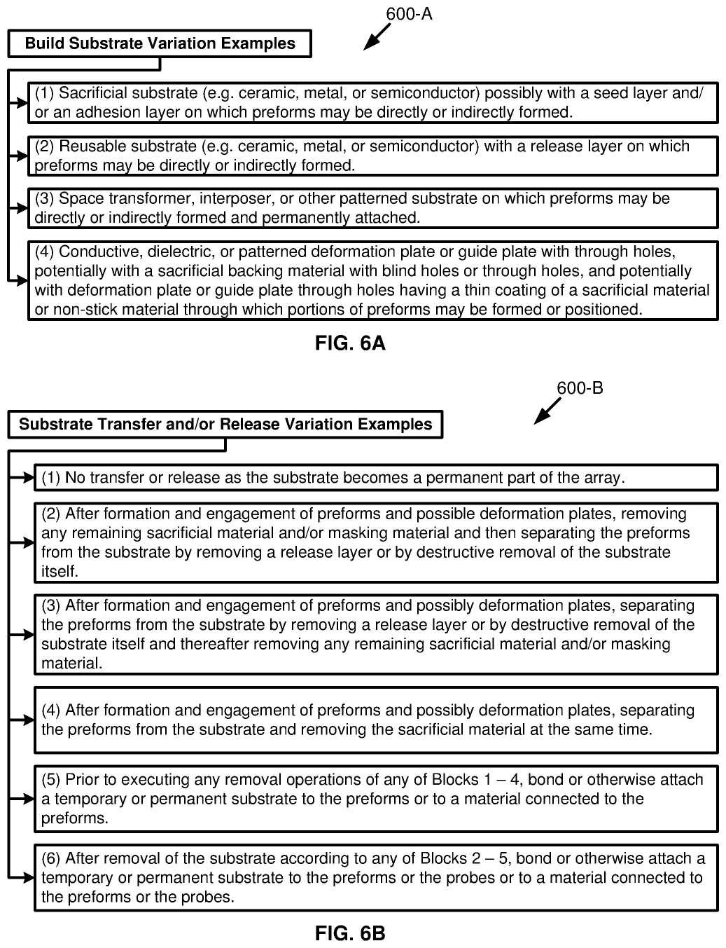

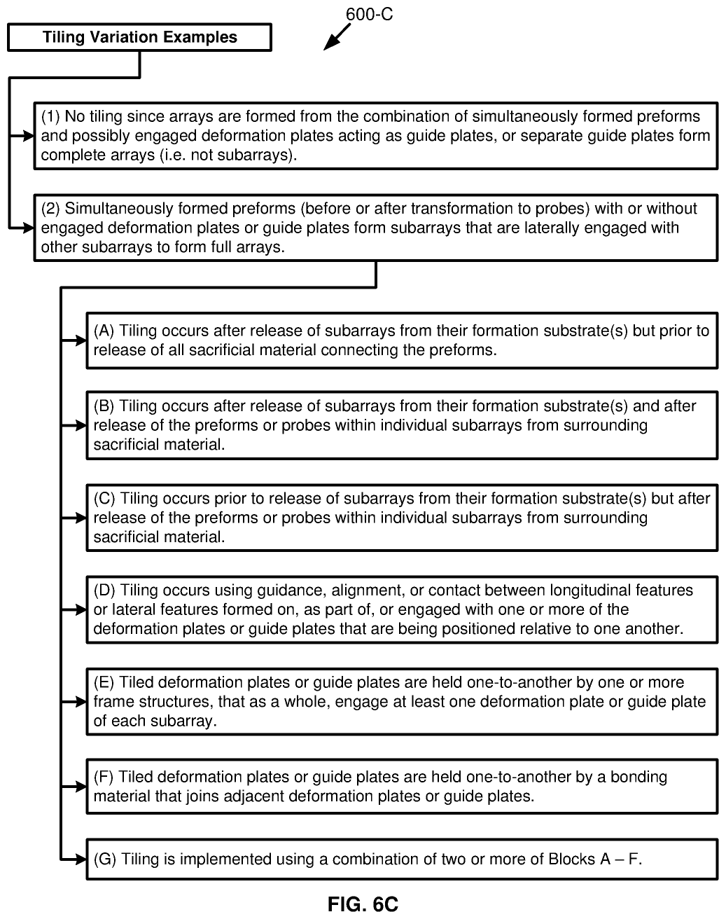

FIG. 6A provides a block diagram listing a number of examples of different build substrates on which probe preforms may be formed. In particular, block diagram 600-A of FIG. 6A provides four example substrates that may be used in Block B of FIG. 4 for probe preform formation including a sacrificial substrate (Block 1), a reusable ceramic substrate (Block 2), a space transformer or other patterned substrate (Block 3), and a deformation plate or guide plate (Block 4). Other embodiments for forming probe arrays may use other substrates for forming probe preforms.

Example 1 of FIG. 6A (Block 1) more particularly provides for a sacrificial substrate (e.g. formed of a ceramic, metal, or semiconductor material) possibly with a seed layer and/or an adhesion layer on which preforms may be directly or indirectly formed.

Example 2 of FIG. 6A (Block 2) more particularly provides for a reusable substrate (e.g. ceramic, metal, or semiconductor) with a release layer on which preforms may be directly or indirectly formed.

Example 3 of FIG. 6A (Block 3) more particularly provides for a space transformer, interposer, or other patterned substrate on which preforms may be directly or indirectly formed and permanently attached.

Example 4 of FIG. 6A (Block 4) more particularly provides for a conductive, dielectric, or patterned deformation plate or guide plate with through holes, potentially with a sacrificial backing material with blind holes or through holes, and potentially with deformation plate or guide plate through holes having a thin coating of a sacrificial material or non-stick material through which portions of preforms may be formed or positioned.

Other substrates may be used in forming probe preforms and will be understood by those of skill in the art upon review of the teachings set forth herein or incorporated herein by reference.

FIG. 6B provides a block diagram listing a number of examples relating to substrate transfer and release. In particular, block diagram 600-B provides four examples related to substrate transfer or release that may be used in association the operations of Blocks Q and/or W of FIG. 4 including a first example where no transfer or release occurs (Block 1); a second example where, after release of sacrificial material, the substrate is removed by removing a release layer or by the destructive removal of the substrate (Block 2); a third example where, before release of sacrificial material, the substrate is removed by removing a release layer or by the destructive removal of the substrate itself which is then followed by removal of the sacrificial material according (Block 3); a fourth example where the substrate and sacrificial material and/or masking material are removed at the same time (Block 4); and a fifth example where, before any removal operations of Blocks 1-4, attaching the opposite ends of the probe preform or a material joined to the probe preforms to a temporary or permanent substrate (Block 5); and according to a sixth example, after release of the build substrate according to any of Blocks 2-5, bonding or otherwise attaching a temporary or permanent substrate to the probe preforms or probes or to a material joined to the probe preforms or probes (Block 6). Other embodiments for releasing or transferring arrays (i.e., probe preform arrays or probe arrays) are possible and will be apparent to those of skill in the art upon review of the teachings herein and/or are set forth in one or more of the applications incorporated herein by reference.

Example 1 of FIG. 6B (Block 1) more particularly provides for no transfer or release as the substrate becomes a permanent part of the array.

Example 2 of FIG. 6B (Block 2) more particularly provides for, after formation and engagement of preforms and possible deformation plates, removing any remaining sacrificial material and/or masking material and then separating the preforms from the substrate by removing a release layer or by destructive removal of the substrate itself.

Example 3 of FIG. 6B (Block 3) more particularly provides for, after formation and engagement of preforms and possibly deformation plates, separating the preforms from the substrate by removing a release layer or by destructive removal of the substrate itself and thereafter removing any remaining sacrificial material and/or masking material.

Example 4 of FIG. 6B (Block 4) more particularly provides for, after formation and engagement of preforms and possibly deformation plates, separating the preforms from the substrate and removing the sacrificial material at the same time.

Example 5 of FIG. 6B (Block 5) more particularly provides for, prior to executing any removal operations of any of Blocks 1-4, bonding or otherwise attaching a temporary or permanent substrate (e.g., a space transformer or interposer substrate) to the preforms or to a material connected to the preforms.

Example 6 of FIG. 6B (Block 6) more particularly provides for, after removal of the substrate according to any of Blocks 2-5, bonding or otherwise attaching a temporary or permanent substrate (e.g., a space transformer or interposer substrate) to the preforms or the probes or to a material connected to the preforms or the probes.

Other methods may be used in the transfer and release of substrates and will be understood by those of skill in the art upon review of the teachings set forth herein or incorporated herein by reference.

FIG. 6C provides a block diagram that sets forth a number of examples related to tiling of subarrays to one another to form larger probe arrays. In particular, block diagram 600-C provides a first example that does not involve tiling (Block 1) while Block 2 and its Subblocks A-G provide seven different examples of how tiling may be implemented as part of Block W of FIG. 4.

Example 1 of block diagram 600-C (Block 1) more particularly provides for no tiling since arrays are formed from the combination of simultaneously formed preforms and possibly engaged deformation plates acting as guide plates, or from separate guide plates that form complete arrays.

Example 2 of block diagram 600-C (Block 2) more particularly provides for simultaneously formed preforms (before or after transformation to probes) with or without engaged deformation plates or guide plates form subarrays that are laterally engaged with other subarrays to form full arrays. Further teachings about tiles and tiling can be found in US Patent Publication No. 2006-0108678, published May 25, 2006, by Kumar et al., and entitled “Probe Arrays and Method for Making”.

Example 2A of block diagram 600-C (Block 2A) furthermore particularly provides for tiling occurring after release of subarrays from their formation substrate(s) but prior to release of all sacrificial material connecting the preforms.

Example 2B of block diagram 600-C (Block 2B) furthermore particularly provides for tiling occurring after release of subarrays from their formation substrate(s) and after release of the preforms or probes within individual subarrays from surrounding sacrificial material.

Example 2C of block diagram 600-C (Block 2C) furthermore particularly provides for tiling occurring prior to release of subarrays from their formation substrate(s) but after release of the preforms or probes within individual subarrays from surrounding sacrificial material.

Example 2D of block diagram 600-C (Block 2D) furthermore particularly provides for tiling occurring using guidance, alignment, or contact between longitudinal features or lateral features formed on, as part of, or engaged with one or more of the deformation plates or guide plates that are being positioned relative to one another.

Example 2E of block diagram 600-C (Block 2E) furthermore particularly provides for tiled deformation plates or guide plates being held one-to-another by one or more frame structures, that as a whole, engage at least one deformation plate or guide plate of each subarray.

Example 2F of block diagram 600-C (Block 2F) furthermore particularly provides for tiled deformation plates or guide plates being held one-to-another by a bonding material that joins adjacent deformation plates or guide plates.

Example 2G of block diagram 600-C (Block 2G) furthermore particularly provides for tiling being implemented using a combination of two or more of examples 2A-2F.

Other methods may be used in the tiling or combining of subarrays into larger arrays and will be understood by those of skill in the art upon review of the teachings set forth herein or incorporated herein by reference. For example after laterally positioning a plurality of subarrays with respect to one another, one or more guide plates or deformation plates may be added that bridge the probes of multiple subarrays into a larger array.

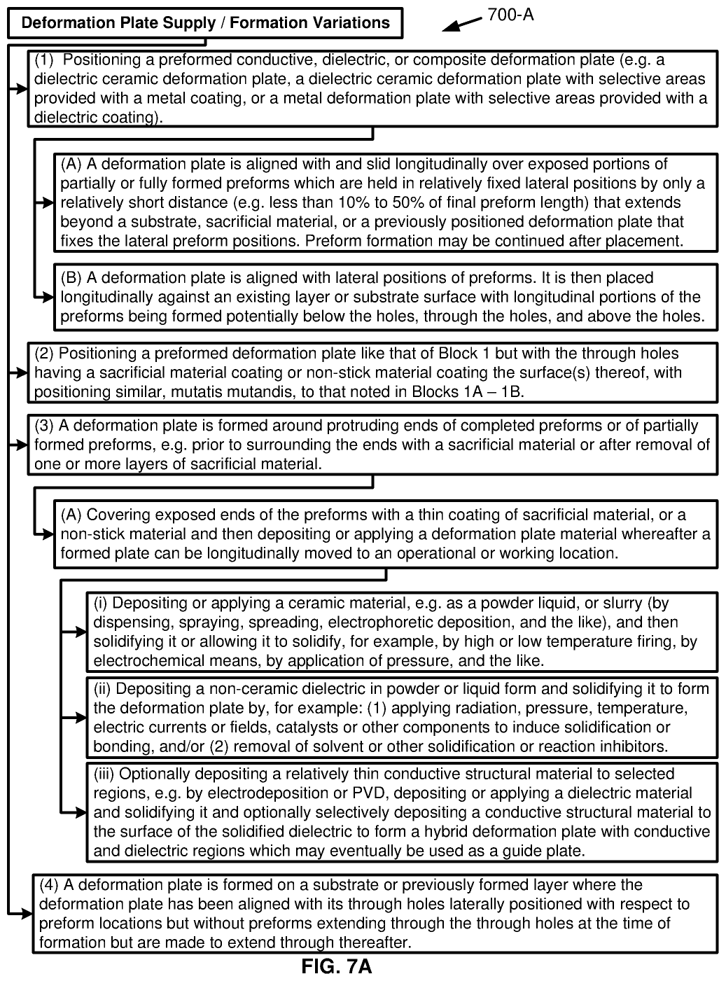

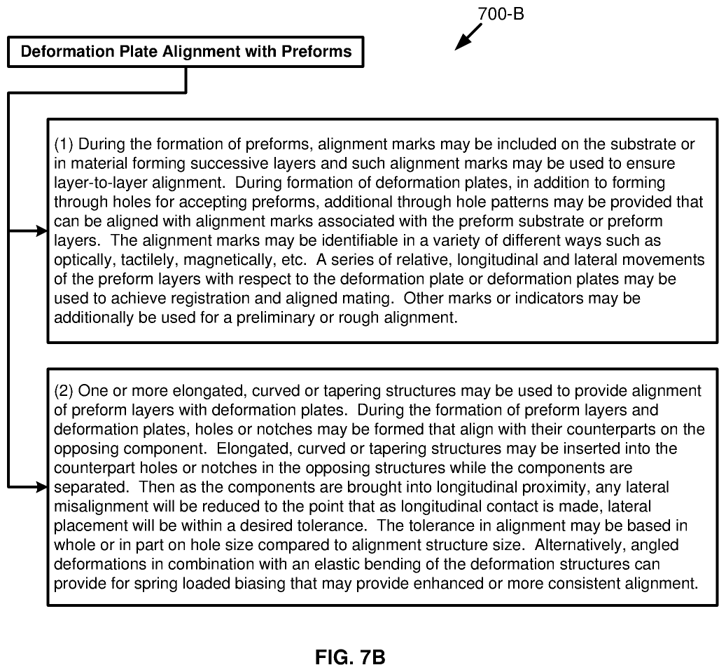

FIG. 7A provides a block diagram setting forth a number of examples of how deformation plates may be positioned relative to probe preforms that have been formed or are being formed and alternatively how deformation plates may be formed relative to probe preforms that have been formed or are being formed. In particular, block diagram 700-A provides two primary placement examples according to Blocks 1 and 2 and two primary formation examples according to Blocks 3 and 4 along with several more detailed implementation examples for Blocks 1 and 3 that may be part of Blocks H and/or K of FIG. 4. Other alternatives are possible and include, for example, placement or formation of deformation plates or separate guide plates prior to probe preform formation and then forming probe preforms on them or engaged with them.

Example 1 of block diagram 700-A (Block 1) particularly provides for positioning a preformed conductive, dielectric, or composite deformation plate (e.g. a dielectric plastic, a metal, a ceramic, a semiconductor deformation plate, a dielectric ceramic deformation plate with selective areas provided with a metal coating, or a metal deformation plate with selective areas provided with a dielectric coating).

Example 1A of block diagram 700-A (Block 1A) furthermore particularly provides for a deformation plate being aligned with and slid longitudinally over exposed portions of partially or fully formed preforms which are held in relatively fixed lateral positions by only a relatively short distance (e.g. less than 10% to 50% of final preform length) of exposed preform that extends beyond a substrate, sacrificial material, or a previously positioned deformation plate that fixes the lateral preform positions. Preform formation may be continued after placement as necessary.

Example 1B of block diagram 700-A (Block 1B) furthermore particularly provides for a deformation plate being aligned with lateral positions of preforms. The deformation plate is then placed longitudinally against an existing layer or substrate surface with longitudinal portions of the preforms being formed potentially below the holes, through the holes, and above the holes.

Example 2 of block diagram 700-A (Block 2) particularly provides for positioning a preformed deformation plate like that of Block 1A but with the through holes having a sacrificial material coating or non-stick material coating the surface(s) thereof, with positioning similar, mutatis mutandis, to that noted in Blocks 1A-1B.

Example 3 of block diagram 700-A (Block 3) particularly provides for a deformation plate being formed around protruding ends of completed preforms or of partially formed preforms, e.g. prior to surrounding the ends with a sacrificial material or after removal of one or more layers of sacrificial material.

Example 3A of block diagram 700-A (Block 3A) furthermore particularly provides for covering exposed ends of the preforms with a thin coating of sacrificial material, or a non-stick material and then depositing or applying a deformation plate material whereafter a formed plate can be longitudinally moved to an operational or working location.

Example 3A(i) of block diagram 700-A (Block 3A(i)) even furthermore particularly provides for depositing or applying a ceramic material, e.g., as a powder, liquid, or slurry (by dispensing, spraying, spreading, electrophoretic deposition, and the like), and then solidifying it or allowing it to solidify, for example, by high or low temperature firing, by electrochemical means, by application of pressure, and the like.

Example 3A(ii) of block diagram 700-A (Block 3A(ii)) even furthermore particularly provides for depositing a non-ceramic dielectric in powder or liquid form and solidifying it to form the deformation plate by, for example: (1) applying radiation, pressure, temperature, electric currents or fields, catalysts, or other components to induce solidification or bonding, and/or (2) removal of solvent or other solidification or reaction inhibitors.

Example 3A(iii) of block diagram 700-A (Block 3A(iii)) even furthermore particularly provides for optionally depositing a relatively thin conductive structural material to selected regions, e.g. by electrodeposition or PVD, depositing or applying a dielectric material and solidifying it and optionally selectively depositing a conductive structural material to the surface of the solidified dielectric to form a hybrid deformation plate with conductive and dielectric regions which may eventually be used as a guide plate.

Example 4 of block diagram 700-A (Block 4) particularly provides for a deformation plate being formed on a substrate or previously formed layer where the deformation plate has been aligned with its through holes laterally positioned with respect to preform locations but without preforms extending through the through holes at the time of formation but are made to extend through the holes thereafter.

Other examples are possible and will be understood by those of skill in the art upon review of the teachings set forth herein or incorporated here by reference.

FIG. 7B provides a block diagram setting forth two examples of how deformation plates and probe preforms may be laterally aligned. In particular, block diagram 700-B provides two examples of alignment methods that may be used in implementing the examples of FIG. 7A.

Example 1 of FIG. 7B (Block 1) particularly provides for, during the formation of preforms, alignment marks possibly being included on the substrate or in material forming successive layers and such alignment marks possibly being used to ensure layer-to-layer alignment. During formation of deformation plates, in addition to forming through holes for accepting preforms, additional through hole patterns may be provided that can be aligned with alignment marks associated with the preform substrate or preform layer or layers. The alignment marks may be identifiable in a variety of different ways such as optically, tactilely, magnetically, etc. A series of relative, longitudinal, and lateral movements of the preform layers with respect to the deformation plate or deformation plates may be used to achieve registration and aligned mating. Other marks or indicators may additionally be used for a preliminary or rough alignment.

Example 2 of block diagram 700-B (Block 2) particularly provides for one or more elongated, curved or tapering structures possibly being used to provide alignment of preform layers with deformation plates. During the formation of preform layers and deformation plates, holes or notches may be formed that align with their counterparts on the opposing component. Elongated, curved, or tapering structures may be inserted into the counterpart holes or notches in the opposing structures while the components are separated. Then as the components are brought into longitudinal proximity, any lateral misalignment will be reduced to the point that as longitudinal contact is made, lateral placement will be within a desired tolerance. The tolerance in alignment may be based in whole or in part on hole size compared to alignment structure size. Alternatively, angled deformations in combination with an elastic bending of the deformation structures can provide for spring loaded biasing that may provide enhanced or more consistent alignment.

Other alignment alternatives are possible and will be apparent to those of skill in the art upon review of the teachings herein and/or are set forth in one or more of the applications incorporated herein by reference.

The general process flow of FIG. 4 may be executed using different combinations of steps, different orders of steps, different repetitions of steps, and using different alternative implementations of steps or groups of steps as set forth in the examples of FIGS. 5-7B and/or other implementations of steps or groups of steps that will be apparent to one of skill in the art upon review of the teachings herein (including the teachings incorporated herein by reference).

### Specific Embodiment Examples

To further enhance understanding of the scope of the generalized embodiments as discussed above, specific illustrative examples are set forth below. These examples use reference numbers wherein the first digit(s) are based on the FIG. number while the final two digits, and possibly an extension, indicate specific features of the embodiments as indicated in the following table.

| Ref. No. (Final 2 Digits - Extension) | Description |
|---|---|
| 00 | Flowchart or block diagram |
| 01 | Substrate |
| 03 | Patterned dielectric stabilization material |
| 05 | Release layer |
| 11 | Probe preforms |
| 21 | Sacrificial material |
| 31 | Upper portion lacking sacrificial material |
| 41, -1, -2, -3, -4, -1A, -1B, -2A, -2B | Deformation plate |
| 43 | Deformation plate or stabilization plate |
| 45 | Compression plate |
| 47 | Flowable stabilization material |
| 51 | Array (partially or fully formed probe preforms) |
| 61 | Region of removed sacrificial material |
| 70, -1A, -1B, -2A, -2B | Relative movement to cause deformation |
| 71, -1, -2 | Array of probes or deformed preforms array |
| 73-1, -2 | Probe preforms after partial deformation |
| 81 | Guide plate |

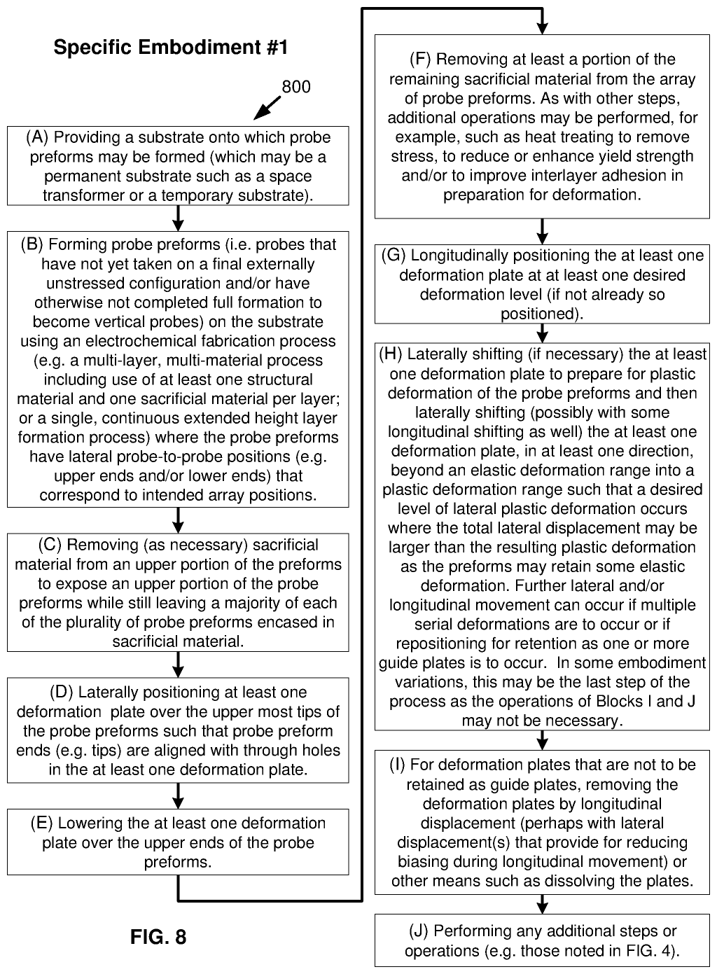

FIG. 8 provides a simplified flowchart of a first specific embodiment of the invention for forming a probe array with a deformation plate inserted from above after probe preform formation and after partial removal of a sacrificial material wherein the deformation plate may be removed from the final probe array or may be retained as a guide plate. Flowchart 800 sets forth operational blocks (e.g. operations, steps, or groups of steps) A-J with Blocks A-I setting forth specific operations associated with the embodiment while Block J is a place holder that calls for any additional operations that may be required in forming the probe array. In some variations, operations like those noted in J may be inserted between some or all of operational Blocks A-I or even between some or all substeps within any of A-I. In other variations, it may be possible to change the order of some blocks relative to other blocks or to even repeat or delay the operations of some blocks to provide different, or additional, orders of operation of the blocks relative to one another.

The process exemplified in FIG. 8 begins with Block A which calls for providing a substrate onto which probe preforms may be formed (which may be a permanent substrate such as a space transformer or it may be a temporary build substrate which will be removed after preform formation). After the operation of Block A, the process moves to Block B which calls for forming probe preforms or partially formed probes that have not yet been fully subjected to a final plastic deformation that will be used to set a real or hypothetical unbiased configuration of the probes. Hypothetical unbiased configuration as used herein, refers to a configuration of a probe that would exist if all biasing forces were to be removed which in practice may not actually occur as preforms may be plastically deformed but the biasing forces associated with their formation may never be fully removed as the probes may be retained by guide plates, or other structures, in a biased state. In particular, in this embodiment, the probe preforms are formed directly or indirectly on the substrate using an electrochemical fabrication process (e.g. via a multi-layer, multi-material process including use of at least one structural material and one sacrificial material per layer, via a single layer process, or via straight or curved continuous extended height formation process, e.g. an ELEX process) where the probe preforms have lateral probe-to-probe positions (e.g. upper ends and/or lower ends) that correspond to intended array positions.

After the operation of Block B, the process moves to Block C which calls for removing (as necessary) sacrificial material from an upper portion of the preforms to expose an upper portion of the probe preforms while still leaving a majority of each of the plurality of probe preforms encased in sacrificial material. After the operation of Block C, the process moves to Block D which calls for laterally positioning at least one deformation plate over the upper most tips of the probe preforms such that probe preform ends (e.g. tips) are aligned with through holes in the at least one deformation plate.

After the operation of Block D, the process moves to Block E which calls for lowering the at least one deformation plate over the upper ends of the probe preforms. After the operation of Block E, the process moves to Block F which calls for removing at least a portion of the remaining sacrificial material from the array of probe preforms. As with other steps, additional operations may be performed. For example, such operations my include heat treating to remove stress, to reduce or enhance yield strength and/or to improve interlayer adhesion in preparation for deformation.

After the operation of Block F, the process moves to Block G which calls for longitudinally positioning the at least one deformation plate at at least one desired deformation level (if not already so positioned). After the operation of Block G, the process moves to Block H which calls for potentially laterally shifting the at least one deformation plate to prepare for plastic deformation of the probe preforms. This may be done prior to causing actual deformation, for example, to position the plate or plates for supporting the preforms or for grasping the preforms by the interaction of multiple preforms. After any initial shifting, performing further lateral shifting (possibly with some longitudinal shifting as well) to cause at least one deformation plate, in at least one direction, to move the preforms beyond an elastic deformation range into a plastic deformation range such that a desired level of lateral plastic deformation occurs where the total lateral displacement may be larger than the resulting plastic deformation as the preforms may retain some elastic deformation. Further lateral and/or longitudinal movement can occur if multiple serial deformations are to occur or if repositioning for retention of the deformation plate or plates as one or more guide plates is to occur. In some embodiment variations, this may be the last step of the process as land J may not be necessary.

After the operation of Block H, for deformation plates that are not to be retained as guide plates, the process moves to Block I which calls for removing the deformation plates by longitudinal displacement (perhaps with lateral displacement(s) that provide for reducing biasing during longitudinal movement) or other means such as dissolving the plates. After the operation of Block I, the process moves to Block J which calls for performing any additional processing steps (e.g. those noted in FIG. 4).

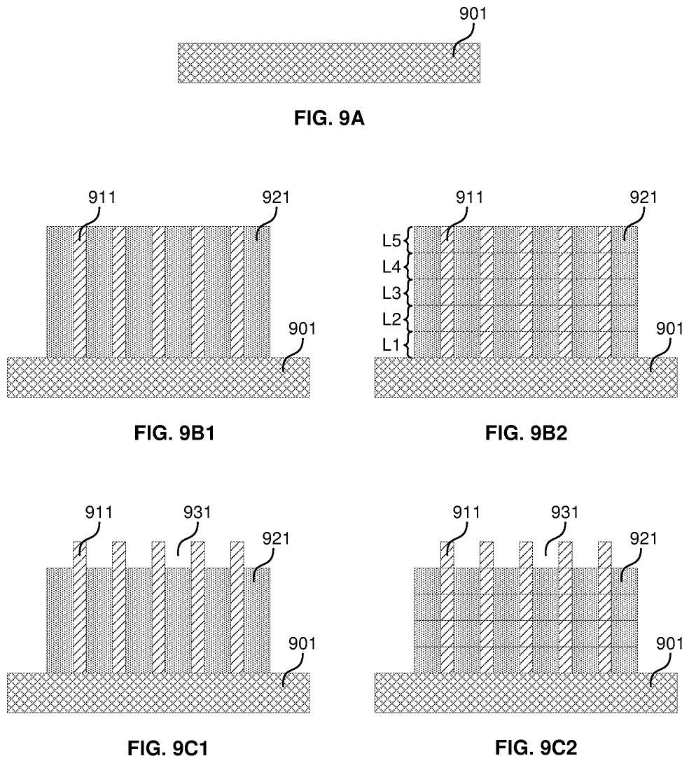

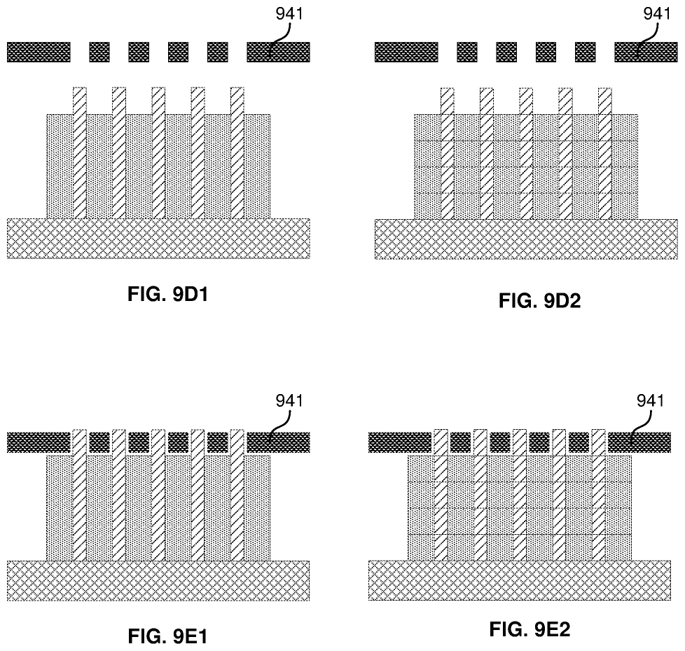

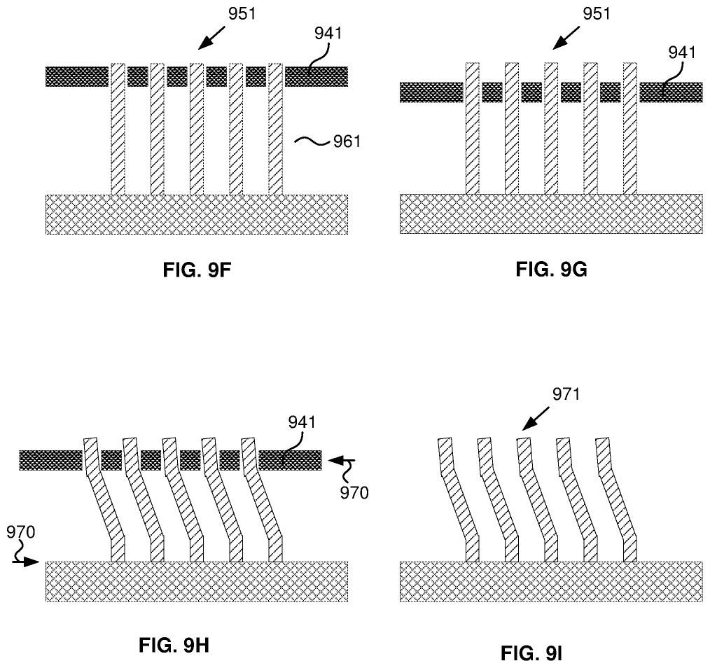

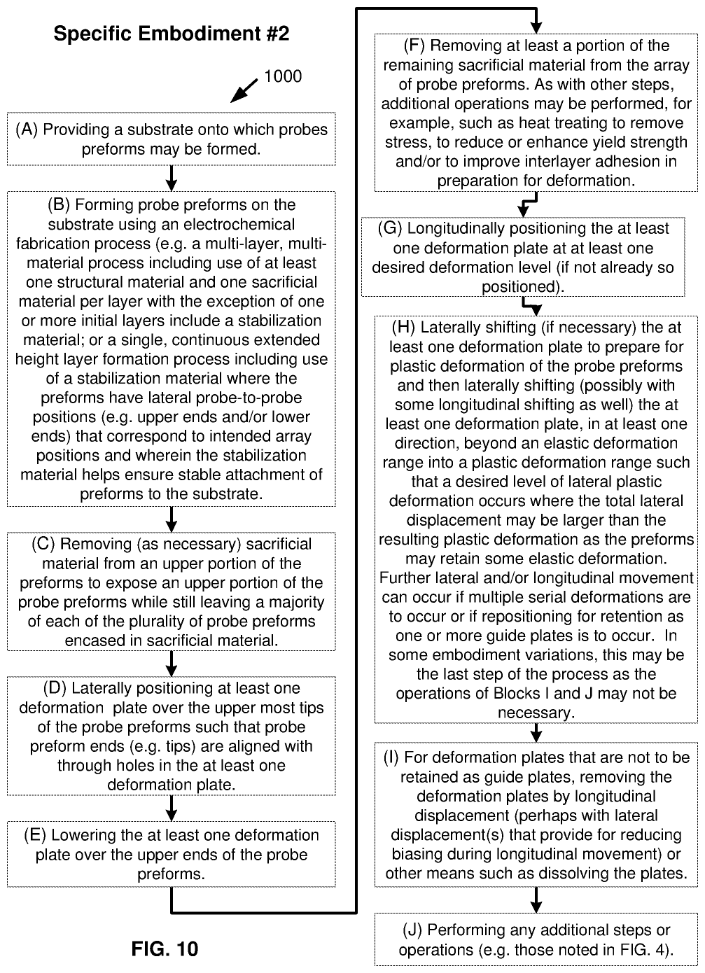

FIGS. 9A-9I provide cut side views of example results of the steps set forth in operational Blocks A-I of FIG. 8. In particular, in this example, the formation of an array of probes (exemplified with five probe preforms/probes) occurs via one of two methods: (1) the formation of a single layer out of a structural material and a sacrificial material or (2) the formation of multiple, multi-material layers (exemplified with five layers). In either method, the probe preforms are held at their lower ends by a substrate and are laterally plastically shaped by manipulation of a single deformation plate. In other embodiments multiple plates may be moved relative to the substrate, wherein the deformation plate may or may not be retained as a guide plate in a final array assembly. The final array assembly is configured to allow elastic compression of the probes when the probes are made to contact an electronic component.

The following states in the formation process can be seen in FIGS. 9A-9I: (1) a substrate 901 after being supplied (FIG. 9A); (2) probe preforms 911 and surrounding sacrificial material 921 after buildup of a single layer on the substrate (FIG. 9B1) or after buildup of a number of multi-material layers L1-L5 on the substrate (FIG. 9B2); (3) the upper portion 931 of the single layer (FIG. 9C1) lacking sacrificial material or one or more upper layers 931 lacking sacrificial material (FIG. 9C2) due to removal of a portion of the sacrificial material previously formed (could have been due to never locating the sacrificial material at these levels in some variations); (4) a deformation plate 941 after lateral placement over the single layer probe preforms (FIG. 9D1) or over the multi-layer probe preforms (FIG. 9D2); (5) the deformation plate after longitudinal placement around the single layer probe preforms (FIG. 9E1) or the multi-layer preforms (FIG. 9E2), (6) the partially formed array 951 with sacrificial material removed 961 (FIG. 9F) where the distinction between single layer preforms and multi-layer preforms is no longer illustrated; (7) the probe preform array after longitudinally shifting the deformation plate to a desired deformation level (FIG. 9G); (8) the probe preform array with the deformation plate laterally shifted to the left relative to the substrate (as illustrated by left and right pointing arrows 970) to cause at least some plastic deformation of the preforms (FIG. 9H); and (9) the array 971 with the deformed preforms having desired probe configurations and probe-to-probe lateral array positions that are retained after removal of the deformation plate to form the final probe array or a probe array ready for additional operations as optionally called for in Block J of FIG. 8 (FIG. 9I).

Numerous other variations of the embodiment of FIGS. 8 and 9A-9H are possible. Some such alternatives include for example, (1) variations allowed in the generalized flowchart of FIG. 4, (2) variations set forth in the examples of FIGS. 5-7, and (3) the individual operations or steps set forth in other specific embodiments set forth herein and/or individual variations noted with regard to those other specific embodiments.

Other such variations include, for example: (1) use of different numbers of the deformation plates; (2) use of different longitudinal positioning of the deformation plates; (3) use of deformation plates that do not engage all probe preforms (e.g. one or more large openings that surround a plurality of preforms and thus do not manipulate those particular preforms); (4) use of deformation plates with different sized holes or different shaped holes to engage some preforms differently than others; (5) use of preforms of different shapes or configurations (at least in the engagement area) such that preform manipulation results in a different net effect on some preform types as compared to other preform types; (6) use of deformation plates in pairs, or in other groupings, wherein the plates are shifted relative to one another and are made to clamp the probe preforms during deformation, (7) use of longitudinal shifting of guide plates during lateral shifting (e.g., to account for changing of height as tilting, (i.e. deformation, of the preform occurs), (8) retention of one or more retention plates as guide plates with such plates retained at their longitudinal deformation levels or moved to different longitudinal levels; (9) two or more guide plates being added, or one or more guide plates being added along with the deformation plate being retained as a glide plate; (10) the substrate being removed, (11) a different substrate attached on the top of shaped preforms; (12) a different substrate attached on the bottom of the shaped preforms; (13) changing the order of performing operations or steps particularly when (a) the change in order has little or no impact on the overall process, or (b) the change in order offers a desired advantage which is believed to outweigh any negative impact, (14) dividing steps in more focused tasks or operations, (15) adding in additional steps, (16) using modified or alternative steps; (17) use of one or more additional longitudinal adjustments followed by lateral displacements to cause different or additional probe configurations such as planar probes with multiple bends or formation of non-planar probes with bends in different lateral directions (e.g. probes with two bends at 90 degree lateral angles, or probes that have spiral-like configurations, and (18) removal of operations that are unnecessary particularly to reduce fabrication time, remove sources of process failure, and/or more generally reduce fabrication cost.

Still other such variations include, for example: (1) using alternative probe materials, sacrificial materials, and/or masking materials during the formation of one or more layers or portions of layers to allow for enhanced probes to be formed or more controlled material removal (e.g. to provide more controlled or reliable deformation plate insertion and positioning); (2) use of alternative probe configurations, (3) incorporating probes having different longitudinal starting positions or ending positions, (4) providing probes with special contact tips or mounting ends with special shapes or formed from special material; (5) use of probes with contact tips on each end as opposed to one contact tip and one mounting end (e.g. to make pressure contact with a DUT on one end and pressure contact with a space transformer on the other); (6) bottoms of probes not remaining attached to a substrate; (7) regions between probes being partially or completely filled with compressible dielectric material, for example, to aid in providing elastic force or to aid in ensuring non-shorting between closely spaced probes upon deflection; (8) probe arrays having uniform spacings between all probes; (9) probe arrays having gaps in probe positions; (10) probe arrays having probes located with non-uniform spacings; (11) probe arrays having probe tips configured in one-dimensional configurations (N×1); (12) probe arrays having probe tips configured in two-dimensional arrays (N×M); (13) one or two dimensional arrays having tips located at more than one longitudinal plane; (14) arrays having only a small number of probes, e.g. under ten or twenty, a moderate number of probes, e.g. tens to hundreds, a large number of probes, e.g. hundreds to thousands, or even a very large number of probes, e.g. from thousands to tens-of-thousands or more; (15) probes formed from as little as one layer or as many as tens of layers, or more, (16) probes formed from planarized layers or non-planarized layers, (17) layers including sacrificial material of a variety of types or using no sacrificial material; (18) including guide plates in arrays that are not deformation plates; (19) using deformation plates that are initially inserted at longitudinal deformation levels, (20) using deformation plates that are initially inserted at non-deformation level and are then moved to deformation levels, (21) removing a build substrate in favor of insertion or formation of one or more additional deformation plates or guide plates, prior to probe formation, during probe preform formation or after probe preform formation, where insertion may occur from above or below and formation may occur while probe preforms are engaged or before engagement occurs; (22) separating lateral alignment and longitudinal alignment of deformation plates by one or more steps or operations; (23) replacing some or all single deformation plates by composite or paired deformation plates that are laterally and/or longitudinally positionable relative to one another, or that are held in fixed lateral and/or longitudinal positions relative to one another at the time of positioning (e.g. due to fixturing or due to a material located at least in part therebetween which may be removed or retained after positioning and which in the case of retention may provide, in addition to configurational stability, general conductive and/or dielectric properties to the assembly such that guide plates and associated probes are provided with intended electrical connections and or electrical isolation); and/or (24) using heat treatments or other operations to modify the material properties of the preforms and/or probes (e.g. to reduce yield strength or make it more uniform prior to deformation and/or to increase yield strength or improve spring properties after deformation). Other possible variations include individual steps or features set forth in the embodiments or embodiment variations in the patent applications incorporated herein by reference such as, for example, those of the '450 patent.

FIG. 10 provides a simplified flowchart of a second specific embodiment of the invention for forming a probe array with a base support material added before or during probe preform formation and a deformation plate inserted from above after probe preform formation and after partial removal of a sacrificial material wherein the deformation plate may be removed from the final probe array or may be retained as a guide plate. Flowchart 1000 sets forth operations, steps, or groups of operations or steps, A-J which are similar to those noted for Flowchart 800 with the primary exception that one or more initial layers, or a lower portion of a single layer, is made to include a stabilization material which is different from the sacrificial material that is used for other layers, or upper portion of a single layer, such that the attachment of the probe preforms to the substrate is further supported either temporarily (e.g., during deformation) or permanently (e.g., during deformation and the during use of the array).

The process exemplified in FIG. 10 begins with Block A which calls for providing a substrate onto which probes preforms may be formed. After the operation of Block A, the process moves to Block B which calls for forming probe preforms on the substrate using an electrochemical fabrication process (e.g. via a multi-layer, multi-material process including use of at least one structural material and one sacrificial material per layer with the exception of one or more initial layers that include a stabilization material, via a single layer single material or multiple material formation process, or via a continuous extended height layer formation process, e.g. an ELEX process) including use of a stabilization material where the preforms have lateral probe-to-probe positions (e.g. upper ends and/or lower ends) that correspond to intended array positions and wherein the stabilization material helps ensure stable attachment of preforms to the substrate.

After the operation of Block B, the process moves to Block C which calls for removing (as necessary) sacrificial material from an upper portion of the preforms to expose an upper portion of the probe preforms while still leaving a majority of each of the plurality of probe preforms encased in sacrificial material. After the operation of Block C, the process moves to Block D which calls for laterally positioning at least one deformation plate over the upper most tips of the probe preforms such that probe preform ends (e.g. tips) are aligned with through holes in the at least one deformation plate.

After the operation of Block D, the process moves to Block E which calls for lowering the at least one deformation plate over the upper ends of the probe preforms. After the operation of Block E, the process moves to Block F which calls for removing at least a portion of the remaining sacrificial material from the array of probe preforms. As with other steps, additional operations may be performed, for example, such as heat treating to remove stress, to reduce or enhance yield strength and/or to improve interlayer adhesion in preparation for deformation.

After the operation of Block F, the process moves to Block G which calls for longitudinally positioning the at least one deformation plate at at least one desired deformation level (if not already so positioned). After the operation of Block G, the process moves to Block H which calls for laterally shifting (if necessary) the at least one deformation plate to prepare for plastic deformation of the probe preforms and then laterally shifting (possibly with some longitudinal shifting as well) the at least one deformation plate, in at least one direction, beyond an elastic deformation range into a plastic deformation range such that a desired level of lateral plastic deformation occurs where the total lateral displacement may be larger than the resulting plastic deformation as the preforms may retain some elastic deformation. Further lateral and/or longitudinal movement can occur if multiple serial deformations are to occur or if repositioning for retention of the deformation plate or plates as one or more guide plates is to occur. In some embodiment variations, this may be the last step of the process as the operations of Blocks land J may not be necessary.

After the operation of Block H, for deformation plates that are not to be retained as guide plates, the process moves to Block I which calls for removing the deformation plates by longitudinal displacement (perhaps with lateral displacement(s) that provide for reducing biasing during longitudinal movement) or other means such as dissolving the plates. After the operation of Block I, the process moves to Block J which calls for performing any additional processing steps (e.g. those noted in FIG. 4).

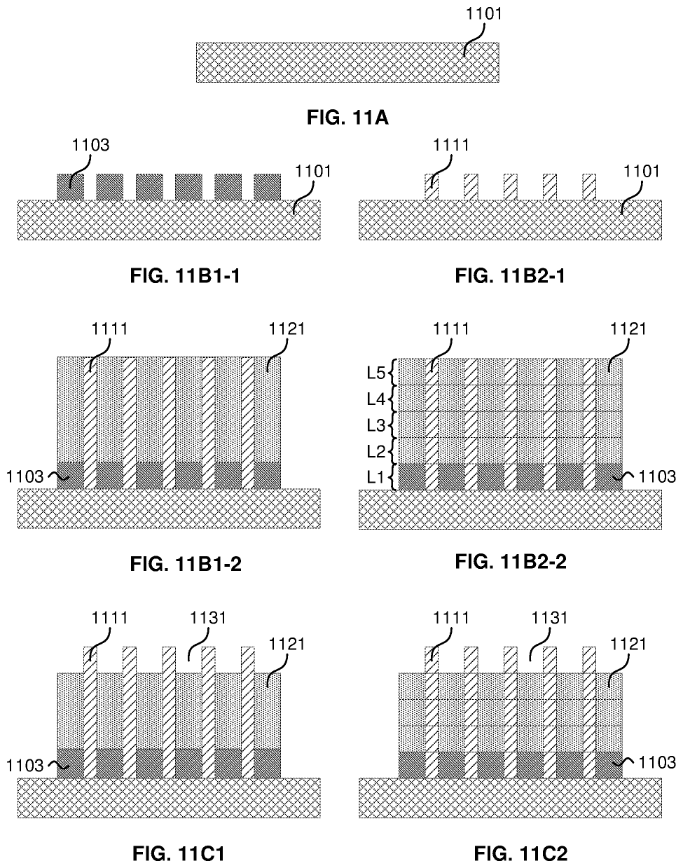

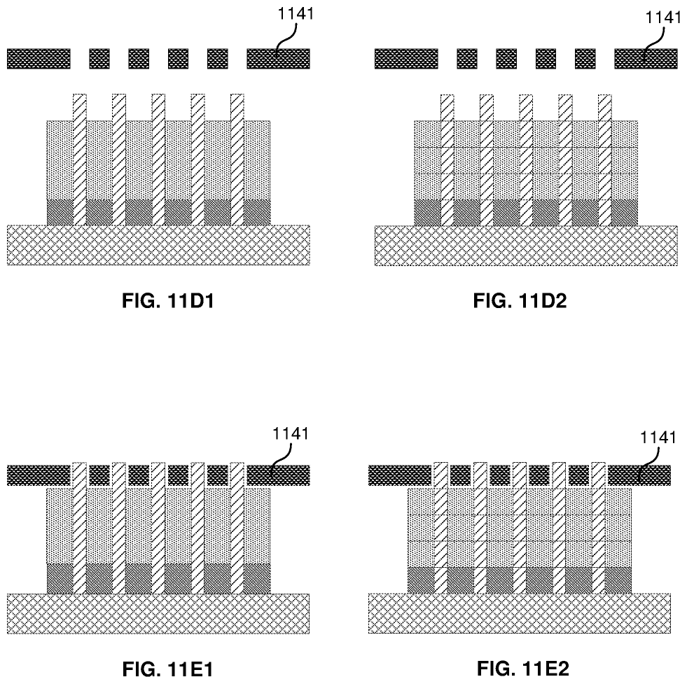

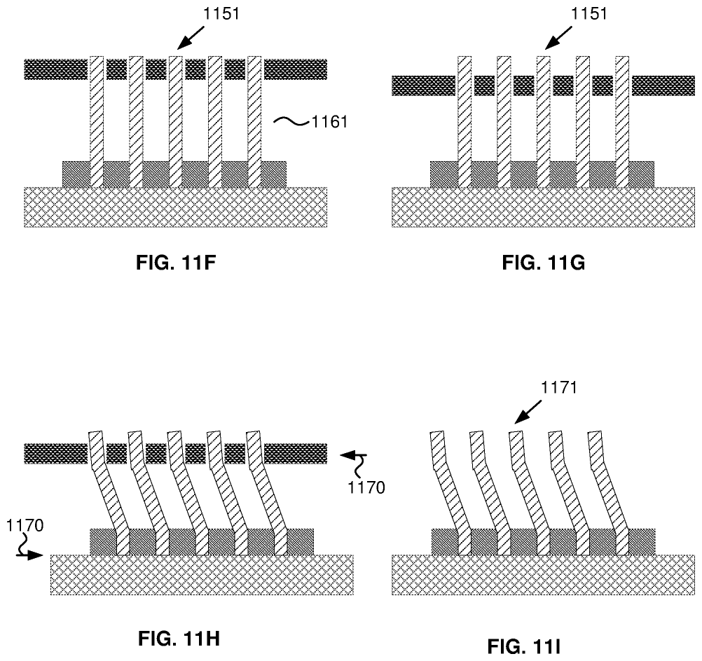

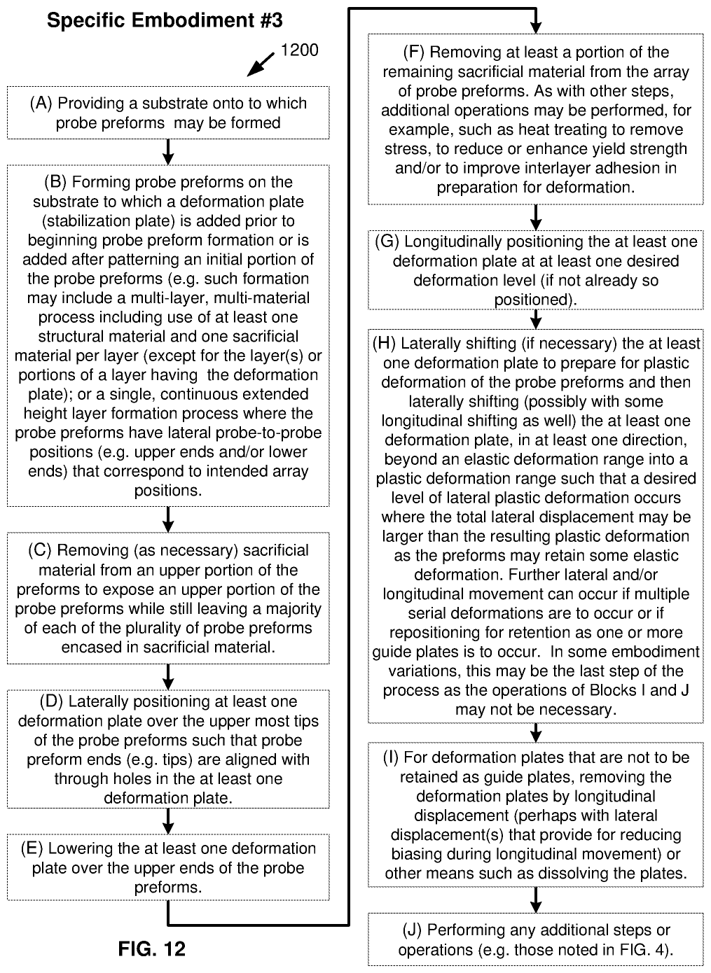

FIGS. 11A-11I provide cut side views of example results of some variations of the steps set forth in operational Blocks A-I of FIG. 10. In particular, in this example, the formation of an array of probes (exemplified with five probe preforms/probes) occurs via either (1) the formation of a single layer out of a structural material and a sacrificial material or (2) via formation of multiple, multi-material layers (exemplified with five layers) where the probe preforms are held at their lower ends by a substrate and by a surrounding thin region of stabilization material and are laterally plastically shaped by manipulation of a deformation plate relative to the substrate, wherein the deformation plate is not retained as a guide plate. The final array assembly is configured to allow elastic compression of the probes when the probes are made to contact an electronic component.

The following states of the process can be seen in FIGS. 11A-11I: (1) a substrate 1101 after being supplied (FIG. 11A); (2) in a first alternative, an initial formation of a patterned dielectric stabilization material 1103 is formed (FIG. 11B1-1) and is followed by the formation of probe preforms 1111 from a single layer with portions above the stabilization material being occupied by a sacrificial material 1121 which may be dielectric or conductive (FIG. 11B1-2) or in a second alternative, an initial patterned formation of parts of the preforms 1111 are formed (FIG. 11B2-1) which is followed by deposition of a stabilization material and planarization to form a first layer L1 which in turn is followed by formation of four additional multi-material layers L2-L5 that each include a probe preform material and a sacrificial material (FIG. 11B2-2); (3) in the first alternative, sacrificial material has been removed from the upper portion 1131 of the single layer of probe preform material (FIG. 11C1) while in the second alternative, sacrificial material has been removed from the upper layer 1131 of the multi-layer preforms (FIG. 11C2); (4) in the first alternative, a deformation plate has been laterally placed over the single layer probe preforms (FIG. 11D1) while in the second alternative, a deformation plate has been laterally placed over the multi-layer probe preforms (FIG. 11D2); (5) in the first alternative, the deformation plate 1141 has been longitudinally placed around the single layer probe preforms (FIG. 11E1) while in the second alternative, the deformation plate has been longitudinally placed around the multi-layer preforms (FIG. 11E2), (6) sacrificial material has been removed 1161 from the partially completed array 1151 and the distinction between single layer preforms and multi-layer preforms is no longer illustrated (FIG. 11F); (7) the deformation plate has been longitudinally shifted to a desired deformation level (FIG. 11G); (8) the deformation plate has been laterally shifted to the left relative to the substrate (as illustrated by left and right pointing arrows 1170) to cause plastic deformation of the preforms (FIG. 11H); and (9) the array 1171 after removal of the deformation plate wherein the array has deformed preforms with desired probe configurations and probe-to-probe lateral array positions such that a final probe array is represented or alternatively an array that is ready for additional operations as optionally called for in Block J of FIG. 10 is provided (FIG. 11I).

As with FIGS. 8 and 9A-9H, numerous additional variations of the embodiment of FIGS. 10 and 11A-11I are possible and include intra alia, those noted with regard to FIGS. 8 and 9A-9H as well as features or operations noted in the other embodiments set forth herein or in variations of those embodiments.

FIG. 12 provides a simplified flowchart of a third specific embodiment of the invention for forming a probe array with a base deformation plate (e.g., a preform stabilization plate) added before or during probe preform formation and a second deformation plate inserted from above after probe preform formation and after partial removal of a sacrificial material wherein the second deformation plate may be removed from the final probe array or may be retained as a guide plate or other array structure. Flowchart 1200 sets forth operations or steps, or groups of operations or steps, A-J which are similar to those of Flowchart 1000 but with the stabilization material being replaced by a deformation plate that functions as a stabilization plate that will be fixed to, or at least moved along with the substrate, to provide enhanced connection reliability of the preforms to the substrate.

The process of FIG. 12 begins with Block A which calls for providing a substrate onto to which probe preforms may be formed. After the operation of Block A, the process moves to Block B which calls for forming probe preforms on the substrate to which a deformation plate (stabilization plate) is added prior to beginning probe preform formation or is added after patterning an initial portion of the probe preforms. In some variations, the methods for forming performs may be similar to those noted in the examples of FIGS. 8 and 10 while in other variations, other methods may be used. As with FIGS. 8 and 10, the probe preforms have lateral probe-to-probe positions (e.g. upper ends and/or lower ends) that correspond to intended array positions.

After the operation of Block B, the process moves to Block C which calls for removing (as necessary) sacrificial material from an upper portion of the preforms to expose an upper portion of the probe preforms while still leaving a majority of each of the plurality of probe preforms encased in sacrificial material. After the operation of Block C, the process moves to Block D which calls for laterally positioning at least one deformation plate over the upper most tips of the probe preforms such that probe preform ends (e.g. tips) are aligned with through holes in the at least one deformation plate.

After the operation of Block D, the process moves to Block E which calls for lowering the at least one deformation plate over the upper ends of the probe preforms. After the operation of Block E, the process moves to Block F which calls for removing at least a portion of the remaining sacrificial material from the array of probe preforms. As with other steps, additional operations may be performed such as heat treating to remove stress, to reduce or enhance yield strength and/or to improve interlayer adhesion in preparation for deformation. In some variations, as with the other embodiments, all sacrificial material may have been removed in a previous operation and thus the operation or operations of Block F may not be needed.

After the operation of Block F, the process moves to Block G which calls for longitudinally positioning the at least one deformation plate at at least one desired longitudinal deformation level (if not already so positioned). After the operation of Block G, the process moves to Block H which calls for laterally shifting (if necessary) the at least one deformation plate to prepare for plastic deformation of the probe preforms and then laterally shifting (possibly with some longitudinal shifting as well) the at least one deformation plate, in at least one direction, beyond an elastic deformation range of the preforms so as to enter a plastic deformation range such that a desired level of lateral plastic deformation occurs where the total lateral displacement may be larger than the resulting plastic deformation as the preforms may retain some elastic deformation. Further lateral and/or longitudinal movement can occur if multiple serial deformations are to occur or if repositioning for retention as one or more guide plates is to occur. In some embodiment variations, this may be the last step of the process as the operations of Blocks I and J may not be necessary.

After the operation of Block H, for deformation plates that are not to be retained as guide plates, the process moves to Block I which calls for removing the deformation plates by longitudinal displacement (perhaps with lateral displacement(s) that provide for reducing biasing during longitudinal movement) or other means such as dissolving the plates. After the operation of Block I, the process moves to Block J which calls for performing any additional processing steps (e.g. those noted in FIG. 4).

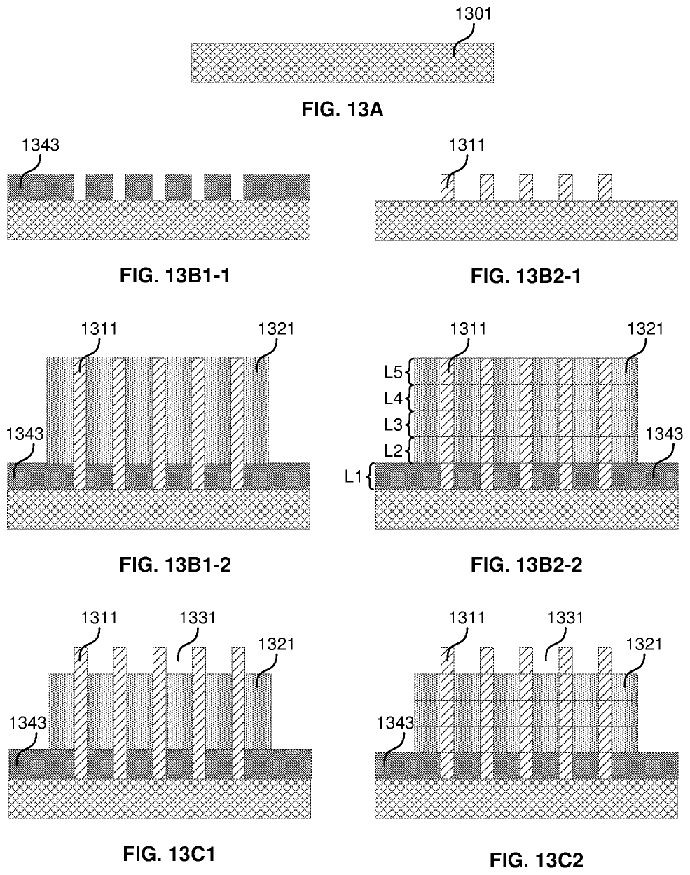

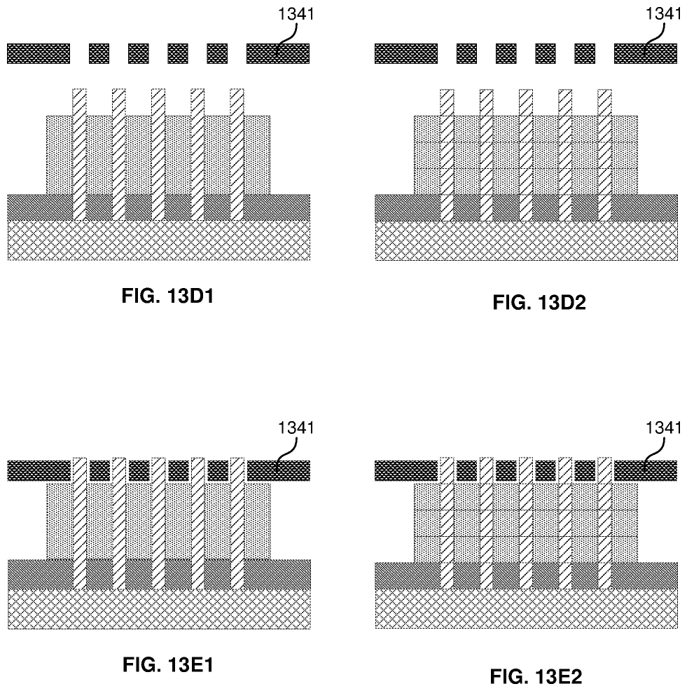

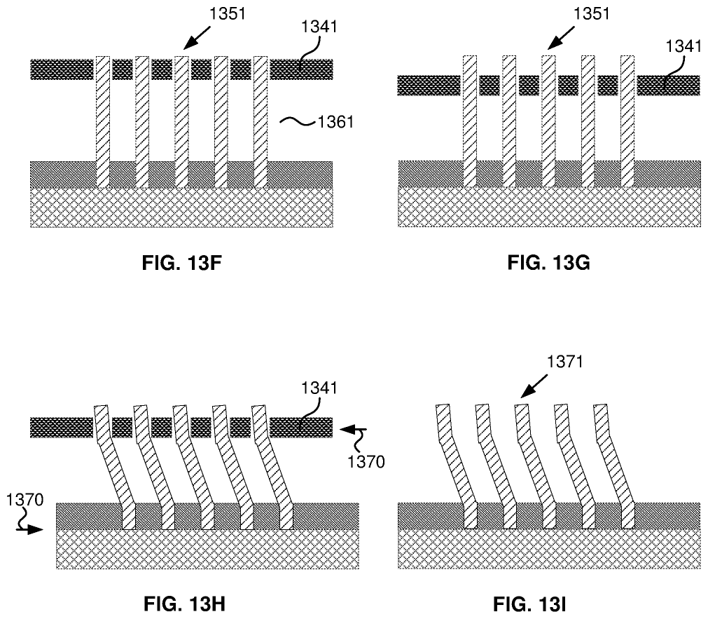

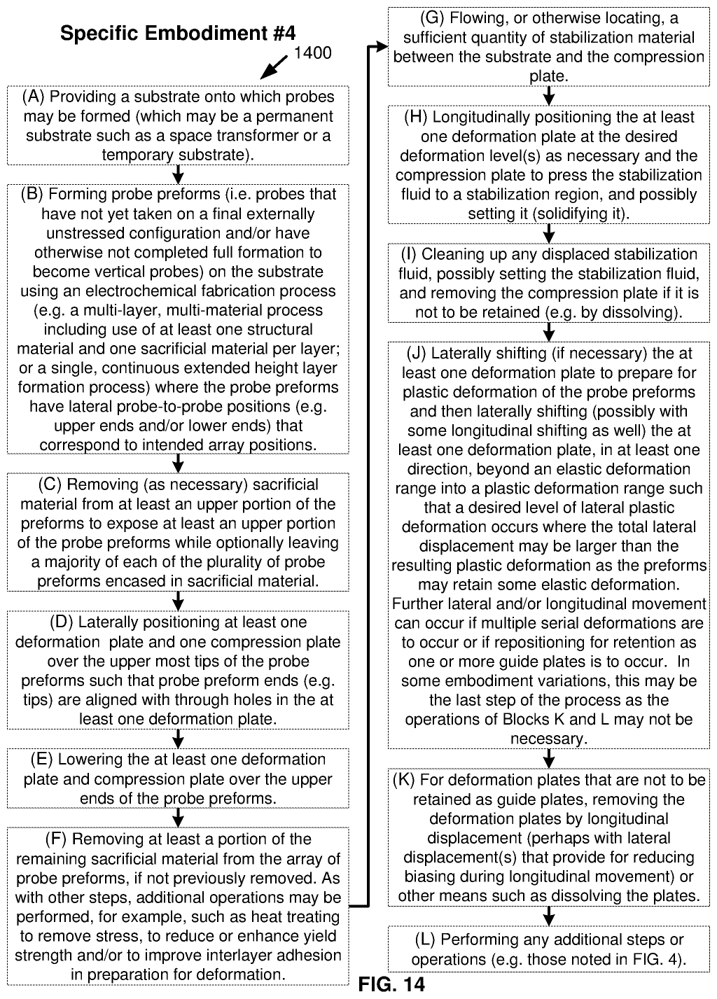

FIGS. 13A-13I provide cut side views of examples of various states in the formation process with each figure illustrating a step as set forth in operational Blocks A-I of FIG. 12 wherein the FIGS. are similar to their FIGS. 11A-11I counterparts, including reference numbers being in the 1300 series, with the exception that the stabilization material 1103 of flowchart 1000 is replaced with a deformation plate or stabilization plate 1343 in flowchart 1200 which is initially exemplified in the alternatives of FIGS. 13B1-1 and 13B2-2.

FIG. 14 provides a simplified flowchart of a fourth specific embodiment of the invention for forming a probe array with a deformation plate inserted from above after probe preform formation and after partial removal of a sacrificial material and a base support material (i.e. preform stabilization material) added after probe preform formation and after completing removal of the sacrificial material wherein the deformation plate may be removed from the final probe array or may be retained as a guide plate. Flowchart 1400 sets forth operational Blocks A-L similar to those of the previous embodiments with the primary exceptions being the addition of a Block G for positioning a stabilization material, a Block H for compressing and possibility setting the stabilization material, and a Block I for cleaning up any excess stabilization material and possibly setting the stabilization material as opposed to operational Blocks A of flowchart 1000 or B of flowchart 1200 which provided locating a base deformation plate or stabilization material, respectively, prior to or during the preform formation.

The process of FIG. 14 begins with Block A which calls for providing a substrate onto which probes may be formed (which may be a permanent substrate such as a space transformer or a temporary substrate). After the operation of Block A, the process moves to Block B which calls for forming probe preforms (i.e. probes that have not yet taken on a final externally unstressed configuration and/or have otherwise not completed full formation to become vertical probes) on the substrate for example using an electrochemical fabrication process similar to those noted with regard to FIGS. 8, 10, and 12 wherein the probe preforms are formed with lateral probe-to-probe positions (e.g. upper ends and/or lower ends) that correspond to intended array positions.

After the operation of Block B, the process moves to Block C which calls for removing (if necessary) sacrificial material from an upper portion of the preforms and possibly from other portion of the preforms so as to at least expose an upper portion of the probe preforms while still leaving a majority of each of the plurality of probe preforms encased in sacrificial material. After the operation of Block C, the process moves to Block D which calls for laterally positioning at least one deformation plate and one compression plate over the upper most tips of the probe preforms such that probe preform ends (e.g. tips) are laterally aligned with through holes in the at least one deformation plate.

After the operation of Block D, the process moves to Block E which calls for lowering the at least one deformation plate and compression plate over the upper ends of the probe preforms to a desired longitudinal height. After the operation of Block E, the process moves to Block F, if necessary, which calls for removing at least a portion of the remaining sacrificial material from the array of probe preforms. As with other steps, additional operations may be performed, for example, such as heat treating to remove stress, to reduce or enhance yield strength and/or to improve interlayer adhesion in preparation for deformation.

After the operation of Block F, the process moves to Block G which calls for flowing, or otherwise locating, a sufficient quantity of stabilization material between the substrate and the compression plate. After the operation of Block G, the process moves to Block H which calls for longitudinally positioning the at least one deformation plate at the desired deformation level(s) as necessary and the compression plate to press the stabilization fluid to a stabilization region, and possibly setting it (e.g., solidifying it).

After the operation of Block H, the process moves to Block I which calls for cleaning up any displaced stabilization fluid, possibly setting the stabilization fluid, and removing the compression plate if it is not to be retained (e.g. by dissolving). After the operation of Block I the process moves to Block J which calls for laterally shifting (as necessary) the at least one deformation plate to prepare for plastic deformation of the probe preforms and then laterally shifting (possibly with some longitudinal shifting as well) the at least one deformation plate, in at least one direction, beyond an elastic deformation range into a plastic deformation range such that a desired level of lateral plastic deformation occurs where the total lateral displacement may be larger than the resulting plastic deformation as the preforms may retain some elastic deformation. Further lateral and/or longitudinal movement can occur if multiple serial deformations are to occur or if repositioning for retention as one or more guide plates is to occur. In some embodiment variations, this may be the last step of the process as the operations of Block K and L may not be necessary.

After the operation of Block J, for deformation plates that are not to be retained as guide plates, the process moves to Block K which calls for removing the deformation plates by longitudinal displacement (perhaps with lateral displacement(s) that provide for reducing biasing during longitudinal movement) or other means such as dissolving the plates. After the operation of Block K, the process moves to Block L which calls for performing any additional processing steps (e.g. those noted in FIG. 4). Other examples are possible and will be understood by those of skill in the art upon review of the teachings set forth herein or incorporated here by reference.

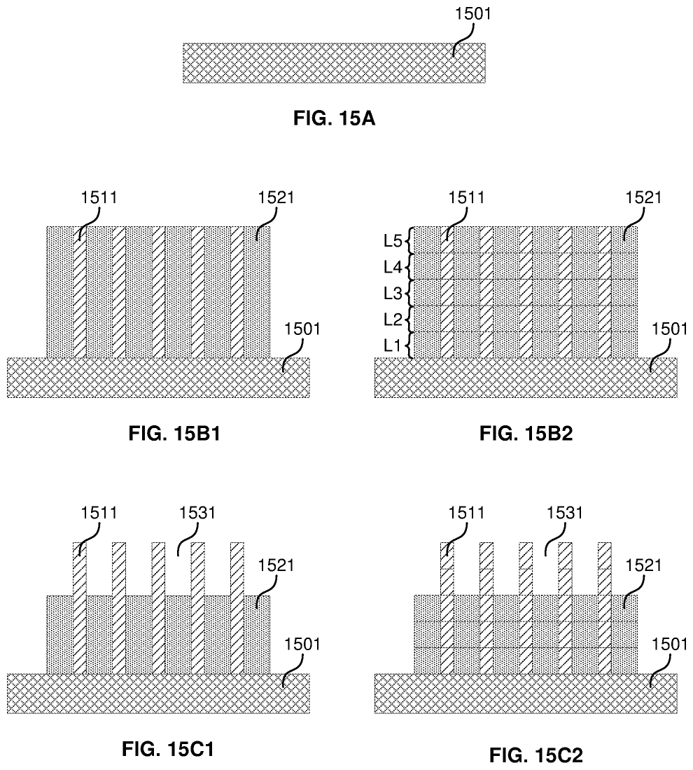

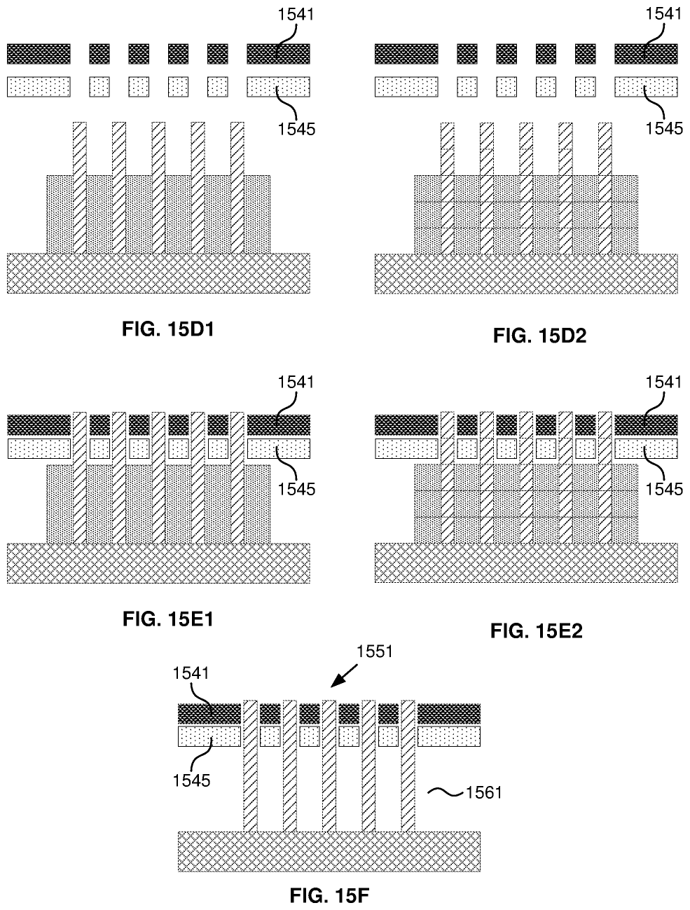

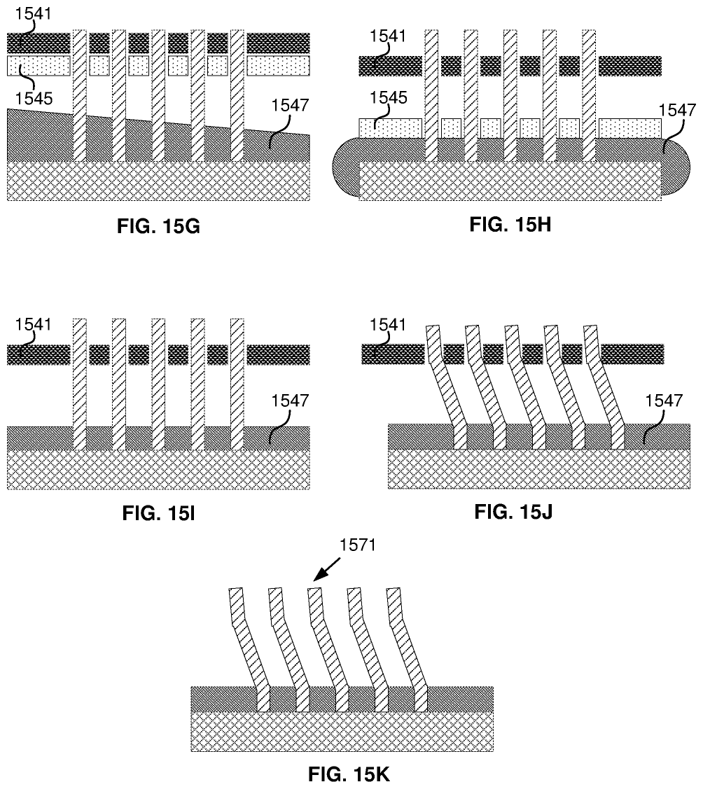

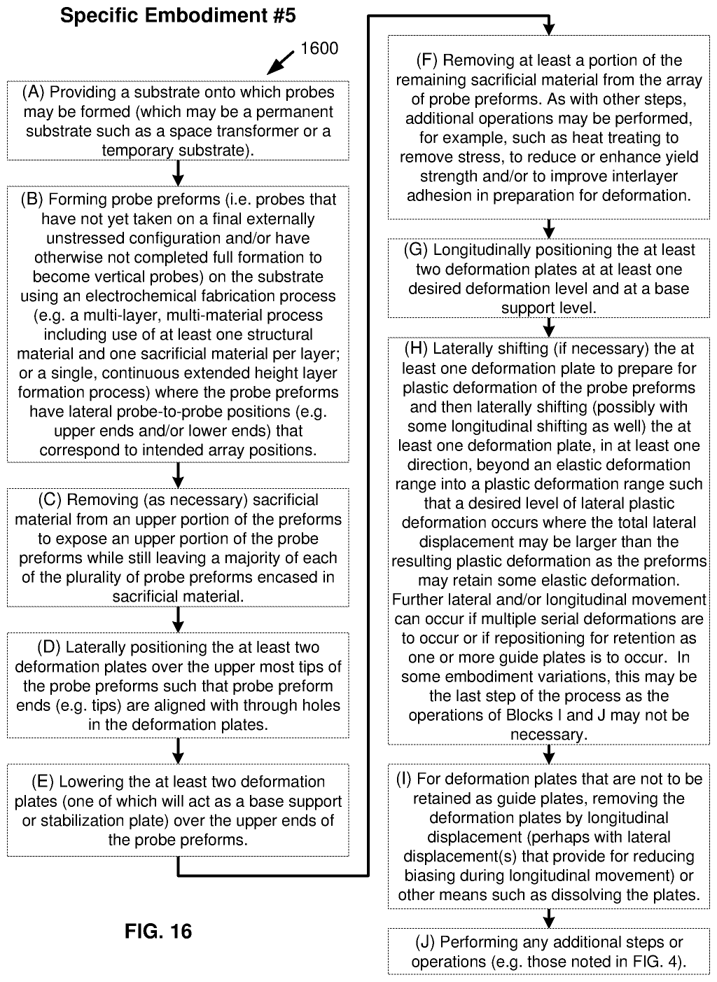

FIGS. 15A-15K provide cut side views of example results of the steps set forth in operational Blocks A-K of FIG. 14. In particular, in this example, the formation of an array of probes (exemplified with five probe preforms/probes) occurs via the formation of a single layer from a structural material and a sacrificial material or via formation of multiple, multi-material layers (exemplified with five layers) where the probe preforms are held at their lower ends by a substrate and eventually also by a stabilization material that is added after removal of sacrificial material but prior to plastic deformation of the preforms by lateral movement of a deformation plate relative to a substrate, wherein the deformation plate is not retained as a guide plate in a final array assembly. The final probe array is configured to allow elastic compression of the probes when the probes are made to contact an electronic component. In some variations, of the process no sacrificial material may be used in the formation of the preforms.

The following states of the process can be seen in FIGS. 15A-15K: (1) a substrate 1501 after being supplied (FIG. 15A); (2) in a first alternative, probe preforms 1511 and surrounding sacrificial material 1521 after buildup of a single layer on the substrate (FIG. 15B1) or in a second alternative, after buildup of a number of multi-material layers L1-L5 on the substrate (FIG. 15B2); (3) in the first alternative, the upper portion 1531 of the single layer with sacrificial material removed (FIG. 15C1) or in the second alternative, one or more upper layers 1531 with sacrificial material removed (FIG. 15C2); (4) the partially formed array with a deformation plate 1541 and a compression plate 1545 after lateral placement over the single layer probe preforms of the first alternative (FIG. 15D1) or over the multi-layer probe preforms of the second alternative (FIG. 15D2); (5) the partially formed array with the deformation plate and the compression plate after longitudinal placement around the single layer probe preforms of the first alternative (FIG. 15E1) or the multi-layer preforms of the second alternative (FIG. 15E2), (6) the partially completed array 1551 with sacrificial material removed 1561 (FIG. 15F) where the distinction between single layer preforms and multi-layer preforms is no longer illustrated; (7) the partially formed array after a flowable stabilization material 1547 has been inserted around the preforms between the substrate and the compression plate (FIG. 15G); (8) the partially formed array after the compression plate has been made to compress the stabilization material against the substrate and where excess stabilization material has been pushed out (FIG. 15H); (9) the partially formed array after removal of the excess stabilization material and removal of the compression plate leaving beyond compressed and solidified stabilization material (FIG. 15I); (10) the partially formed probe array after the deformation plate has been laterally shifted to the left relative to the substrate to cause plastic deformation of the preforms (FIG. 15J); and (11) the array 1571 after the removal of deformation plate where the deformed preforms have taken on desired probe configurations and are located with desired probe-to-probe positions such that the final probe array is represented or alternatively an array that is ready for additional operations as optionally called for in Block L of FIG. 14 is provided (FIG. 15K).

As with FIGS. 8 and 9A-9H, 10 and 11A-11I, and 12 and 13A-13I, numerous additional variations of the embodiment of FIGS. 14 and 15A-15K are possible and include intra alia, individual operations and/or features noted with regard to these earlier specific embodiments and their variations as well as individual operations and/or variations associated with subsequent embodiments set forth herein. Additional examples include (1) the compression plate being retained and used as a deformation plate or stabilization plate during preform deformation; (2) the compression plate being retained as a guide plate; (3) solidification of the stabilization material by a method selected from the group consisting of evaporation of a solvent, exposure to UV radiation, removal of oxygen from the surrounding atmosphere (by compression, creation of a vacuum, or displacement with a different gas, reduction in temperature, time based solidification initiated by addition of second component either before or after introduction of the stabilization material into the array, pressure based solidification as a result of compression, and removal of oxygen and associated reaction inhibition by compression; (4) removal of the compression plate by dissolution; and (5) removal of the compression plate after removal of the deformation plate.

FIG. 16 provides a simplified flowchart of a fifth specific embodiment of the invention for forming a probe array with a base support deformation plate and a second deformation plate, both inserted from above after probe preform formation and after partial removal of a sacrificial material wherein the second deformation plate may be removed from the final probe array or may be retained as a guide plate. Flowchart 1600 sets forth operations, steps, or groups of operations or steps, A-J similar to those of Flowchart 800 with the exception that steps D, E, and G include the positioning of at least two deformation plates for which one acts as base support or stabilization plate.

The process of FIG. 16 begins with Block A which calls for providing a substrate onto which probes may be formed (which may be a permanent substrate such as a space transformer or a temporary substrate). After the operation of Block A, the process moves to Block B which calls for forming probe preforms (i.e. probes that have not yet taken on a final externally unstressed configuration and/or have otherwise not completed full formation to become vertical probes) on the substrate using an electrochemical fabrication process (e.g. via a multi-layer, multi-material process including use of at least one structural material and one sacrificial material per layer, via a single layer material or multiple material formation process, or via a continuous extended height layer formation process, e.g. an ELEX process) where the probe preforms have lateral probe-to-probe positions (e.g. upper ends and/or lower ends) that correspond to intended array positions.

After the operation of Block B, the process moves to Block C which calls for removing (as necessary) sacrificial material from an upper portion of the preforms to expose an upper portion of the probe preforms while still leaving a majority of each of the plurality of probe preforms encased in sacrificial material. After the operation of Block C, the process moves to Block D which calls for laterally positioning the at least two deformation plates over the upper most tips of the probe preforms such that probe preform ends (e.g. tips) are aligned with through holes in the deformation plates.

After the operation of Block D, the process moves to Block E which calls for lowering the at least two deformation plates (one of which will act as a base support or stabilization plate) over the upper ends of the probe preforms. After the operation of Block E, the process moves to Block F which calls for removing at least a portion of the remaining sacrificial material from the array of probe preforms. As with other steps, additional operations may be performed, for example, such as heat treating to remove stress, to reduce or enhance yield strength and/or to improve interlayer adhesion in preparation for deformation.

After the operation of Block F, the process moves to Block G which calls for longitudinally positioning the at least two deformation plates at at least one desired deformation level and at a base support level. After the operation of Block G, the process moves to Block H which calls for laterally shifting (if necessary) the at least one deformation plate to prepare for plastic deformation of the probe preforms and then laterally shifting (possibly with some longitudinal shifting as well) the at least one deformation plate, in at least one direction, beyond an elastic deformation range into a plastic deformation range such that a desired level of lateral plastic deformation occurs where the total lateral displacement may be larger than the resulting plastic deformation as the preforms may retain some elastic deformation. Further lateral and/or longitudinal movement can occur if multiple serial deformations are to occur or if repositioning for retention of the deformation plate or plates as one or more guide plates is to occur. In some embodiment variations, this may be the last step of the process as the operations of Blocks land J may not be necessary.

After the operation of Block H, for deformation plates that are not to be retained as guide plates, the process moves to Block I which calls for removing the deformation plates by longitudinal displacement (perhaps with lateral displacement(s) that provide for reducing biasing during longitudinal movement) or other means such as dissolving the plates. After the operation of Block I, the process moves to Block J which calls for performing any additional steps or operations (e.g. those noted in FIG. 4). Other examples are possible and will be understood by those of skill in the art upon review of the teachings set forth herein or incorporated here by reference.

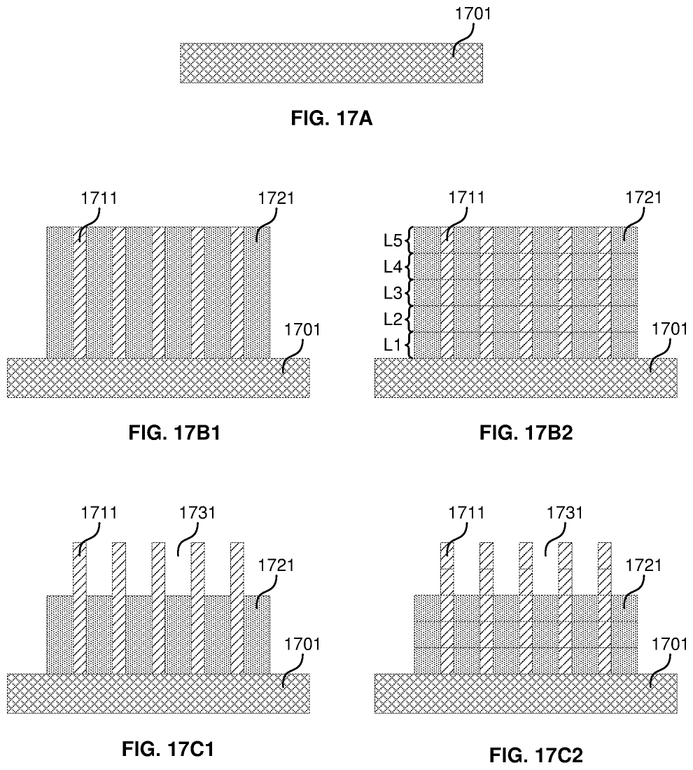

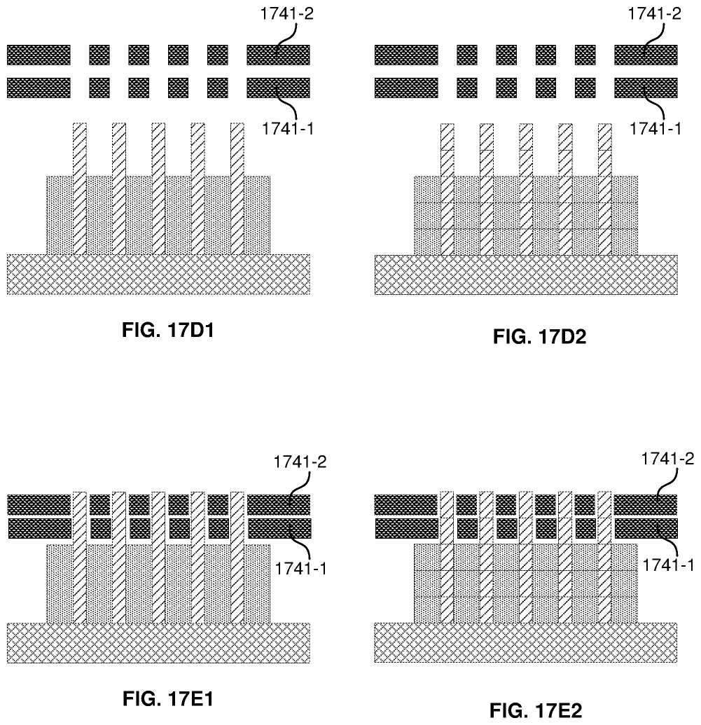

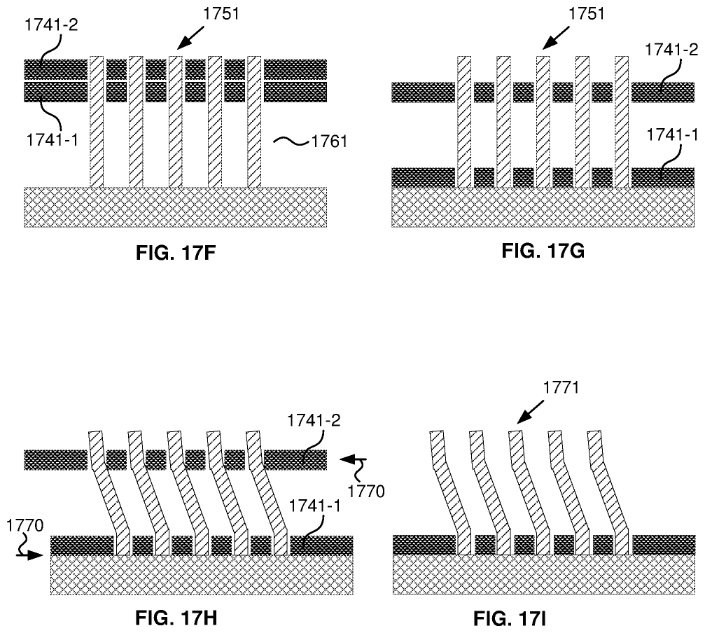

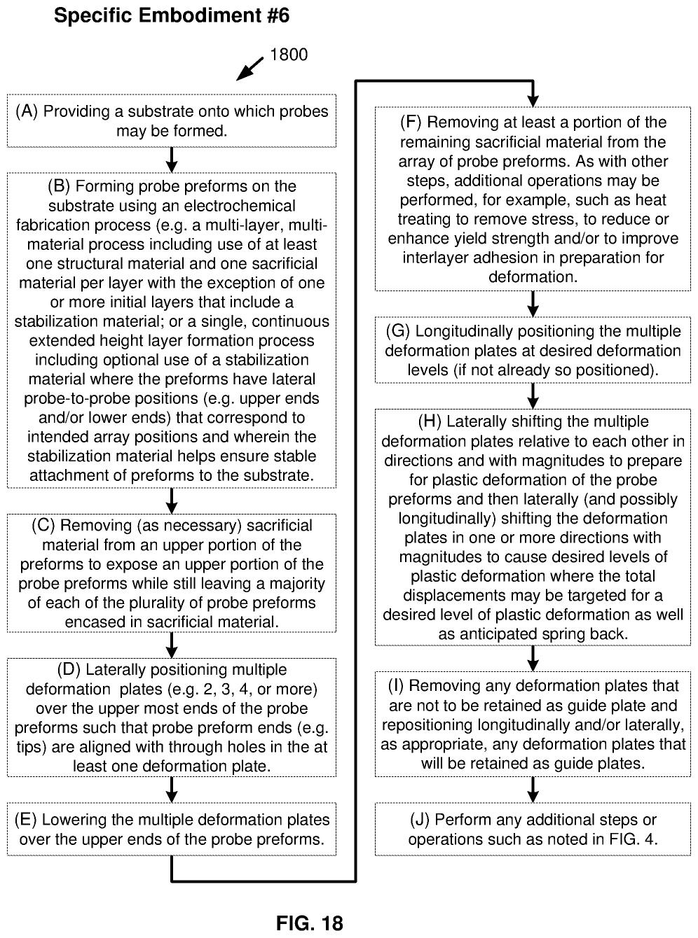

FIGS. 17A-17I provide cut side views of example results of the steps set forth in operational Blocks A-I of FIG. 16. In particular, in this example, the formation of an array of probes (exemplified with five probe preforms/probes) occurs via the formation of a single layer out of a structural material and a sacrificial material or via formation of multiple, multi-material layers (exemplified with five layers) where the probe preforms are held at their lower ends by a substrate and eventually also by a deformation plate or stabilization plate that is added after removal of sacrificial material but prior to plastic deformation of the preforms which occurs by lateral movement of an upper deformation plate relative to a substrate and a stabilization plate located against the substrate, wherein at least the stabilization plate will be retained as part of the array assembly during use of the array. The final probe array is configured to allow elastic compression of the probes when the probes are made to contact an electronic component.

The following states of the process can be seen in FIGS. 17A-17I: (1) a substrate 1701 after being supplied (FIG. 17A); (2) probe preforms 1711 and surrounding sacrificial material 1721 after buildup of a single layer on the substrate (FIG. 17B1) or after buildup of a number of multi-material layers L1-L5 on the substrate (FIG. 17B2); (3) the upper portion 1731 of the single layer with sacrificial material removed (FIG. 17C1) or one or more upper layers 1731 with sacrificial material removed (FIG. 17C2); (4) the partially formed array after lateral placement of a lower deformation plate 1741-1 and an upper deformation plate 1741-2 above the single layer probe preforms (FIG. 17D1) or above the multi-layer probe preforms (FIG. 17D2); (5) the partially formed array after the deformation plates are longitudinally placed around the single layer probe preforms (FIG. 17E1) or around the multi-layer preforms (FIG. 17E2); (6) the partially completed array 1751 without sacrificial material 1761 (FIG. 17F) where the distinction between single layer preforms and multi-layer preforms is no longer illustrated; (7) the probe preform array after longitudinally shifting the two deformation plates to their desired longitudinal levels with the lower plate located in contact with the substrate so it may act as a preform/substrate attachment stabilization element while the upper deformation plate is positioned at a desired deformation level (FIG. 17G); (8) the probe array with the upper deformation plate shifted to the left relative to the substrate (and the stabilization plate) (as illustrated by left and right pointing arrows 1770) to cause plastic deformation of the preforms (FIG. 17H); and (9) the array 1771 after removal of the deformation plate showing deformed preforms having desired probe configurations and probe-to-probe lateral array positions such that the final probe array is represented or alternatively an array that is ready for additional operations as optionally called for in Block J of FIG. 16 is provided (FIG. 17I).

As with FIGS. 8 and 9A-9H, 10 and 11A-11I, 12 and 13A-13I, and 14 and 15A-15L, numerous additional variations of the embodiment of FIGS. 16 and 17A-17I are possible and include intra alia, individual operations and/or features noted with regard to these earlier specific embodiments and their variations as well as individual operations and/or variations associated with subsequent embodiments set forth herein. Additional examples include (1) moving the first deformation plate or stabilization plate against the substrate after deformation such that it provides stabilized probe positioning during use of the array but not during plastic deformation of the preforms, and (2) removal of the stabilization plate after deformation along with the deformation plate.

FIG. 18 provides a simplified flowchart of a sixth specific embodiment of the invention for forming a probe array using a plurality of deformation plates inserted from above after probe preform formation and partial removal of sacrificial material that can be used in creating multiple plastic deformation regions in a parallel manner wherein all the deformation plates may be removed from the final probe array or one or more may be retained as guide plates. Flowchart 1800 sets forth operations, steps, or groups of operations or steps, A-J which are similar to the steps of Flowchart 1600 with the primary difference being that the multiple deformation plates are use in parallel, i.e. simultaneously or substantially at the same time, according to step H to cause multiple deformations of each probe preform as part of the process of making a probe array.

The process of FIG. 18 begins with Block (A) which calls for providing a substrate onto which probes may be formed. After the operation of Block (A), the process moves to Block (B) which calls for forming probe preforms on the substrate using an electrochemical fabrication process (e.g. via a multi-layer, multi-material process including use of at least one structural material and one sacrificial material per layer with the exception of one or more initial layers that include a stabilization material, via a single layer material or multiple material formation process, or via a continuous extended height layer formation process e.g. an ELEX process) including optional use of a stabilization material where the preforms have lateral probe-to-probe positions (e.g. upper ends and/or lower ends) that correspond to intended array positions and wherein the stabilization material helps ensure stable attachment of preforms to the substrate.

After the operation of Block (B), the process moves to Block (C) which calls for removing (as necessary) sacrificial material from an upper portion of the preforms to expose an upper portion of the probe preforms while still leaving a majority of each of the plurality of probe preforms encased in sacrificial material. After the operation of Block (C), the process moves to Block (D) which calls for laterally positioning multiple deformation plates (e.g. 2, 3, 4, or more) over the upper most ends of the probe preforms such that probe preform ends (e.g. tips) are aligned with through holes in the at least one deformation plate.

After the operation of Block (D), the process moves to Block (E) which calls for lowering the multiple deformation plates over the upper ends of the probe preforms. After the operation of Block (E), the process moves to Block (F) which calls for removing at least a portion of the remaining sacrificial material from the array of probe preforms. As with other steps, additional operations may be performed, for example, such as heat treating to remove stress, to reduce or enhance yield strength and/or to improve interlayer adhesion in preparation for deformation.

After the operation of Block (F), the process moves to (G) which calls for longitudinally positioning the multiple deformation plates at desired deformation levels (if not already so positioned). After the operation of Block (G), the process moves to Block (H) laterally shifting the multiple deformation plates relative to each other in directions and with magnitudes to prepare for plastic deformation of the probe preforms and then laterally (and possibly longitudinally) shifting the deformation plates in one or more directions with magnitudes to cause desired levels of plastic deformation where the total displacements may be targeted for a desired level of plastic deformation as well as anticipated spring back.

After the operation of Block (H), the process of Block (I) which calls for removing any deformation plates that are not to be retained as guide plate and repositioning longitudinally and/or laterally, as appropriate, any deformation plates that will be retained as guide plates. After the operation of Block (I), the process moves to Block (J) which calls for performing any additional steps or operations such as noted in FIG. 4. Other examples are possible and will be understood by those of skill in the art upon review of the teachings set forth herein or incorporate here by reference.

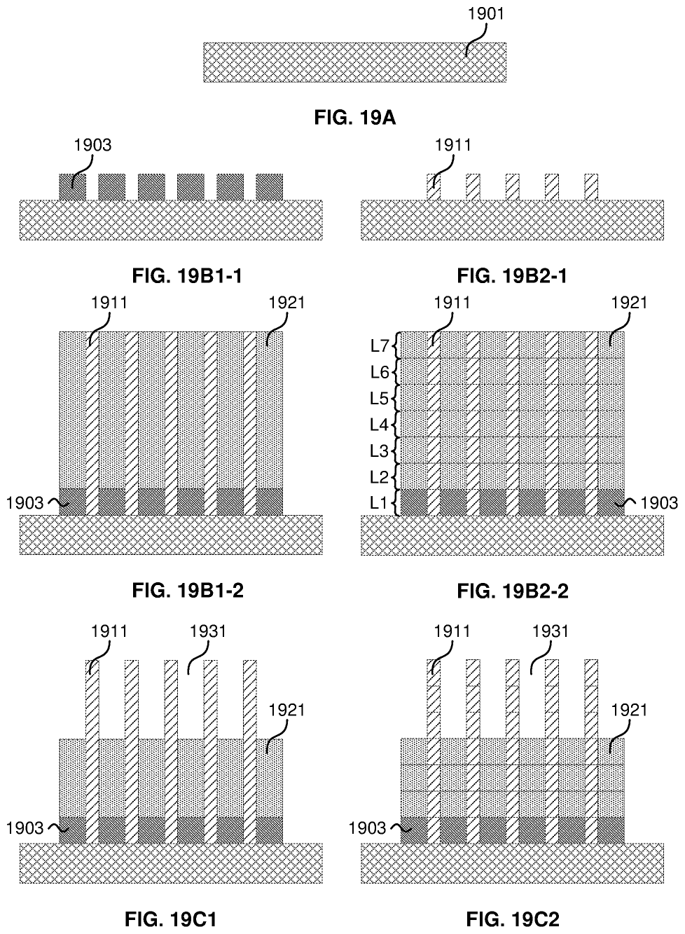

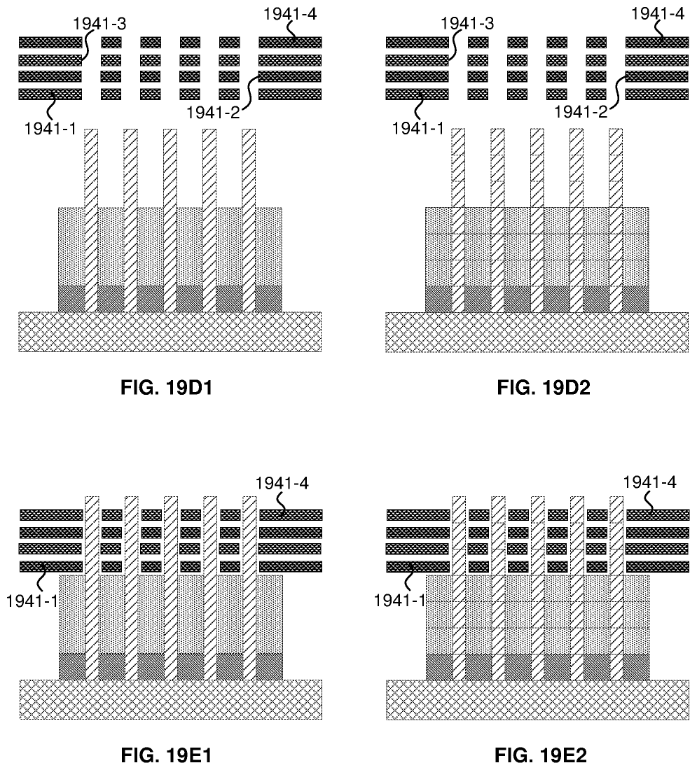

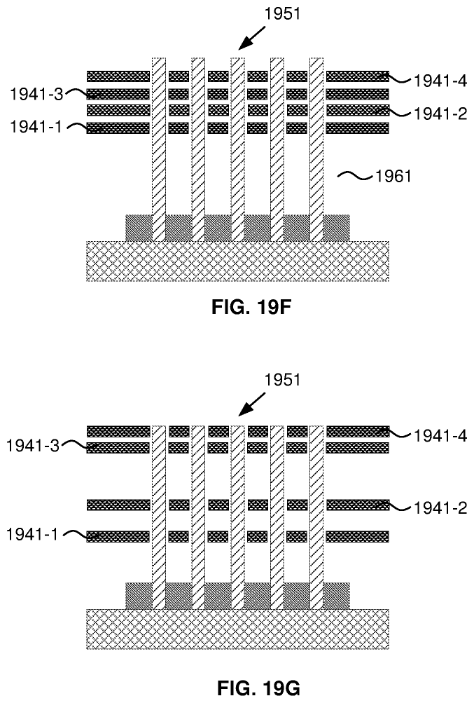

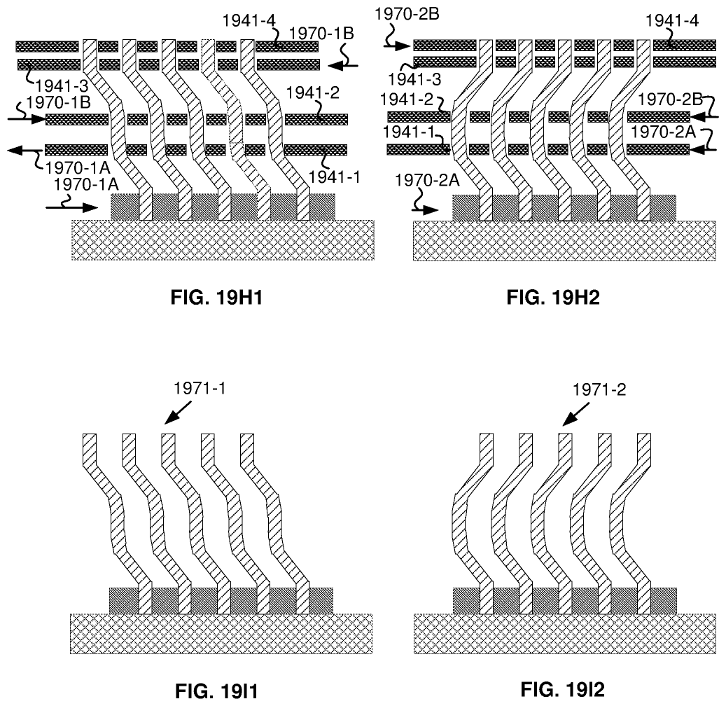

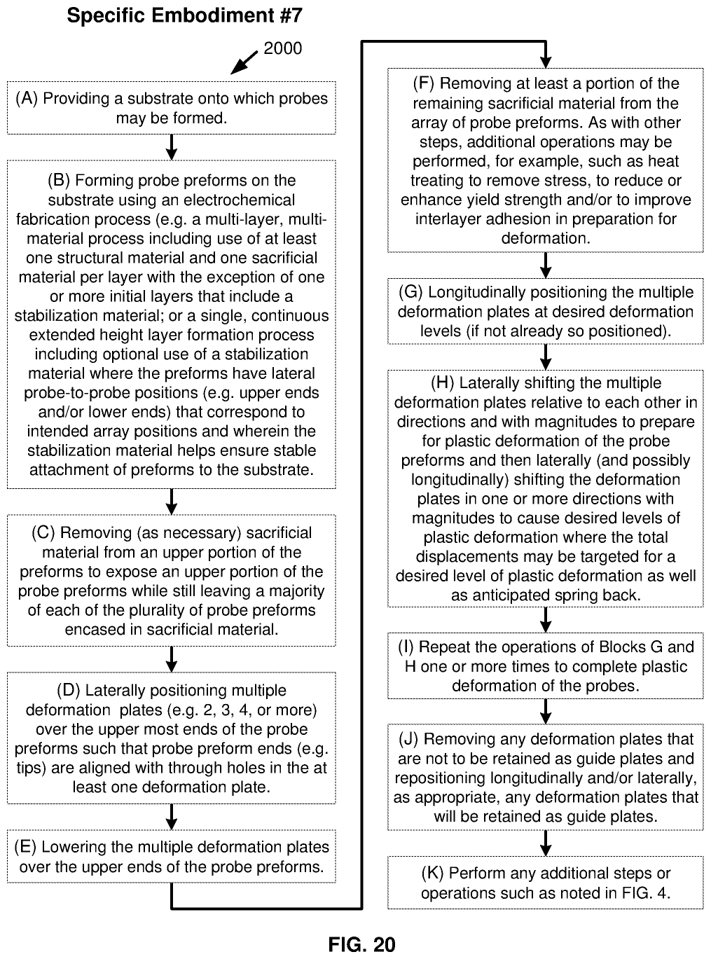

FIGS. 19A-19I2 provide cut side views of example results of the steps set forth in operational Blocks A-I of FIG. 18 wherein some of the steps illustrate deformation plate placement and movement that result in probes having different structural configurations. In particular, in this example, the formation of an array of probes (exemplified with five probe preforms/probes) occurs via the formation of a single layer from a structural material and a sacrificial material or from multiple, multi-material layers (exemplified with seven layers) where the probe preforms are held at their lower ends by a substrate and by a surrounding thin region (e.g. 1 layer thickness or less) of stabilization material and are laterally plastically deformed (i.e. shaped) by parallel (i.e. substantially simultaneously) manipulation of a plurality of deformation plates by movement relative to each other and to a substrate. The final probe array is configured to allow elastic compression of the probes when the probes are made to contact an electronic component.

Various states of the process can be seen in FIGS. 19A-19I2: (1) a substrate 1901 after being supplied (FIG. 19A); (2) in a first alternative, an initial formation of a patterned dielectric stabilization material 1903 is formed (FIG. 19B1-1) and is followed by the formation of probe preforms 1911 from a single layer with portions above the stabilization material being occupied with a sacrificial material 1921 which may be dielectric or conductive (FIG. 19B1-2) or alternatively an initial patterned formation of structural probe preform material 1921 (FIG. 19B2-1) which is followed by deposition of a stabilization material and planarization to form a first layer L1 which in turn is followed by formation of six additional multi-material layers L2-L7 including probe preform material and a sacrificial material (FIG. 19B2-2); (3) in a first alternative, sacrificial material has been removed from the upper portion 1931 of the single layer of probe preform material (FIG. 19C1) while in a second alternative, sacrificial material has been removed from the three upper most layers 1931 of the multi-layer preforms (FIG. 19C2); (4) in a first alternative and in a second alternative, a plurality of deformation plates 1941-1 to 1941-4 have been laterally placed above the single layer probe preforms (FIG. 19D1) and over the multi-layer probe preforms (FIG. 19D2) respectively; (5) in a first alternative and in a second alternative, the plurality of deformation plates have been longitudinally placed around the single layer probe preforms (FIG. 19E1) or the multi-layer preforms (FIG. 19E2) respectively, (6) the sacrificial material is removed 1961 from the partially completed array 1951 (FIG. 19F) where the distinction between single layer preforms and multi-layer preforms is no longer illustrated; (7) the plurality of deformation plates have been longitudinally placed at their respective deformation locations around the probe preforms (FIG. 19G); (8) in one alternative, the substrate or stabilization material is moved to the right relative to the lower pair of deformation plates (as illustrated with the pair of arrows labeled 1970-1A); simultaneously therewith or before or after such relative movement, the lower pair of deformation plates is moved to the right relative to the upper pair of deformation plates (as illustrated with the pair of arrows labeled 1970-1B) such that plastic deformation occurs, yielding a plurality of two-step leftward leaning probes (FIG. 19H1) while in a second alternative, the substrate or stabilization material is moved to the right relative to the lower pair of deformation plates (as illustrated with the pair of arrows labeled 1970-2A); simultaneously therewith or before or after such relative movement, the lower pair of deformation plates is moved to the left relative to the upper pair of deformation plates (as illustrated with the pair of arrows labeled 1970-2B) (e.g. depending on whether excess movement is needed to achieve a final desired configuration in view of any retained elastic deformation) such that plastic deformation occurs yielding a plurality of C-shaped probes (FIG. 19H2); and (9) for arrays 1971-1 and 1971-2 having first and second alternative probe configurations, the deformation plates were removed leaving the arrays with deformed preforms (e.g., probes) that have desired probe configurations and probe-to-probe lateral array positions such that the final probe arrays are represented or such that arrays that are ready for additional operations as optionally called for in Block J of FIG. 18 are provided (FIGS. 19I1 and 19I2).

As with FIGS. 8 and 9A-9H, 10 and 11A-11I, 12 and 13A-13I, 14 and 15A-15L, and 16 and 17A-17I, numerous additional variations of the embodiment of FIGS. 18 and 19A-19I2 are possible and include intra alia, individual operations and/or features noted with regard to these earlier specific embodiments and their variations as well as individual operations and/or variations associated with subsequent embodiments set forth herein. Additional examples include: (1) instead of removing sacrificial material from the upper portion of a layer, from a whole layer or from a plurality of layers, the sacrificial material may never have been located there; (2) to better control the removal of sacrificial material from the upper portion of a layer, from a whole layer, or from a plurality of layers, a different sacrificial material may be used in those regions compared to other regions so that it may be removed using a process that does remove the other sacrificial material; (3) instead of the upper region of preforms being surrounded by a conductive sacrificial material, they may be surround by a patterning material such as dielectric photoresist or the like; (4) any dielectric regions to be overcoated by electrodeposited material may first be coated with a seed layer; (5) the deformation plates may be laterally aligned and longitudinally positioned onto the probe preforms one at a time or in subgroups; (6) the deformation plates may be loaded in subgroups with other operational steps occurring between loading some of the groups; (7) in some alternatives, the deformation plates may not be moved in pairs, or at least not always moved in pairs, such that adjacent plates may be moved in different amounts and potentially in different relative directions to cause differential amounts of deformation; (8) in some alternatives, lateral shifting may occur by an amount that is in excess of the desired deformation amount in anticipation that not all deflection will be plastic deformation but some might be due to elastic deformation, (9) in some alternatives, plastic deflection amounts may be tested and incremental additional lateral motion induced until a desired level of plastic deformation is achieved; (10) in some alternatives, deflection by all deformation plates may occur in substantially a parallel manner while in other alternatives, some amount of deformation may be implemented in a serial manner; (11) in some embodiments, spacing between lower ends of probes might not be identical to the spacing of the upper ends of at least some probes; (12) due to different anticipated deformation amounts for different probe materials or preform configurations, lower array spacings of preforms may intentionally be set so that upon differential deformation the upper array spacings, though different from the lower array spacings, intended spacing configurations are achieved.

FIG. 20 provides a simplified flowchart of a seventh specific embodiment of the invention for forming a probe array using a plurality of deformation plates inserted from above after probe preform formation and partial removal of sacrificial material that can be used in creating multiple plastic deformation regions in a serial manner (i.e. deformations at each deformation level occur one after another as opposed to at the same time where different plates may be used for the different deformations or plates may be reused after repositioning to cause one or more subsequent deformations) wherein all the deformation plates may be removed from the final probe array or one or more may be retained as guide plates. Flowchart 2000 sets forth operations, steps, or groups of operations or steps, A-K which are similar to those of Flowchart 1800 with the insertion of a step I which calls for the repeated operation of steps G and H one or more times to provide for a plurality of serial deformations.

The process of FIG. 20 begins with Block A which calls for providing a substrate onto which probes may be formed. After the operation of Block A, the process moves to Block B which calls for forming probe preforms on the substrate using an electrochemical fabrication process (e.g. via a multi-layer, multi-material process including use of at least one structural material and one sacrificial material per layer with the exception of one or more initial layers that include a stabilization material, via a single layer material or multiple material formation process, or via a continuous extended height layer formation process, e.g. an ELEX process) including optional use of a stabilization material where the preforms have lateral probe-to-probe positions (e.g. upper ends and/or lower ends) that correspond to intended array positions and wherein the stabilization material helps ensure stable attachment of preforms to the substrate.

After the operation of Block B, the process moves to Block C which calls for removing (as necessary) sacrificial material from an upper portion of the preforms to expose an upper portion of the probe preforms while still leaving a majority of each of the plurality of probe preforms encased in sacrificial material. After the operation of Block C, the process moves to Block D which calls for laterally positioning multiple deformation plates (e.g. 2, 3, 4, or more) over the upper most ends of the probe preforms such that probe preform ends (e.g. tips) are aligned with through holes in the at least one deformation plate.

After the operation of Block D, the process moves to Block E which calls for lowering the multiple deformation plates over the upper ends of the probe preforms. After the operation of Block E, the process moves to Block F which calls for removing at least a portion of the remaining sacrificial material from the array of probe preforms. As with other steps, additional operations may be performed, for example, such as heat treating to remove stress, to reduce or enhance yield strength and/or to improve interlayer adhesion in preparation for deformation.

After the operation of Block F, the process moves to Block G which calls for longitudinally positioning the multiple deformation plates at desired deformation levels (if not already so positioned). After the operation of Block G, the process moves to Block H which calls for laterally shifting the multiple deformation plates relative to each other in directions and with magnitudes to prepare for plastic deformation of the probe preforms and then laterally (and possibly longitudinally) shifting the deformation plates in one or more directions with magnitudes to cause desired levels of plastic deformation where the total displacements may be targeted for a desired level of plastic deformation as well as anticipated spring back.

After the operation of Block H, the process moves to Block I which calls for repeating the operations of Blocks G and H one or more times to complete plastic deformation of the probes. After the operation of Block I, the process moves to Block J which calls for removing any deformation plates that are not to be retained as guide plates and repositioning longitudinally and/or laterally, as appropriate, any deformation plates that will be retained as guide plates. After the operation of Block J, the process moves to Block K which calls for performing any additional steps or operations such as noted in FIG. 4. Other examples are possible and will be understood by those of skill in the art upon review of the teachings set forth herein or incorporate here by reference . . . .

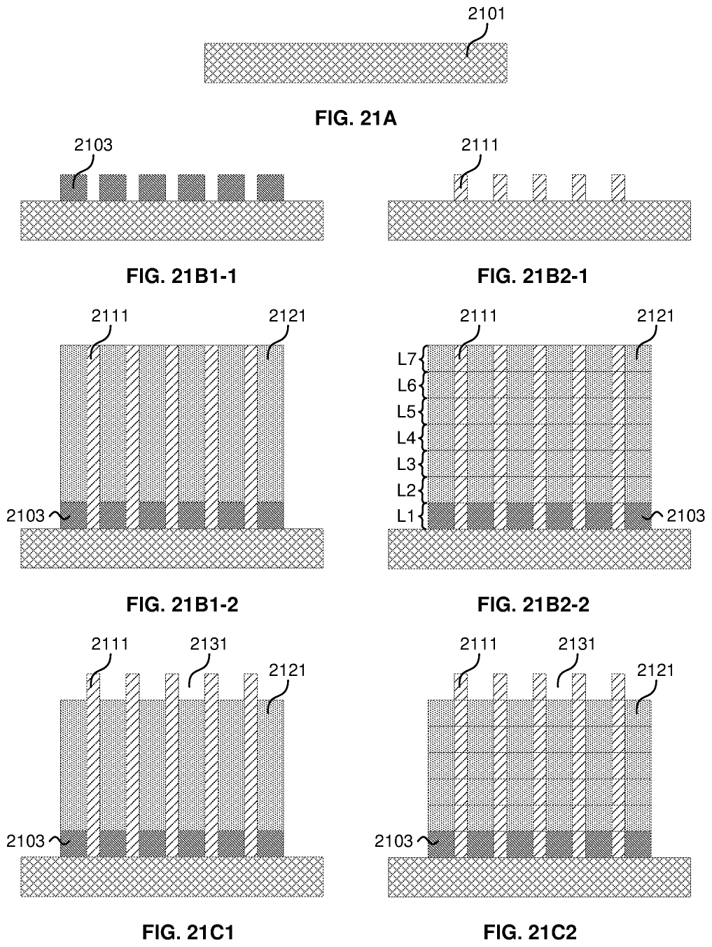

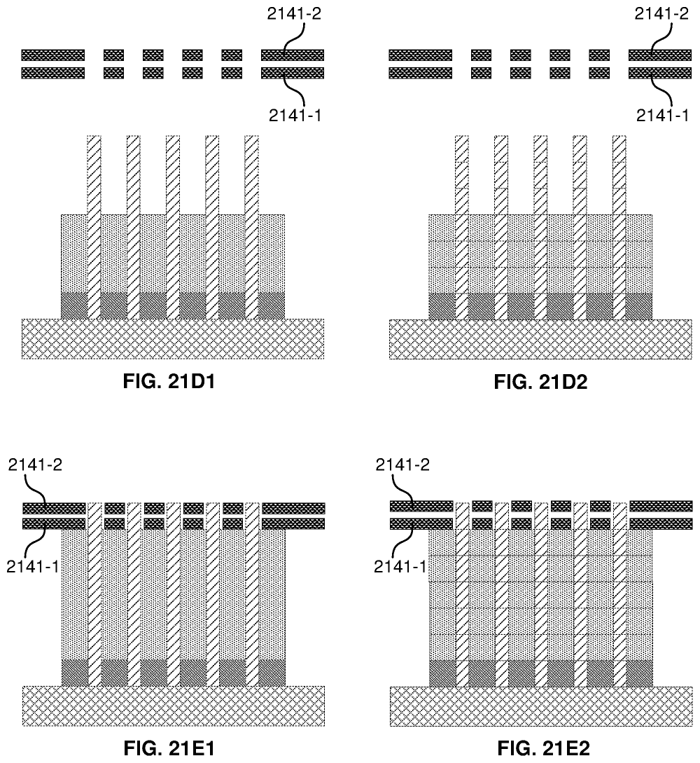

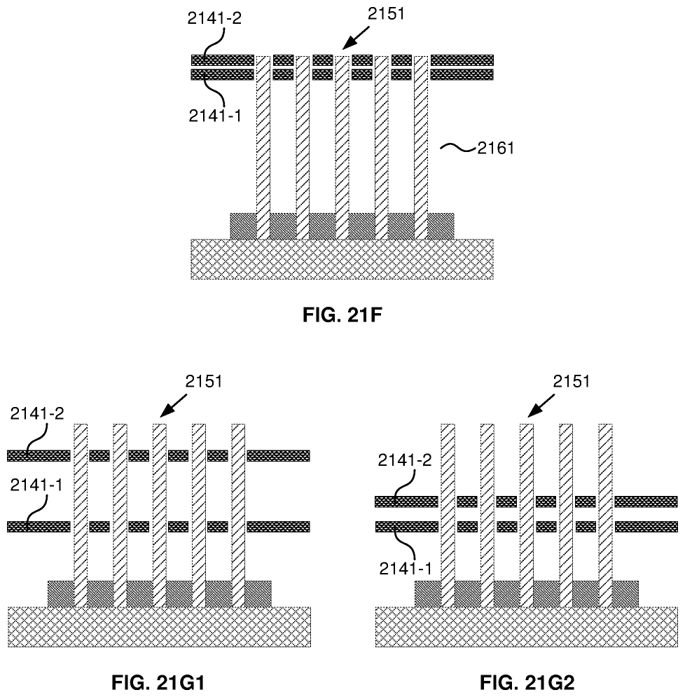

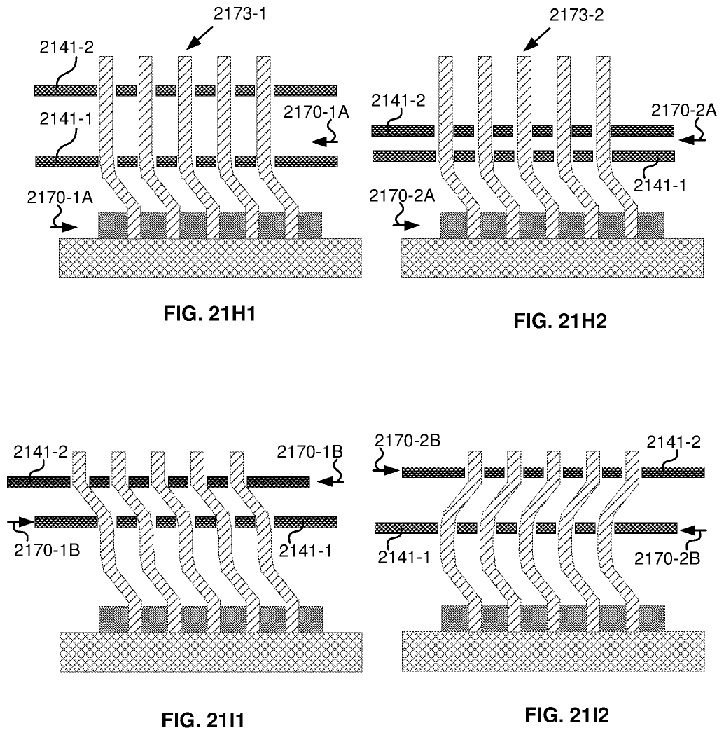

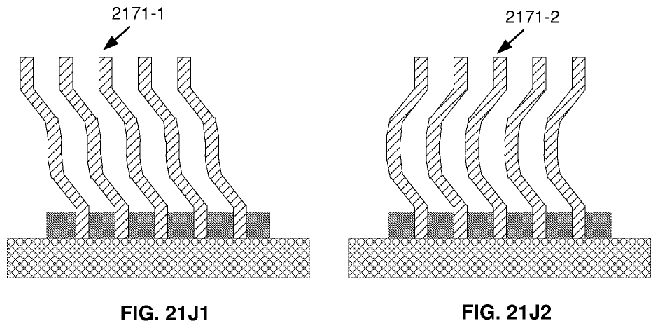

FIGS. 21A-21J2 provide cut side views of example results of the steps set forth in operational Blocks A-J of FIG. 20 wherein some of the steps illustrate deformation plate placement and movement that result in probes having different structural configurations. In particular, in this example, the formation of an array of probes (exemplified with five probe preforms/probes) occurs via the formation of a single layer from a structural material and a sacrificial material or from multiple, multi-material layers (exemplified with seven layers) where the probe preforms are held at their lower ends by a substrate and by a surrounding thin region of stabilization material and are laterally plastically deformed (i.e. shaped) by serial displacements of a plurality of deformation plates by movement relative to each other and potentially to a substrate, wherein the deformation plate is not retained as a guide plate in a final array assembly wherein the probe array is configured to allow elastic compression of the probes when the probes are made to contact an electronic component.

The following states of the process can be seen in FIGS. 21A-21I2: (1) a substrate 2101 after being supplied (FIG. 21A); (2) in a first alternative, an initial formation of a patterned dielectric stabilization material 2103 is formed (FIG. 21B1-1) and is followed by the formation of probe preforms 2111 from a single layer with portions above the stabilization material being occupied with a sacrificial material 2121 which may be dielectric or conductive (FIG. 21B1-2) or in a second alternative, an initial patterned formation of structural probe preform material 2111 is formed (FIG. 21B2-1) which is followed by deposition of a stabilization material and planarization to form a first layer L1 which in turn is followed by formation of six additional multi-material layers L2-L7 including probe preform material and a sacrificial material (FIG. 21B2-2); (3) in a first alternative, the sacrificial material has been removed from the upper portion 2131 of the single layer of probe preform material (FIG. 21C1) or in a second alternative, the sacrificial material has been removed from the upper most layer 2131 of the multi-layer preform (FIG. 21C2); (4) in a first alternative, a plurality of deformation plates 2141-1 and 2141-2 have been laterally placed over the single layer probe preforms (FIG. 21D1) while in a second alternative, the deformation plates have been laterally placed over the multi-layer probe preforms (FIG. 21D2); (5) in a first alternative, the deformation plates have been longitudinally placed around the single layer probe preforms (FIG. 21E1) while in a second alternative, the deformation plates have been placed around the multi-layer preforms (FIG. 21E2), (6) sacrificial material has been removed 2161 from a partially completed array 2151 (FIG. 21F) where the distinction between single layer preforms and multi-layer preforms is no longer illustrated; (7) in a first alternative, the deformation plates have been longitudinally shifted around the probe preforms to a first group of desired deformation levels (FIG. 21G1) and in a second alternative, the deformation plates have been longitudinally shifted around the multi-layer preforms to a different group of desired deformation levels where the deformation locations are appropriate for an initial deformation (FIG. 21G2); (8) continuing with the first alternative and the second alternatives, the deformation plates are laterally (and perhaps longitudinally) displaced (as illustrated by left and right pointing arrows 2170-1A and 2170-2A) to cause a first permanent deformation of the respective probe preforms 2173-1 and 2173-2 (FIG. 21H1 and FIG. 21H2); (9) continuing further with the first and second alternatives, the deformation plates are shifted to new longitudinal positions and then laterally displaced (and perhaps longitudinally displaced) (as illustrated by left and right pointing arrows 2170-1B and 2170-2B) to cause additional deformation of their respective preforms to yield left leaning probes (FIG. 21I1) and bowed or C-shaped probes (FIG. 21I2), respectively; and (10) for arrays 2171-1 and 2171-2 in first and second alternatives, the deformation plates have been removed leaving permanently deformed preforms (e.g. probes) having desired, respective, probe configurations and probe-to-probe lateral array positions such that the final probe array is represented or such that an array is represented that is ready for additional operations as optionally called for in Block K of FIG. 20 is provided (FIGS. 19J1 and 19J2).

As with FIGS. 8 and 9A-9H, 10 and 11A-11I, 12 and 13A-13I, 14 and 15A-15L, 16 and 17A-17I, and 18 and 19A-19I2, numerous additional variations of the embodiment of FIGS. 20 and 21A-21I2 are possible and include intra alia, individual operations and/or features noted with regard to these earlier specific embodiments and their variations as well as individual operations and/or variations associated with subsequent embodiments set forth herein.

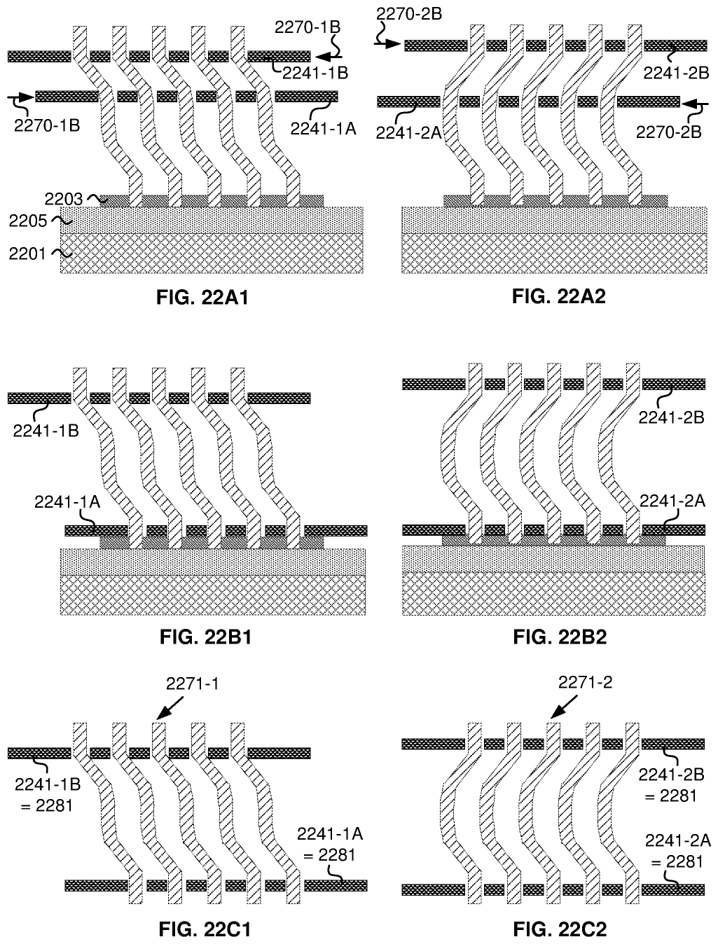

FIGS. 22A1-22C2 provide cut side views of example results of an embodiment, similar to the sixth or seventh embodiments, but where the substrates 2201 on which the probe preforms are created are temporary substrates that are spaced from the probe preforms by release layers 2205 that are removed after (1) probe formation and (2) possible movement of at least some of the deformation plates (2241-1A, 2241-1B, 2241-2A, and 2241-B) to longitudinal guide plate positions wherein the movement results in a probe array with guide plates 2281 that retain the deformed preforms (e.g. probes) in their array configurations 2271-1 and 2271-2 wherein the deformed preforms have desired, respective, probe configurations and probe-to-probe lateral array positions. In particular, FIGS. 22A1, 22B1, and 22C1 illustrate a series of states of array formation for a probe array having probes with a plurality of left leaning offsets while FIGS. 22A2, 22B2, and 22C2 illustrate a series of states of array formation for a probe array having probes with bowed or “C” shape probe configurations. FIGS. 22A1 and 22A2 show the two array configurations after a second deformation where the deformation plates are still at their longitudinal deformation levels, while FIGS. 22B1 and 22B2 show the two array configurations after movement of the deformation plates to guide plate positions, and finally FIGS. 22C1 and 22C2 show the two array configurations 2271-1 and 2271-2 after removal of the substrates and removal of the stabilization material 2203.

### FURTHER COMMENTS AND CONCLUSIONS

Various other embodiments of the present invention exist. Some of these embodiments may be based on a combination of the teachings herein with various teachings incorporated herein by reference. For example, some other embodiments, or embodiment variations may be derived, mutatis mutandis, from the generalized embodiments, specific embodiments, and alternatives set forth in previously referenced U.S. Provisional Patent Application No. 63/015,450 by Lockard, et al. For example, the guide plate to probe alignment and engagement methods of the '450 application may be used in aligning and engaging the deformation plates of the present invention. As another example, the guide plates of the '450 application that cause elastic deformation could function as deformation plates as taught in the present application wherein the plates may or may not be retained as guide plates (where any guide plate functionality may be used with or without implementing some additional amount of elastic or biased bending as taught in the '450 application). In still other variations, un-deflected probes of the various example configurations in the '450 application may be used as the probe preforms of the present application and thus may undergo some amount of shaping due to plastic deformation in addition to any configuration that they are initially formed with. Deformation plates of the present invention may have relatively large openings that allow for ease of longitudinal movement along the lengths of the probes after plastic deformation occurs. Such plates may be used for plastic deformation as longitudinally separated structures which may allow for smoother bends to be formed, but they may be placed in slightly offset lateral groups (e.g. pairs) that are in longitudinal contact such that more constrained positioning or even gripping occurs so as to allow sharper or more controlled bends to be formed. In some embodiments, such longitudinal grouping may be useful in allowing the plates to function as guide plates if they are to be retained. In other variations, the various probe to plate interface configurations noted in the '450 application may be used, mutatis mutandis, for deformation purposes or for optional guide plate purposes if the deformation plates are to be retained in the final array structures/assemblies.

Some fabrication embodiments may not use any blanket deposition process. Some embodiments may use selective deposition processes or blanket deposition processes on some layers that are not electrodeposition processes. Some embodiments may use nickel or nickel-cobalt as a structural material while other embodiments may use different materials. For example, preferred spring materials include nickel (Ni), copper (Cu), beryllium copper (BeCu), nickel phosphorous (Ni—P), tungsten (W), aluminum copper (Al—Cu), steel, P7 alloy, palladium, palladium-cobalt, silver, molybdenum, manganese, brass, chrome, chromium copper (Cr—Cu), and combinations of these. Some embodiments may use copper as the structural material with or without a sacrificial material. Some embodiments, for example, may use nickel, nickel-phosphorous, nickel-cobalt, palladium, palladium-cobalt, gold, copper, tin, silver, zinc, solder, rhodium, rhenium as structural materials while other embodiments may use different materials. Some embodiments, for example, may use copper, tin, zinc, solder or other materials as sacrificial materials. Some embodiments may use different structural materials on different layers or on different portions of single layers. Some embodiments may remove a sacrificial material while other embodiments may not. Some embodiments may use photoresist, polyimide, glass, ceramics, other polymers, and the like as dielectric structural materials.

Structural or sacrificial dielectric materials may be incorporated into embodiments of the present invention in a variety of different ways. Such materials may form a third material or higher deposited material on selected layers or may form one of the first two materials deposited on some layers. Additional teachings concerning the formation of structures on dielectric substrates and/or the formation of structures that incorporate dielectric materials into the formation process and possibly into the final structures as formed are set forth in a number of patent applications filed Dec. 31, 2003: (1) U.S. Patent Application No. 60/534,184 which is entitled “Electrochemical Fabrication Methods Incorporating Dielectric Materials and/or Using Dielectric Substrates”; (2) U.S. Patent Application No. 60/533,932, which is entitled “Electrochemical Fabrication Methods Using Dielectric Substrates”; (3) U.S. Patent Application No. 60/534,157, which is entitled “Electrochemical Fabrication Methods Incorporating Dielectric Materials”; (4) U.S. Patent Application No. 60/533,891, which is entitled “Methods for Electrochemically Fabricating Structures Incorporating Dielectric Sheets and/or Seed layers That Are Partially Removed Via Planarization”; and (5) U.S. Patent Application No. 60/533,895, which is entitled “Electrochemical Fabrication Method for Producing Multi-layer Three-Dimensional Structures on a Porous Dielectric”. These patent filings are each hereby incorporated herein by reference as if set forth in full herein.

Additional patent filings that provide, intra alia, teachings concerning incorporation of dielectrics into electrochemical fabrication processes include (1) U.S. patent application Ser. No. 11/139,262, filed May 26, 2005, now U.S. Pat. No. 7,501,328, by Lockard, et al., and which is entitled “Methods for Electrochemically Fabricating Structures Using Adhered Masks, Incorporating Dielectric Sheets, and/or Seed Layers that are Partially Removed Via Planarization”; (2) U.S. patent application Ser. No. 11/029,216, filed Jan. 3, 2005 by Cohen, et al., now abandoned, and which is entitled “Electrochemical Fabrication Methods Incorporating Dielectric Materials and/or Using Dielectric Substrates”; (3) U.S. patent application Ser. No. 11/028,957 (P-US127-A-SC), by Cohen, which was filed on Jan. 3, 2005, now abandoned, and which is entitled “Incorporating Dielectric Materials and/or Using Dielectric Substrates”; (4) U.S. patent application Ser. No. 10/841,300 (P-US099-A-MF), by Lockard et al., which was filed on May 7, 2004, now abandoned, and which is entitled “Methods for Electrochemically Fabricating Structures Using Adhered Masks, Incorporating Dielectric Sheets, and/or Seed Layers that are Partially Removed Via Planarization”; (5) U.S. patent application Ser. No. 10/841,378 (P-US106-A-MF), by Lembrikov et al., which was filed on May 7, 2004, now U.S. Pat. No. 7,527,721, and which is entitled “Electrochemical Fabrication Method for Producing Multi-layer Three-Dimensional Structures on a Porous Dielectric; (5) U.S. patent application Ser. No. 11/325,405 (P-US152-A-MF), filed Jan. 3, 2006 by Dennis R. Smalley, now abandoned, and entitled “Method of Forming Electrically Isolated Structures Using Thin Dielectric Coatings”; (6) U.S. patent application Ser. No. 10/607,931, by Brown, et al., which was filed on Jun. 27, 2003, now U.S. Pat. No. 7,239,219, and which is entitled “Miniature RF and Microwave Components and Methods for Fabricating Such Components”, (7) U.S. patent application Ser. No. 10/841,006, by Thompson, et al., which was filed on May 7, 2004, now abandoned, and which is entitled “Electrochemically Fabricated Structures Having Dielectric or Active Bases and Methods of and Apparatus for Producing Such Structures”; (8) U.S. patent application Ser. No. 10/434,295, by Cohen, which was filed on May 7, 2003, now abandoned, and which is entitled “Method of and Apparatus for Forming Three-Dimensional Structures Integral With Semiconductor Based Circuitry”; and (9) U.S. patent application Ser. No. 10/677,556, by Cohen, et al., filed Oct. 1, 2003, now abandoned, and which is entitled “Monolithic Structures Including Alignment and/or Retention Fixtures for Accepting Components”. These patent filings are each hereby incorporated herein by reference as if set forth in full herein.

Some embodiments may employ diffusion bonding or the like to enhance adhesion between successive layers of material. Various teachings concerning the use of diffusion bonding in electrochemical fabrication processes are set forth in U.S. patent application Ser. No. 10/841,384 which was filed May 7, 2004 by Cohen et al., now abandoned, which is entitled “Method of Electrochemically Fabricating Multilayer Structures Having Improved Interlayer Adhesion” and which is hereby incorporated herein by reference as if set forth in full. This application is hereby incorporated herein by reference as if set forth in full.

The patent applications and patents set forth below are hereby incorporated by reference herein as if set forth in full. The teachings in these incorporated applications can be combined with the teachings of the instant application in many ways: For example, enhanced methods of producing structures may be derived from some combinations of teachings, enhanced structures may be obtainable, enhanced apparatus may be derived, enhanced methods of using may be implemented, and the like.

| U.S. Pat App No., Filing Date | |
|---|---|
| U.S. App Pub No., Pub Date | |
| U.S. Patent No., Pub Date | First Named Inventor, Title |
| 10/271,574 - Oct. 15, 2002 | Cohen, “Methods of and Apparatus for Making High Aspect |
| 2003-0127336 Jul. 10, 2003 | Ratio Microelectromechanical Structures” |
| 7,288,178 - Oct. 30, 2007 | |
| 10/387,958 - Mar. 13, 2003 | Cohen, “Electrochemical Fabrication Method and |
| 2003-022168 - Dec. 4, 2003 | Application for Producing Three-Dimensional Structures |
| — | Having Improved Surface Finish” |
| 10/434,289 - May 7, 2003 | Zhang, “Conformable Contact Masking Methods and |
| 20040065555 - Apr. 8, 2004 | Apparatus Utilizing In Situ Cathodic Activation of a |
| — | Substrate” |
| 10/434,294 - May 7, 2003 | Zhang, “Electrochemical Fabrication Methods With |
| 2004-0065550 - Apr. 8, 2004 | Enhanced Post Deposition Processing” |
| — | |
| 10/434,315 - May 7, 2003 | Bang, “Methods of and Apparatus for Molding Structures |
| 2003-0234179 - Dec. 25, 2003 | Using Sacrificial Metal Patterns” |
| 7,229,542 - Jun. 12, 2007 | |
| 10/434,494 - May 7, 2003 | Zhang, “Methods and Apparatus for Monitoring Deposition |
| 2004-0000489 - Jan. 1, 2004 | Quality During Conformable Contact Mask Plating |
| — | Operations” |
| 10/677,498 - Oct. 1, 2003 | Cohen, “Multi-cell Masks and Methods and Apparatus for |
| 2004-0134788 - Jul. 15, 2004 | Using Such Masks To Form Three-Dimensional Structures” |
| 7,235,166 - Jun. 26, 2007 | |
| 10/697,597 - Dec. 20, 2002 | Lockard, “EFAB Methods and Apparatus Including Spray |
| 2004-0146650 - Jul. 29, 2004 | Metal or Powder Coating Processes” |
| — | |
| 10/724,513 - Nov. 26, 2003 | Cohen, “Non-Conformable Masks and Methods and |
| 2004-0147124 - Jul. 29, 2004 | Apparatus for Forming Three-Dimensional Structures” |
| 7,368,044 - May 6, 2008 | |
| 10/724,515 - Nov. 26, 2003 | Cohen, “Method for Electrochemically Forming Structures |
| 2004-0182716 - Sep. 23, 2004 | Including Non-Parallel Mating of Contact Masks and |
| 7,291,254 - Nov. 6, 2007 | Substrates” |
| 10/830,262 - Apr. 21, 2004 | Cohen, “Methods of Reducing Interlayer Discontinuities in |
| 2004-0251142 - Dec. 16, 2004 | Electrochemically Fabricated Three-Dimensional |
| 7,198,704 - Apr. 3, 2007 | Structures” |
| 10/841,100 - May 7, 2004 | Cohen, “Electrochemical Fabrication Methods Including |
| 2005-0032362 - Feb. 10, 2005 | Use of Surface Treatments to Reduce Overplating and/or |
| 7,109,118 - Sep. 19, 2006 | Planarization During Formation of Multi-layer Three- |
| | Dimensional Structures” |
| 10/841,347 - May 7, 2004 | Cohen, “Multi-step Release Method for Electrochemically |
| 2005-0072681 - Apr. 7, 2005 | Fabricated Structures” |
| — | |
| 10/949,744 - Sep. 24, 2004 | Lockard, “Multi-Layer Three-Dimensional Structures Having |
| 2005-0126916 - Jun. 16, 2005 | Features Smaller Than a Minimum Feature Size |
| 7,498,714 - Mar. 3, 2009 | Associated with the Formation of Individual Layers” |
| 12/345,624 - Dec. 29, 2008 | Cohen, “Electrochemical Fabrication Method Including |
| — | Elastic Joining of Structures” |
| 8,070,931 - Dec. 6, 2011 | |
| 14/194,564 - Feb. 28, 2014 | Kumar, “Methods of Forming Three-Dimensional Structures |
| 2014-0238865 - Aug. 28, 2014 | Having Reduced Stress and/or Curvature” |
| 9,540,233 - Jan. 10, 2017 | |
| 14/720,719 - May 22, 2015 | Veeramani, “Methods of Forming Parts Using Laser |
| — | Machining” |
| 9,878,401 - Jan. 30, 2018 | |
| 14/872,033 - Sep. 30, 2015 | Le, “Multi-Layer, Multi-Material Microscale and Millimeter |
| — | Scale Batch Part Fabrication Methods Including |
| — | Disambiguation of Good Parts and Defective Parts” |

It will be understood by those of skill in the art that additional operations may be used in variations of the above presented method of making embodiments. These additional operations may, for example, perform cleaning functions (e.g. between the primary operations) discussed herein or discussed in the various materials incorporated herein by reference, they may perform activation functions and monitoring functions, and the like.

It will also be understood that the probe elements of some aspects of the invention may be formed with processes which are very different from the processes set forth herein, and it is not intended that structural aspects of the invention need to be formed by only those processes taught herein or by processes made obvious by those taught herein.

Though various portions of this specification have been provided with headers, it is not intended that the headers be used to limit the application of teachings found in one portion of the specification from applying to other portions of the specification. For example, alternatives acknowledged in association with one embodiment are intended to apply to all embodiments to the extent that the features of the different embodiments make such applications functional and do not otherwise contradict or remove all benefits of the adopted embodiment. Various other embodiments of the present invention exist. Some of these embodiments may be based on a combination of the teachings set forth herein with various teachings incorporated herein by reference.

It is intended that any aspects of the invention set forth herein represent independent invention descriptions which Applicant contemplates as full and complete invention descriptions that Applicant believes may be set forth as independent claims without need of importing additional limitations or elements, from other embodiments or aspects set forth herein, for interpretation or clarification other than when explicitly set forth in such independent claims once written. It is also understood that any variations of the aspects set forth herein represent individual and separate features that may form separate independent claims, be individually added to independent claims, or added as dependent claims to further define an invention being claimed by those respective dependent claims should they be written.

In view of the teachings herein, many further embodiments, alternatives in design and uses of the embodiments of the instant invention will be apparent to those of skill in the art. As such, it is not intended that the invention be limited to the particular illustrative embodiments, alternatives, and uses described above but instead that it be solely limited by the claims presented hereafter.

1. A method for forming a probe array, comprising:
(a) providing a build substrate;
(b) forming a plurality of probe preforms with one end of each probe preform formed directly or indirectly on the build substrate and with the other end of each probe preform extending away from the build substrate and with the plurality of probe preforms formed in a lateral pattern with a desired array spacing;
(c) providing at least one deformation plate having a plurality of holes having a lateral pattern matching at least a portion of the lateral pattern of the plurality of probe preforms;
(d) engaging matching holes of the at least one deformation plate with matching probe preforms;
(e) locating the at least one deformation plate at a longitudinal height (or heights) relative to the probe preforms that corresponds to at least one deformation level for the plurality of probe preforms;
(f) changing a lateral position of the at least one deformation plate with respect to an element selected from the group consisting of: (1) the build substrate, (2) a transfer substrate, and (3) a different deformation plate that also engages the matching probe preforms but at a different longitudinal height, such that the change in lateral position induces a plastic deformation into each of the matching probe preforms at the least one deformation level to introduce at least one permanent bend or deformation in each of the plurality of matching probe preforms;
whereby the at least one deformation provides probes from the probe preforms wherein each probe has a desired probe configuration, and
whereby a combination of the probes and at least one element selected from the group consisting of: (1) the substrate; (2) at least one deformation plate that is retained as a guide plate; (3) a transfer substrate, different from the build substrate, to which the probes are attached; and (4) at least one guide plate that was not previously used as a deformation plate that is made to engage the probes, form at least part of the probe array, and
wherein the method further comprises providing a stabilization material or plate that is positioned to hold the probe preforms to the substrate during deformation.

2. The method of claim 1 wherein the at least one deformation plate comprises a plurality of deformation plates that each engage multiple probe preforms and simultaneously introduce permanent deformation in a plurality of probe preforms at multiple heights.

3. The method of claim 1 wherein the at least one deformation plate comprises a plurality of deformation plates that each engage multiple probe preforms and that are used to introduce permanent deformation in a plurality of probe preforms simultaneously at at least one height after which at least one of the plurality of deformation plates is moved to introduce additional permanent deformation at at least one different height.

4. (canceled)

5. The method of claim 1 wherein the probe preforms are formed from a plurality of layers of deposited material.

6. The method of claim 1 wherein the probe preforms are formed from a single deposition of material that extends from a lower portion of the probe preforms to an upper portion of the probe preforms.

7. The method of claim 1 wherein each of the probes included in the probe array have similar bends at similar longitudinal levels.

8. The method of claim 1 wherein at least some of the probes included in a probe array have bends and/or longitudinal heights of bends that are different from the bends and/or longitudinal heights of the bends of other probes which form part of the probe array.

9. The method of claim 1 wherein the probe array when complete has a configuration selected from the group consisting of: (1) the probe array does not comprise the build substrate; (2) the probe array does not comprise any substrate; (3) the probe array does not comprise a guide plate; (4) the probe array does comprise at least one guide plate; (5) the probe array when complete does comprise at least two guide plates; and (6) the probe array does comprise a substrate.

10. The method of claim 1 wherein the providing of the at least one deformation plate comprises forming a deformation plate in lateral alignment with probe preforms.

11. The method of claim 1 wherein the providing of the at least one deformation plate and the engaging of the deformation plate comprises forming a deformation plate in lateral and longitudinal alignment with probe preforms.

12. The method of claim 1 wherein the at least one deformation plate is engaged with at least a portion of the probe preforms prior to complete release of the probe preforms from a sacrificial material such that sacrificial material provides some lateral support for holding the probe preforms in their respective lateral positions during engagement.

13. The method of claim 1 wherein the probe preforms are formed using an electrochemical fabrication process.

14. The method of claim 13 wherein the electrochemical fabrication process is a multi-layer electrochemical fabrication process.

15. The method of claim 14 wherein the multi-layer electrochemical fabrication process comprises deposition of at least one structural material and at least one sacrificial material during formation of each of a plurality of successive layers wherein each successive layer has its boundaries set by one or more planarization operations.

16. The method of claim 15 wherein at least one layer comprises a permanent stabilization material selected from the group consisting of: (1) a sacrificial material that is removed after deformation is completed; (2) a material that is a structural material that remains as part of the probe array; (3) a material that functions as a patterning material for deposition of probe preform material; and (4) a material that is deposited after removal of a patterning material that was used in depositing of probe preform material.

17. A method for forming a probe array, comprising:
(a) providing a substrate;
(b) forming a plurality of probe preforms with one end of each probe preform formed directly or indirectly on the substrate and with the other end of each probe preform extending away from the substrate and with the plurality of probe preforms formed in a lateral pattern with a desired array spacing;
(c) creating at least one deformation plate having a plurality of holes having a lateral pattern matching at least a portion of the lateral pattern of the plurality of probe preforms, wherein the at least one deformation plate upon creation has holes therein that are aligned laterally with the probe preforms, and wherein either during or after creation of the at least one deformation plate, longitudinally engaging the holes in the deformation plate with matching probe preforms or partially formed matching probe preforms;
(d) as necessary locating the at least one deformation plate at at least one longitudinal height relative to the probe preforms that corresponds to at least one deformation level for the matching plurality of probe preforms;
(f) changing a lateral position of the at least one deformation plate with respect to an element selected from the group consisting of: (1) the substrate, and (2) a different deformation plate that also engages the matching plurality of probe preforms at a different longitudinal height, such that the change in lateral position induces a plastic deformation into each of the matching probe preforms at the least one deformation level to introduce at least one permanent bend or deformation in each of the plurality of matching probe preforms;
whereby the at least one deformation provides probes from deformed probe preforms with a desired probe configuration, and
whereby a combination of the probes and at least one element selected from the group consisting of: (1) the substrate; (2) at least one deformation plate that is retained as a guide plate; (3) a separate substrate to which the probes are attached; and (4) at least one guide plate that was not previously used as a deformation plate that is made to engage the probes, form at least part of the probe array, and
wherein the method further comprises providing a stabilization material or plate that is positioned to hold the probe preforms to the substrate during deformation.
